(19) United States
(12) Patent Application Publication
(10) Pub. No.: US 2020/0356003 A1
(43) Pub. Date: Nov. 12, 2020

(54) PHOTOSENSITIVE COMPOSITION

(71) Applicant: FUJIFILM Corporation, Tokyo (JP)

(72) Inventors: Shunsuke KITAJIMA, Shizuoka (JP); Takahiro OKAWARA, Shizuoka (JP)

(73) Assignee: FUJIFILM Corporation, Tokyo (JP)

(21) Appl. No.: 16/943,833

(22) Filed: Jul. 30, 2020

Related U.S. Application Data
(63) Continuation of application No. PCT/JP2019/007063, filed on Feb. 25, 2019.

(30) Foreign Application Priority Data
Feb. 28, 2018 (JP) 2018-035140

(51) Int. Cl. G03F 7/031; G03F 7/00; G03F 7/029

(52) U.S. Cl. CPC G03F 7/031; G02B 5/208; G03F 7/029; G03F 7/0007

(57) ABSTRACT

A photosensitive composition for pulse exposure includes: a near infrared absorber A; a photoinitiator B; and a compound C that is cured by reacting with an active species generated from the photoinitiator B.

### CROSS-REFERENCE TO RELATED APPLICATIONS

This application is a Continuation of PCT International Application No. PCT/JP2019/007063 filed on Feb. 25, 2019, which claims priority under 35 U.S.C § 119(a) to Japanese Patent Application No. 2018-035140 filed on Feb. 28, 2018. Each of the above application(s) is hereby expressly incorporated by reference, in its entirety, into the present application.

### BACKGROUND OF THE INVENTION

### 1. Field of the Invention

The present invention relates to a photosensitive composition including a near infrared absorber. More specifically, a photosensitive composition used for a near infrared cut filter, a near infrared transmitting filter, or the like.

### 2. Description of the Related Art

A digital camera, a mobile phone equipped with a camera, or the like has been widely used, and a demand for a solid-state imaging element such as a charge coupled device (CCD) image sensor has increased significantly. As a key device of a display or an optical element, a color filter is used. Typically, the color filter includes pixels (colored patterns) of three primary colors including red, green, and blue and has a function of separating transmitted light into three primary colors.

The color filter can be formed using a photosensitive composition including a colorant. In addition, JP2012-532334A describes a photosensitive color resin composition for manufacturing a color filter for a solid-state imaging element using an ultra-short wavelength exposing device of 300 nm or less.

In addition, in a light receiving section of this solid-state imaging element, a silicon photodiode having sensitivity to infrared light is used. Therefore, visibility may be corrected using a near infrared cut filter. The near infrared cut filter is manufactured, for example, using a photosensitive composition including a near infrared absorber.

### SUMMARY OF THE INVENTION

In the related art, a near infrared cut filter has been used as a flat film. Recently, it has also been considered to form a pattern on a near infrared cut filter. For example, the use of a laminate in which each pixel (for example, a red pixel, a blue pixel, or a green pixel) of a color filter is formed on a pattern of a near infrared cut filter has been considered.

On the other hand, a near infrared absorber has high transmittance with respect to light such as an i-ray used for exposure. Therefore, in a case where a photosensitive composition including a near infrared absorber is exposed through a mask, a non-exposed portion at a mask edge may be exposed to reflected light or scattered light from a support or the like. In order to form a film that is sufficiently cured, a certain level of exposure dose is required. However, in a case where the exposure dose is excessively high, the reaction also progresses in a portion covered with a mask such that solubility in a developer deteriorates. As a result, the line width of the obtained pattern may be thicker than a desired value or a residue is likely to be formed between the patterns. Therefore, further improvement of performance for pattern formability regarding a photosensitive composition including a near infrared absorber is desired.

JP2012-532334A does not describe a composition including a near infrared absorber regarding a color filter.

Accordingly, an object of the present invention is to provide a photosensitive composition having excellent pattern formability.

As a result of a thorough investigation, the present inventors found that excellent pattern formability can be obtained by exposing a photosensitive composition including a near infrared absorber to pulses of light to form a pattern, thereby completing the present invention. Accordingly, the present invention provides the following.

<1> A photosensitive composition for pulse exposure comprising:

a near infrared absorber A;

a photoinitiator B; and

a compound C that is cured by reacting with an active species generated from the photoinitiator B.

<2> The photosensitive composition according to <1>,

in which an A/B that is a ratio of an absorbance A of the photosensitive composition with respect to light having a wavelength of 248 nm to an absorbance B of the photosensitive composition with respect to light having a wavelength of 365 nm is 3.4 or higher.

<3> The photosensitive composition according to <1> or <2>,

in which the photoinitiator B includes an photoinitiator b1 that satisfies the following condition 1,

condition 1: after a propylene glycol monomethyl ether acetate solution including 0.035 mmol/L of the photoinitiator b1 is exposed to pulses of light having a wavelength of 355 nm under conditions of a maximum instantaneous illuminance of 375000000 W/m², pulse duration: 8 nanoseconds, and frequency: 10 Hz, a quantum yield q₃₅₅ is 0.05 or higher.

<4> The photosensitive composition according to <3>,

in which the quantum yield q₃₅₅ of the photoinitiator b1 is 0.10 or higher.

<5> The photosensitive composition according to <3> or <4>,

in which the photoinitiator b1 satisfies the following condition 2,

condition 2: after a film having a thickness of 1.0 μm and including 5 mass % of the photoinitiator b1 and 95 mass % of a resin is exposed to pulses of light having a wavelength of 265 nm under conditions of a maximum instantaneous illuminance of 375000000 W/m², pulse duration: 8 nanoseconds, and frequency: 10 Hz, a quantum yield q₂₆₅ is 0.05 or higher.

<6> The photosensitive composition according to <5>,

in which the quantum yield q₂₆₅ of the photoinitiator b1 is 0.10 or higher.

<7> The photosensitive composition according to any one of <3> to <6>,

in which the photoinitiator b1 satisfies the following condition 3,

condition 3: after a film including 5 mass % of the photoinitiator b1 and a resin is exposed to one pulse of light having a wavelength in a wavelength range of 248 to 365 nm under conditions of a maximum instantaneous illuminance of 62/500,0000 W/m², pulse duration: 8 nanoseconds, and frequency: 10 Hz, an active species concentration in the film reaches 0.000000001 mmol or higher per 1 cm² of the film.

<8> The photosensitive composition according to <7>,

in which the active species concentration in the film the photoinitiator b1 reaches 0.0000001 mmol or higher per 1 cm² of the film under the condition 3.

<9> The photosensitive composition according to any one of <1> to <8>,

in which a content of the near infrared absorber A is 15 mass % or higher with respect to a total solid content of the photosensitive composition.

<10> The photosensitive composition according to any one of <1> to <9>,

in which a content of the compound C is 5% to 30 mass % with respect to a total solid content of the photosensitive composition.

<11> The photosensitive composition according to any one of <1> to <10>,

in which the photoinitiator B is a photoradical polymerization initiator, and

the compound C is a radically polymerizable compound.

<12> The photosensitive composition according to <11>,

in which the radically polymerizable compound includes a radically polymerizable monomer.

<13> The photosensitive composition according to <12>,

in which a polymerizable group value of the radically polymerizable monomer is 10.5 mmol/g or higher.

<14> The photosensitive composition according to any one of <11> to <13>,

in which the photoradical polymerization initiator is at least one compound selected from an alkylphenone compound, an acylphosphine compound, a benzophenone compound, a thioxanthone compound, a triazine compound, or an oxime compound.

<15> The photosensitive composition according to any one of <1> to <14>, further comprising:

an ultraviolet absorber.

<16> The photosensitive composition according to <15>,

in which a content of the ultraviolet absorber is 0.01% to 7 mass % with respect to a total solid content of the photosensitive composition.

<17> The photosensitive composition according to any one of <1> to <16>, further comprising:

an antioxidant.

<18> The photosensitive composition according to <17>,

in which a content of the antioxidant is 0.1% to 5 mass % with respect to a total solid content of the photosensitive composition.

<19> The photosensitive composition according to any one of <1> to <18>, which is a composition for a near infrared cut filter.

<20> The photosensitive composition according to any one of <1> to <18>, which is a photosensitive composition for a near infrared transmitting filter.

<21> The photosensitive composition according to any one of <1> to <20>, which is a photosensitive composition for pulse exposure to light having a wavelength of 300 nm or shorter.

<22> The photosensitive composition according to any one of <1> to <21>, which is a photosensitive composition for pulse exposure under a condition of a maximum instantaneous illuminance of 50000000 W/m² or higher.

According to the present invention, a photosensitive composition having excellent pattern formability can be provided.

### DESCRIPTION OF THE PREFERRED EMBODIMENTS

Hereinafter, the details of the present invention will be described.

In this specification, numerical ranges represented by “to” include numerical values before and after “to” as lower limit values and upper limit values.

In this specification, unless specified as a substituted group or as an unsubstituted group, a group (atomic group) denotes not only a group (atomic group) having no substituent but also a group (atomic group) having a substituent. For example, “alkyl group” denotes not only an alkyl group having no substituent (unsubstituted alkyl group) but also an alkyl group having a substituent (substituted alkyl group).

In this specification, “(meth)allyl group” denotes either or both of allyl and methallyl, “(meth)acrylate” denotes either or both of acrylate or methacrylate, “(meth)acryl” denotes either or both of acryl and methacryl, and “(meth)acryloyl” denotes either or both of acryloyl and methacryloyl.

In this specification, a weight-average molecular weight and a number-average molecular weight denote values in terms of polystyrene measured by gel permeation chromatography (GPC).

In this specification, near infrared light denotes light in a wavelength range of 700 to 2500 nm.

In this specification, a total solid content denotes the total mass of all the components of the composition excluding a solvent.

In this specification, the term “step” denotes not only an individual step but also a step which is not clearly distinguishable from another step as long as an effect expected from the step can be achieved.

<Photosensitive Composition>

A photosensitive composition for pulse exposure according to an embodiment of the present invention comprises: a near infrared absorber A; a photoinitiator B; and a compound C that is cured by reacting with an active species generated from the photoinitiator B.

The photosensitive composition according to the embodiment of the present invention has excellent pattern formability. A fine pattern can be formed by exposing the photosensitive composition according to the embodiment of the present invention to pulses of light. The reason why this effect is obtained is presumed to be as follows. That is, by exposing the photosensitive composition including the near infrared absorber A, the photoinitiator B, and the compound C to pulses of light, a large amount of an active species such as a radical is instantaneously generated from the photoinitiator B in the exposed portion. As a result, the compound C can be efficiently cured due to an effect of, for example, suppressing deactivation caused by oxygen. As a result, it is presumed that only the exposed portion of the photosensitive composition can be selectively cured by the pulse exposure such that a pattern can be formed along a mask shape. Therefore, it is presumed that the photosensitive composition according to the embodiment of the present invention has excellent pattern formability. The pulse exposure described in the present invention refers to an exposure method in which light irradiation and pause are repeated in a cycle of a short period of time (for example, a level of milliseconds).

The photosensitive composition according to the embodiment of the present invention is a photosensitive composition for pulse exposure. The light used for the exposure may be light having a wavelength of longer than 300 nm or light having a wavelength of 300 nm or shorter. From the viewpoint of easily obtaining higher pattern formability, curing properties, and the like, the light used for the exposure is preferably light having a wavelength of 300 nm or shorter, more preferably light having a wavelength of 270 nm or shorter, and still more preferably light having a wavelength of 250 nm or shorter. In addition, the above-described light is preferably light having a wavelength of 180 nm or longer. Specific examples of the light include a KrF ray (wavelength: 248 nm) and an ArF ray (wavelength: 193 nm). From the viewpoint of easily obtaining higher pattern formability, curing properties, and the like, a KrF ray (wavelength: 248 nm) is preferable.

It is preferable that the exposure condition of the pulse exposure is the following condition. From the viewpoint of instantaneously generating a large amount of an active species such as a radical easily, the pulse duration is preferably 100 nanoseconds (ns) or shorter, more preferably 50 nanoseconds or shorter, and still more preferably 30 nanoseconds or shorter. The lower limit of the pulse duration is not particularly limited and may be 1 femtoseconds (fs) or longer or 10 femtoseconds (fs) or longer. From the viewpoint of easily thermally polymerizing the compound C due to exposure heat, the frequency is preferably 1 kHz or higher, more preferably 2 kHz or higher, and still more preferably 4 kHz or higher. From the viewpoint of easily suppressing deformation of a substrate or the like caused by exposure heat, the upper limit of the frequency is preferably 50 kHz or lower, more preferably 20 kHz or lower, and still more preferably 10 kHz or lower. From the viewpoint of curing properties, the maximum instantaneous illuminance is preferably 50000000 W/m² or higher, more preferably 100000000 W/m² or higher, and still more preferably 200000000 W/m² or higher. In addition, from the viewpoint of high illuminance reciprocity failure, the upper limit of the maximum instantaneous illuminance is preferably 1000000000 W/m² or lower, more preferably 800000000 W/m² or lower, and still more preferably 500000000 W/m² or lower. The pulse duration refers to the length of time during which light is irradiated during a pulse period. In addition, the frequency refers to the number of pulse periods per second. In addition, the maximum instantaneous illuminance refers to an average illuminance within a time during which light is irradiated in a pulse period. In addition, the pulse period refers to a period in which light irradiation and pause during pulse exposure are set as one cycle.

It is preferable that the photosensitive composition according to the embodiment of the present invention satisfies spectral characteristics in which an A/B that is a ratio of an absorbance A with respect to light having a wavelength of 248 nm to an absorbance B with respect to light having a wavelength of 365 nm is 3.4 or higher. By the photosensitive composition according to the embodiment of the present invention satisfying the spectral characteristics, even in a case where the content of the photopolymerization initiator is low, excellent sensitivity properties can be obtained, and an ultrafine pattern with a high resolution can be formed even at a low exposure dose. A/B is preferably 3.4 or higher, more preferably 3.45 or higher, and still more preferably 3.5 or higher. From the viewpoint of easily suppressing a reverse tapered shape due to insufficient curing of a pattern lower portion, the upper limit is preferably 4.0 or lower.

The photosensitive composition according to the embodiment of the present invention can be preferably used as a photosensitive composition for a near infrared cut filter or a photosensitive composition for a near infrared transmitting filter. In addition, the photosensitive composition according to the embodiment of the present invention can be preferably used as a photosensitive composition for a solid-state imaging element. In the present invention, “near infrared cut filter” refers to a filter that allows transmission of light (visible light) in the visible range and blocks at least a part of light (near infrared light) in the near infrared range. The near infrared cut filter may be a filter that allows transmission of light in the entire wavelength range of the visible range, or may be a filter that allows transmission of light in a specific wavelength range of the visible range and blocks light in another specific wavelength range of the visible range. In addition, in the present invention, “near infrared transmitting filter” refers to a filter that blocks visible light and allows transmission of at least a part of near infrared light.

In a case where the photosensitive composition according to the embodiment of the present invention is used as a photosensitive composition for a near infrared cut filter, it is preferable that the photosensitive composition according to the embodiment of the present invention has a maximum absorption wavelength in a wavelength range of 700 to 1800 nm, it is more preferable that the photosensitive composition according to the embodiment of the present invention has a maximum absorption wavelength in a wavelength range of 700 to 1300 nm, and it is still more preferable that the photosensitive composition according to the embodiment of the present invention has a maximum absorption wavelength in a wavelength range of 700 to 1000 nm. In addition, it is preferable that the photosensitive composition according to the embodiment of the present invention satisfies spectral characteristics in which A₁/A₂ that is a ratio of a maximum value A₁ of an absorbance in a wavelength range of 400 to 600 nm to an absorbance A₂ at the maximum absorption wavelength is 0.30 or lower. With the photosensitive composition having the spectral characteristics, a near infrared cut filter having excellent near infrared blocking properties and excellent visible transparency can be formed. A₁/A₂ is preferably 0.20 or lower, more preferably 0.15 or lower, and still more preferably 0.10 or lower.

In a case where the photosensitive composition according to the embodiment of the present invention is used as a photosensitive composition for a near infrared transmitting filter, it is preferable that the photosensitive composition according to the embodiment of the present invention satisfies spectral characteristics in which a ratio Amin/Bmax of a minimum value Amin of an absorbance of the photosensitive composition in a wavelength range of 400 to 640 nm to a maximum value Bmax of an absorbance of the photosensitive composition in a wavelength range of 1100 to 1300 nm is 5 or higher. Amin/Bmax is more preferably 7.5 or higher, still more preferably 15 or higher, and still more preferably 30 or higher.

An absorbance Aλ at a wavelength λ is defined by the following Expression (1).

Aλ=−log(Tλ/100) (1)

Aλ represents the absorbance at the wavelength λ, and Tλ represents a transmittance (%) at the wavelength λ.

In the present invention, a value of the absorbance may be a value measured in the form of a solution or a value of a film which is formed using the photosensitive composition. In a case where the absorbance is measured in the form of the film, it is preferable that the absorbance is measured using a film that is formed by applying the photosensitive composition to a glass substrate using a method such as spin coating such that the thickness of the dried film is a predetermined value, and drying the applied composition using a hot plate at 100° C. for 120 seconds.

In a case where the photosensitive composition according to the embodiment of the present invention is used as a photosensitive composition for a near infrared transmitting filter, it is more preferable that the photosensitive composition according to the embodiment of the present invention satisfies any one of the following spectral characteristics (11) to (14).

(11): A ratio Amin1/Bmax1 of a minimum value Amin1 of an absorbance of the photosensitive composition in a wavelength range of 400 to 640 nm to a maximum value Bmax1 of an absorbance of the photosensitive composition in a wavelength range of 800 to 1300 nm is 5 or higher, preferably 7.5 or higher, more preferably 15 or higher, and still more preferably 30 or higher. In this aspect, a film that can block light in a wavelength range of 400 to 640 nm and allows transmission of light having a wavelength of 720 nm or longer can be formed.

(12): A ratio Amin2/Bmax2 of a minimum value Amin2 of an absorbance of the photosensitive composition in a wavelength range of 400 to 750 nm to a maximum value Bmax2 of an absorbance of the photosensitive composition in a wavelength range of 900 to 1300 nm is 5 or higher, preferably 7.5 or higher, more preferably 15 or higher, and still more preferably 30 or higher. In this aspect, a film that can block light in a wavelength range of 400 to 750 nm and allows transmission of light having a wavelength of 850 nm or longer can be formed.

(13): A ratio Amin3/Bmax3 of a minimum value Amin3 of an absorbance of the photosensitive composition in a wavelength range of 400 to 850 nm to a maximum value Bmax3 of an absorbance of the photosensitive composition in a wavelength range of 1000 to 1300 nm is 5 or higher, preferably 7.5 or higher, more preferably 15 or higher, and still more preferably 30 or higher. In this aspect, a film that can block light in a wavelength range of 400 to 850 nm and allows transmission of light having a wavelength of 940 nm or longer can be formed.

(14): A ratio Amin4/Bmax4 of a minimum value Amin4 of an absorbance of the photosensitive composition in a wavelength range of 400 to 950 nm to a maximum value Bmax4 of an absorbance of the photosensitive composition in a wavelength range of 1100 to 1300 nm is 5 or higher, preferably 7.5 or higher, more preferably 15 or higher, and still more preferably 30 or higher. In this aspect, a film that can block light in a wavelength range of 400 to 950 nm and allows transmission of light having a wavelength of 1040 nm or longer can be formed.

Hereinafter, each of the components used in the photosensitive composition according to the embodiment of the present invention will be described.

<<Near Infrared Absorber A>>

The photosensitive composition according to the embodiment of the present invention includes a near infrared absorber A (hereinafter, simply referred to as “near infrared absorber”). The near infrared absorber may be an organic compound or an inorganic compound. In addition, the near infrared absorber may be a pigment (also referred to as “near infrared absorbing pigment”) or a dye (also referred to as “near infrared absorbing dye”). In addition, it is preferable that the near infrared absorbing dye and the near infrared absorbing pigment are used in combination. In a case where the near infrared absorbing dye and the near infrared absorbing pigment are used in combination, a mass ratio near infrared absorbing dye:near infrared absorbing pigment of the near infrared absorbing dye to the near infrared absorbing pigment is preferably 99.9:0.1 to 0.1:99.9, more preferably 99.9:0.1 to 10:90, and still more preferably 99.9:0.1 to 20:80. The solubility of the near infrared absorbing dye in 100 g of at least one solvent selected from cyclopentanone, cyclohexanone, or dipropylene glycol monomethyl ether at 23° C. is preferably 1 g or higher, more preferably 2 g or higher, and still more preferably 5 g or higher. In addition, a solubility of the near infrared absorbing pigment in 100 g of each solvent of cyclopentanone, cyclohexanone, or dipropylene glycol monomethyl ether at 23° C. is preferably lower than 1 g, more preferably 0.1 g or lower, and still more preferably 0.01 g or lower.

The near infrared absorber is preferably a compound having a maximum absorption wavelength in a wavelength range of 700 to 1800 nm, more preferably a compound having a maximum absorption wavelength in a wavelength range of 700 to 1300 nm, and still more preferably a compound having a maximum absorption wavelength in a wavelength range of 700 to 1000 nm. In addition, in the near infrared absorber, a ratio A¹/A² of an absorbance A¹ at a wavelength of 500 nm to an absorbance A² at the maximum absorption wavelength is preferably 0.08 or lower and more preferably 0.04 or lower. In this aspect, a film having excellent visible transparency and near infrared blocking properties can be easily manufactured.

In the present invention, as the near infrared absorber, at least two compounds having different maximum absorption wavelengths are preferably used. In this aspect, the waveform of the absorption spectrum of the obtained film is wider than that in a case where one near infrared absorber is used, and the film can block near infrared light in a wide wavelength range.

Examples of the inorganic compound used as the near infrared absorber include a metal oxide and a metal boride. Examples of the metal oxide include indium tin oxide, antimony tin oxide, zinc oxide, Al-doped zinc oxide, fluorine-doped tin dioxide, niobium-doped titanium dioxide, and tungsten oxide. The details of the tungsten oxide can be found in paragraph “0080” of JP2016-006476A, the content of which is incorporated herein by reference. Examples of the metal boride include lanthanum boride. Examples of a commercially available product of the lanthanum boride include LaB₆—F (manufactured by Japan New Metals Co., Ltd.).

It is preferable that the organic compound used as the near infrared absorber is a compound that includes a π-conjugated plane having a monocyclic or fused aromatic ring. The number of atoms forming the π-conjugated plane other than hydrogen is preferably 6 or more, more preferably 14 or more, still more preferably 20 or more, still more preferably 25 or more, and still more preferably 30 or more. For example, the upper limit is preferably 80 or less and more preferably 50 or less.

In addition, the number of monocyclic or fused aromatic rings included in the π-conjugated plane is preferably 2 or more, more preferably 3 or more, and still more preferably 4 or more. The upper limit is preferably 100 or less, more preferably 50 or less, and still more preferably 30 or less. Examples of the aromatic ring include a benzene ring, a naphthalene ring, an indene ring, an azulene ring, a heptalene ring, an indacene ring, a perylene ring, a pentacene ring, a quaterrylene ring, an acenaphthene ring, a phenanthrene ring, an anthracene ring, a naphthacene ring, a chrysene ring, a triphenylene ring, a fluorene ring, a pyridine ring, a quinoline ring, an isoquinoline ring, an imidazole ring, a benzimidazole ring, a pyrazole ring, a thiazole ring, a benzothiazole ring, a triazole ring, a benzotriazole ring, an oxazole ring, a benzoxazole ring, an imidazoline ring, a pyrazine ring, a quinoxaline ring, a pyrimidine ring, a quinazoline ring, a pyridazine ring, a triazine ring, a pyrrole ring, an indole ring, an isoindole ring, a carbazole ring, a pyran ring, a thiopyran ring, and a fused ring including the above-described ring.

As the organic compound used as the near infrared absorber, at least one selected from a pyrrolopyrrole compound, a cyanine compound, a squarylium compound, a phthalocyanine compound, a naphthalocyanine compound, a rylene compound, a merocyanine compound, a croconium compound, an oxonol compound, an iminium compound, a dithiol compound, a triarylmethane compound, a pyrromethene compound, an azomethine compound, an anthraquinone compound, or a dibenzofuranone compound is preferable, at least one selected from a pyrrolopyrrole compound, a cyanine compound, a squarylium compound, a croconium compound, a rylene compound, or an iminium compound is more preferable, at least one selected from a pyrrolopyrrole compound, a cyanine compound, a squarylium compound, or a croconium compound is still more preferable, and a pyrrolopyrrole compound is still more preferable. Examples of the phthalocyanine compound include a compound described in paragraph “0093” of JP2012-077153A, oxytitaniumphthalocyanine described in JP2006-343631A, a compound described in paragraphs “0013” to “0029” of JP2013-195480A, vanadium phthalocyanine described in JP6081771B, the contents of which are incorporated herein by reference. Examples of the naphthalocyanine compound include a compound described in paragraph “0093” of JP2012-077153A, the content of which is incorporated herein by reference. In addition, a compound described in JP2016-146619A can also be used as the near infrared absorber, the content of which is incorporated herein by reference. Specific examples of the organic compound used as the near infrared absorber include a compound described in Examples described below. In addition, as the rylene compound, for example, a compound having the following structure can also be used. In the following structural formula, R's each independently represent a hydrogen atom, a linear or branched alkyl group having 1 to 22 carbon atoms, an acyl group, or a group represented by the following Formula (1).

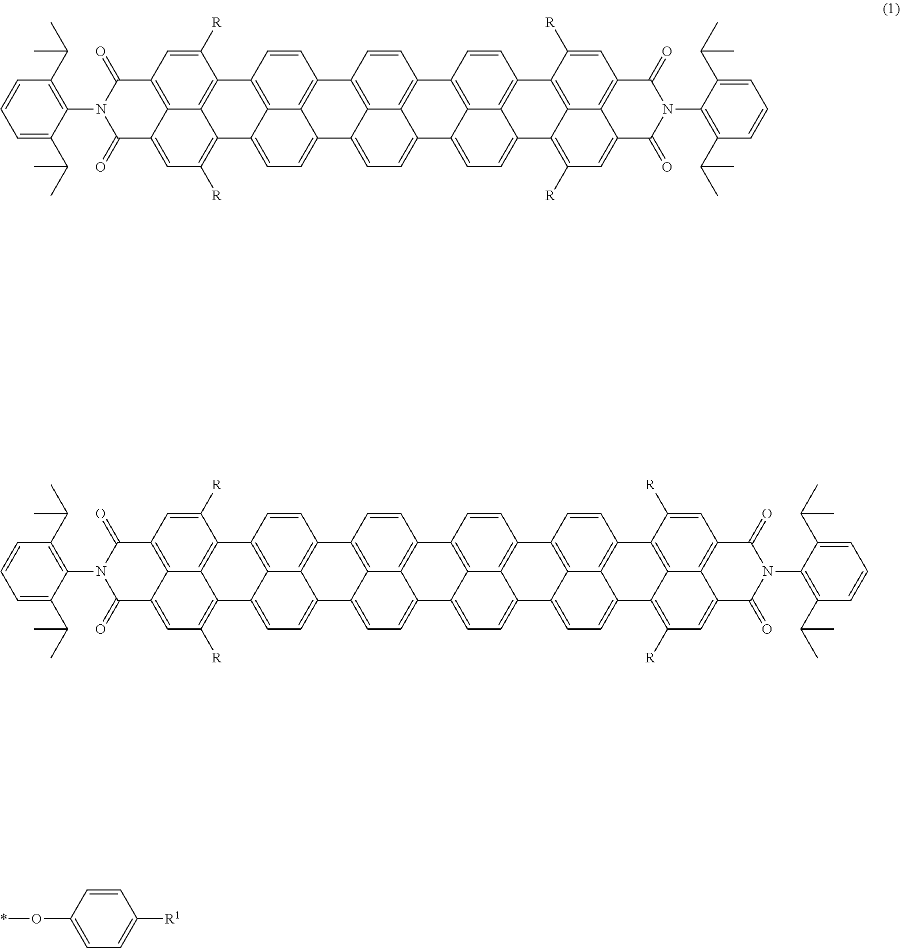

In Formula (1), R¹ represents a linear or branched alkyl group having 1 to 22 carbon atoms.

Examples of the pyrrolopyrrole compound include a compound represented by Formula (PP).

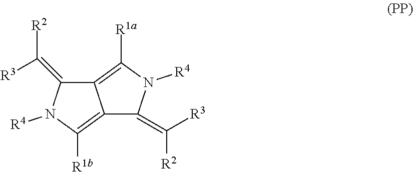

In the formula, R^{1a} and R^{1b} each independently represent an alkyl group, an aryl group, or a heteroaryl group, R² and R³ each independently represent a hydrogen atom or a substituent, R² and R³ may be bonded to each other to form a ring, R⁴'s each independently represent a hydrogen atom, an alkyl group, an aryl group, a heteroaryl group, —BR^{4A}R^{4B}, or a metal atom, R⁴ may form a covalent bond or a coordinate bond with at least one selected from R^{1a}, R^{1b}, or R³, and R^{4A} and R^{4B} each independently represent a substituent. R^{4A} and R^{4B} may be bonded to each other to form a ring. The details of Formula (PP) can be found in paragraphs “0017” to “0047” of JP2009-263614A, paragraphs “0011” to “0036” of JP2011-068731A, and paragraphs “0010” to “0024” of WO2015/166873A, the contents of which are incorporated herein by reference.

In Formula (PP), R^{1a} and R^{1b} each independently represent preferably an aryl group or a heteroaryl group, and more preferably an aryl group. In addition, the alkyl group, the aryl group, and the heteroaryl group represented by R^{1a} and R^{1b} may have a substituent or may be unsubstituted. Examples of the substituent include substituents described in paragraphs “0020” to “0022” of 2009-0263614A and the following substituent T.

(Substituent T)

The substituent T includes an alkyl group (preferably an alkyl group having 1 to 30 carbon atoms), an alkenyl group (preferably an alkenyl group having 2 to 30 carbon atoms), an alkynyl group (preferably an alkynyl group having 2 to 30 carbon atoms), an aryl group (preferably an aryl group having 6 to 30 carbon atoms), an amino group (preferably an amino group having 0 to 30 carbon atoms), an alkoxy group (preferably an alkoxy group having 1 to 30 carbon atoms), an aryloxy group (preferably an aryloxy group having 6 to 30 carbon atoms), a heteroaryloxy group, an acyl group (preferably having an acyl group 1 to 30 carbon atoms), an alkoxycarbonyl group (preferably an alkoxycarbonyl group having 2 to 30 carbon atoms), an aryloxycarbonyl group (preferably an aryloxycarbonyl group having 7 to 30 carbon atoms), an acyloxy group (preferably an acyloxy group having 2 to 30 carbon atoms), an acylamino group (preferably an acylamino group having 2 to 30 carbon atoms), an alkoxycarbonylamino group (preferably an alkoxycarbonylamino group having 2 to 30 carbon atoms), an aryloxycarbonylamino group (preferably an aryloxycarbonylamino group having 7 to 30 carbon atoms), a sulfamoyl group (preferably a sulfamoyl group having 0 to 30 carbon atoms), a carbamoyl group (preferably a carbamoyl group having 1 to 30 carbon atoms), an alkylthio group (preferably an alkylthio group having 1 to 30 carbon atoms), an arylthio group (preferably an arylthio group having 6 to 30 carbon atoms), a heteroarylthio group (preferably having 1 to 30 carbon atoms), an alkylsulfonyl group (preferably having 1 to 30 carbon atoms), an arylsulfonyl group (preferably having 6 to 30 carbon atoms), a heteroarylsulfonyl group (preferably having 1 to 30 carbon atoms), an alkylsulfinyl group (preferably having 1 to 30 carbon atoms), an arylsulfinyl group (preferably having 6 to 30 carbon atoms), a heteroarylsulfinyl group (preferably having 1 to 30 carbon atoms), a ureido group (preferably having 1 to 30 carbon atoms), a hydroxy group, a carboxyl group, a sulfo group, a phosphate group, a carboxylic acid amide group, a sulfonic acid amide group, an imide acid group, a mercapto group, a halogen atom, a cyano group, an alkylsulfino group, an arylsulfino group, a hydrazino group, an imino group, and a heteroaryl group (preferably having 1 to 30 carbon atoms). In a case where the above-described groups can be further substituted, the groups may further have a substituent. Examples of the substituent include the groups described regarding the substituent T.

Specific examples of the group represented by R^{1a} and R^{1b} include an aryl group which has an alkoxy group as a substituent, an aryl group which has a hydroxy group as a substituent, and an aryl group which has an acyloxy group as a substituent.

In Formula (PP), R² and R³ each independently represent a hydrogen atom or a substituent. Examples of the substituent include the above-described substituent T. It is preferable that at least one of R² or R³ represents an electron-withdrawing group. A substituent having a positive Hammett's substituent constant σ value (sigma value) acts as an electron-withdrawing group. Here, the substituent constant obtained by Hammett's rule includes a σp value and a σm value. The values can be found in many common books. In the present invention, a substituent having the Hammett's substituent constant σ value of 0.2 or more can be exemplified as the electron-withdrawing group. σ value is preferably 0.25 or more, more preferably 0.3 or more, and still more preferably 0.35 or more. The upper limit is not particularly limited, but preferably 0.80 or less. Specific examples of the electron-withdrawing group include a cyano group (σp value=0.66), a carboxyl group (—COOH: σp value=0.45), an alkoxycarbonyl group (for example, —COOMe: σp value=0.45), an aryloxycarbonyl group (for example, —COOPh: σp value=0.44), a carbamoyl group (for example, —CONH₂: σp value=0.36), an alkylcarbonyl group (for example, —COMe: σp value=0.50), an arylcarbonyl group (for example, —COPh: σp value=0.43), an alkylsulfonyl group (for example, —SO₂Me: σp value=0.72), and an arylsulfonyl group (for example, —SO₂Ph: σp value=0.68). Among these, a cyano group is preferable. Here, Me represents a methyl group, and Ph represents a phenyl group. For example, the Hammett's substituent constant σ value can be found in the description of paragraphs “0017” and “0018” of JP2011-068731A, the content of which is incorporated herein by reference.

In Formula (PP), it is preferable that R² represents an electron-withdrawing group (preferably a cyano group) and R³ represents a heteroaryl group. It is preferable that the heteroaryl group is a 5- or 6-membered ring. In addition, the heteroaryl group is preferably a monocyclic or fused ring, more preferably a monocyclic or fused ring including 2 to 8 rings, and still more preferably a monocyclic or fused ring including 2 to 4 rings. The number of heteroatoms forming the heteroaryl group is preferably 1 to 3 and more preferably 1 or 2. Examples of the heteroatom include a nitrogen atom, an oxygen atom, and a sulfur atom. It is preferable that the heteroaryl group has one or more nitrogen atoms. Two R²'s in Formula (PP) may be the same as or different from each other. In addition, two R³'s in Formula (PP) may be the same as or different from each other.

In Formula (PP), R⁴ represents preferably a hydrogen atom, an alkyl group, an aryl group, a heteroaryl group, or a group represented by —BR^{4A}R^{4B}, more preferably a hydrogen atom, an alkyl group, an aryl group, or a group represented by —BR^{4A}R^{4B}, and still more preferably a group represented by —BR^{4A}R^{4B}. As the substituent represented by R^{4A} and R^{4B}, a halogen atom, an alkyl group, an alkoxy group, an aryl group, or a heteroaryl group is preferable, an alkyl group, an aryl group, or a heteroaryl group is more preferable, and an aryl group is still more preferable. Each of the groups may further have a substituent. Two R⁴'s in Formula (PP) may be the same as or different from each other. R^{4A} and R^{4B} may be bonded to each other to form a ring.

Specific examples of the pyrrolopyrrole compound include a compound described in Examples described below. In addition, Examples of the pyrrolopyrrole compound include compounds described in paragraphs “0016” to “0058” of JP2009-263614A, compounds described in paragraphs “0037” to “0052” of JP2011-068731A, compounds described in paragraphs “0010” to “0033” of WO2015/166873A, the contents of which are incorporated herein by reference.

It is preferable that the squarylium compound is a compound represented by the following Formula (SQ1).

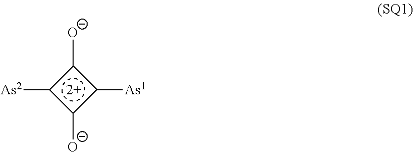

In the formulae, As¹ and As² each independently represent an aryl group, a heterocyclic group, or a group represented by Formula (As-1).

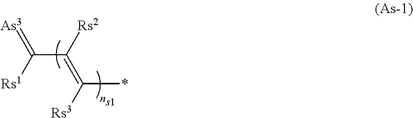

In the formula, * represents a direct bond.

Rs¹ to Rs³ each independently represent a hydrogen atom or an alkyl group.

As³ represents a heterocyclic group.

nₛ₁ represents an integer of 0 or more.

Rs¹ and Rs² may be bonded to each other to form a ring.

Rs¹ and As³ may be bonded to each other to form a ring.

Rs² and Rs³ may be bonded to each other to form a ring.

In a case where nₛ₁ represents 2 or more, a plurality of Rs²'s may be the same as or different from each other and a plurality of Rs³'s may be the same as or different from each other.

The number of carbon atoms in the aryl group represented by As¹ and As² is preferably 6 to 48, more preferably 6 to 22, and still more preferably 6 to 12.

It is preferable that the heterocyclic group represented by As¹, As², and As³ is a 5- or 6-membered heterocyclic group. In addition, the heterocyclic group is preferably a monocyclic or fused heterocyclic group including 2 to 8 rings, more preferably a monocyclic or fused heterocyclic group including 2 to 4 rings, still more preferably a monocyclic or fused heterocyclic group including 2 or 3 rings, and still more preferably a monocyclic or fused heterocyclic group including 2 rings. Examples of a heteroatom included in the ring of the heterocyclic group include a nitrogen atom, an oxygen atom, and a sulfur atom. Among these, a nitrogen atom or a sulfur atom is preferable. The number of heteroatoms forming the ring of the heterocyclic group is preferably 1 to 3 and more preferably 1 or 2.

Rs¹ to Rs³ in Formula (As-1) each independently represent a hydrogen atom or an alkyl group. The number of carbon atoms in the alkyl group represented by Rs¹ to Rs³ is preferably 1 to 20, more preferably 1 to 15, and still more preferably 1 to 8. The alkyl group may be linear, branched, or cyclic and is preferably linear or branched. It is preferable that Rs¹ to Rs³ represent a hydrogen atom.

nₛ₁ in Formula (As-1) represents an integer of 0 or more. nₛ₁ represents preferably an integer of 0 to 2, more preferably 0 or 1, and still more preferably 0.

In Formula (As-1), Rs¹ and Rs² may be bonded to each other to form a ring, Rs¹ and As³ may be bonded to each other to form a ring, and Rs² and Rs³ may be bonded to each other to form a ring. It is preferable that a linking group for forming the ring is a divalent linking group selected from the group consisting of —CO—, —O—, —NH—, an alkylene group having 1 to 10 carbon atoms, and a combination thereof. The alkylene group as the linking group may be unsubstituted or may have a substituent. Examples of the substituent include the above-described substituent T.

In Formula (SQ1), it is preferable that the group represented by As¹ and As² has a substituent. Examples of the substituent include the above-described substituent T.

In Formula (SQ1), it is preferable that As¹ and As² each independently represent an aryl group or a heterocyclic group, or it is preferable that As¹ and As² each independently represent a group represented by Formula (As-1).

As shown below, cations in Formula (SQ1) are present without being localized.

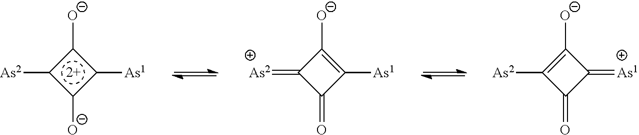

It is preferable that the squarylium compound is a compound represented by the following Formula (SQ2) or a compound represented by the following Formula (SQ3).

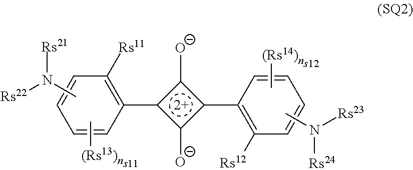

Rs¹¹ and Rs¹² each independently represent a hydrogen atom or a substituent.

Rs¹³ and Rs¹ each independently represent a substituent.

nₛ₁₁ and nₛ₁₂ each independently represent an integer of 0 to 3.

In a case where nₛ₁₁ represents 2 or more, two Rs¹³'s may be bonded to each other to form a ring.

In a case where nₛ₁₂ represents 2 or more, two Rs¹³'s may be bonded to each other to form a ring.

Rs²¹ to Rs²⁴ each independently represent an alkyl group, an aryl group, or a heteroaryl group.

Rs²¹ and Rs²², Rs²³ and Rs²⁴, Rs²¹ and Rs¹³, Rs²² and Rs¹³, Rs²³ and Rs¹⁴, Rs²⁴ and Rs¹⁴, Rs²¹ and a ring two Rs¹³'s formed by being bonded to each other, or Rs²³ and a ring formed by two Rs¹⁴'s being bonded to each other may be bonded to each other to form a ring.

As the substituent represented by Rs¹¹ and Rs¹² in Formula (SQ2), a group having active hydrogen is preferable, —OH, —SH, —COOH, —SO₃H, —NR^{X1}R^{X2}, —NHCOR^{X1}, —CONR^{X1}R^{X2}, —NHCONR^{X1}R^{X2}, —NHCOOR^{X1}, —NHSO₂R^{X1}, —B(OH)₂, or —PO(OH)₂ is more preferable, and —OH, —SH, or —NR^{X1}R^{X2} is still more preferable. R^{X1} and R^{X2} each independently represent a hydrogen atom or a substituent. Examples of the substituent R^{X1} and R^{X2} include an alkyl group, an aryl group, and a heteroaryl group. Among these, an alkyl group is preferable.

Examples of the substituent represented by Rs¹³ and Rs¹⁴ in Formula (SQ2) include the above-described substituent T.

In Formula (SQ2), Rs²¹ to Rs²⁴ each independently represent an alkyl group, an aryl group, or a heteroaryl group. The number of carbon atoms in the alkyl group is preferably 1 to 20, more preferably 1 to 15, and still more preferably 1 to 8. The alkyl group may be linear, branched, or cyclic and is preferably linear or branched. The number of carbon atoms in the aryl group is preferably 6 to 30, more preferably 6 to 20, and still more preferably 6 to 12. The heteroaryl group is preferably a monocyclic or fused heteroaryl group including 2 to 8 rings, and more preferably a monocyclic or fused heteroaryl group including 2 to 4 rings. The number of heteroatoms forming the ring of the heteroaryl group is preferably 1 to 3. It is preferable that the heteroatoms forming the ring of the heteroaryl group are a nitrogen atom, an oxygen atom, or a sulfur atom. It is preferable that the heteroaryl group is a 5- or 6-membered ring. The number of carbon atoms forming the ring of the heteroaryl group is preferably 3 to 30, more preferably 3 to 18, and still more preferably 3 to 12. The alkyl group, the aryl group, and the heteroaryl group may have a substituent or may be unsubstituted. Examples of the substituent include the substituents described above regarding the substituent T.

In Formula (SQ2), nₛ₁₁ and nₛ₁₂ each independently represent an integer of 0 to 3 and preferably an integer of 0 to 2.

In Formula (SQ2), in a case where nₛ₁₁ represents 2 or more, two Rs¹³'s may be bonded each other to form a ring. In a case where nₛ₁₂ represents 2 or more, two Rs¹⁴'s may be bonded to each other to form a ring. It is preferable that a linking group for forming the ring is a divalent linking group selected from the group consisting of —CO—, —O—, —NH—, an alkylene group having 1 to 10 carbon atoms, and a combination thereof. The alkylene group as the linking group may be unsubstituted or may have a substituent. Examples of the substituent include the above-described substituent T.

In Formula (SQ2), Rs²¹ and Rs²², Rs²³ and Rs²⁴, Rs²¹ and Rs¹³, Rs²² and Rs¹³, Rs²³ and Rs¹⁴, or Rs²⁴ and Rs¹⁴ may be bonded to each other to form a ring. In addition, in a case where two Rs¹³'s are bonded to each other to form a ring, Rs²¹ and a ring formed by two Rs¹³'s being bonded to each other may be further bonded to each other to form a ring. In addition, in a case where two Rs¹⁴'s are bonded to each other to form a ring, Rs²³ and a ring formed by two Rs¹⁴'s being bonded to each other may be further bonded to each other to form a ring. It is preferable that a linking group for forming the ring is a divalent linking group selected from the group consisting of —CO—, —O—, —NH—, an alkylene group having 1 to 10 carbon atoms, and a combination thereof. The alkylene group as the linking group may be unsubstituted or may have a substituent. Examples of the substituent include the above-described substituent T. In a case where Rs²¹ and a ring formed by two Rs¹³'s being bonded to each other are further bonded to each other to form a ring, the ring has, for example, the following structure. In the following formula, A1 represents a ring formed by two Rs¹³'s being bonded to each other, A2 represents a ring formed by the ring A1 and Rs²² being bonded to each other, Rs²² represents an alkyl group, an aryl group, or a heteroaryl group, Rs¹¹ and Rs¹³ represent a hydrogen atom or a substituent, and * represents a direct bond. The same can be applied to a case where Rs²³ and a ring formed by two Rs¹⁴'s being bonded to each other are further bonded to each other to form a ring.

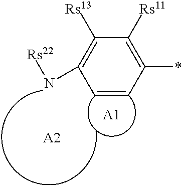

Specific examples of the squarylium compound include compounds described in Examples described below. In addition, examples of the squarylium compound include a compound described in paragraphs “0044” to “0049” of JP2011-208101A, a compound described in paragraphs “0060” and “0061” of JP6065169B, a compound described in paragraph “0040” of WO2016/181987A, a compound described in WO2013/133099A, a compound described in WO2014/088063A, a compound described in JP2014-126642A, a compound described in JP2016-146619A, a compound described in JP2015-176046A, a compound described in JP2017-025311A, a compound described in WO2016/154782A, a compound described in JP5884953B, a compound described in JP6036689B, a compound described in JP5810604B, and a compound described in JP2017-068120A, the contents of which are incorporated herein by reference.

As the cyanine compound, a compound represented by Formula (Cy1) is preferable.

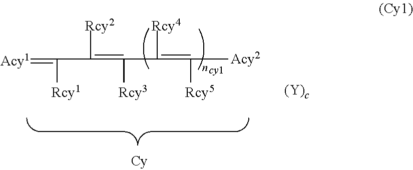

Rcy¹ to Rcy⁵ each independently represent a hydrogen atom or a substituent, and two of Rcy¹ to Rcy⁵ may be bonded to each other to form a ring. n_{cy1} represents an integer of 0 to 2, and in a case where n_{cy1} represents 2, a plurality of Rcy⁴'s and a plurality of Rcy⁵'s may be the same as or different from each other, respectively. Acy¹ and Acy² each independently represent an aryl group or a heterocyclic group. In a case where a site represented by Cy in the formula is a cation site, Y represents a counter anion, and c represents the number of Y's for balancing charge. In a case where a site represented by Cy in the formula is an anion site, Y represents a counter cation, and c represents the number of Y's for balancing charge. In a case where charge of a site represented by Cy in the formula is neutralized in a molecule, c represents 0.

Rcy¹ to Rcy⁵ each independently represent a hydrogen atom or a substituent. Examples of the substituent include the above-described substituent T. In Formula (Cy1), two of Rcy¹ to Rcy⁵ may be bonded to each other to form a ring. It is preferable that a linking group for forming the ring is a divalent linking group selected from the group consisting of —CO—, —O—, —NH—, an alkylene group having 1 to 10 carbon atoms, and a combination thereof. The alkylene group as the linking group may be unsubstituted or may have a substituent. Examples of the substituent include the above-described substituent T.

n_{cy1} represents an integer of 0 to 2 and preferably 0 or 1. In a case where n_{cy1} represents 2, a plurality of Rcy⁴'s may be the same as or different from each other and a plurality of Rcy⁵'s may be the same as or different from each other.

The number of carbon atoms in the aryl group represented by Acy¹ and Acy² is preferably 6 to 48, more preferably 6 to 22, and still more preferably 6 to 12. It is preferable that the heterocyclic group represented by Acy¹ and Acy² is a 5- or 6-membered heterocyclic group. In addition, the heterocycle is preferably a monocyclic or fused heterocyclic group including 2 to 8 rings, more preferably a monocyclic or fused heterocyclic group including 2 to 4 rings, still more preferably a monocyclic or fused heterocyclic group including 2 or 3 rings, and still more preferably a monocyclic or fused heterocyclic group including 2 rings. Examples of a heteroatom included in the ring of the heterocyclic group include a nitrogen atom, an oxygen atom, and a sulfur atom. Among these, an oxygen atom or a sulfur atom is preferable. The number of heteroatoms forming the ring of the heterocyclic group is preferably 1 to 3 and more preferably 1 or 2. The group represented by Acy¹ and Acy² may have a substituent. Examples of the substituent include the above-described substituent T.

In a case where a site represented by Cy in Formula (Cy1) is a cation site, Y represents a counter anion, and c represents the number of Y's for balancing charge. Examples of the counter anion include a halogen ion (Cl⁻, Br⁻, I⁻), a p-toluenesulfonate ion, an ethyl sulfate ion, PF₆⁻, BF₄⁻ or ClO₄⁻, a tris(halogenoalkylsulfonyl)methide anion (for example, (CF₃SO₂)₃C⁻), a di(halogenoalkylsulfonyl)imide anion (for example, (CF₃SO₂)₂N⁻), and a tetracyanoborate anion.

In a case where a site represented by Cy in Formula (Cy1) is an anion site, Y represents a counter cation, and c represents the number of Y's for balancing charge. Examples of the counter cation include an alkali metal ion (for example, Li⁺, Na⁺, or K⁺), an alkali earth metal ion (Mg²⁺, Ca²⁺, Ba²⁺, or Sr²⁺), a transition metal ion (for example, Ag⁺, Fe²⁺, Co²⁺, Ni²⁺, Cu²⁺, or Zn²⁺), other metal ions (for example, Al³⁺), an ammonium ion, a triethylammonium ion, a tributylammonium ion, a pyridinium ion, a tetrabutylammonium ion, a guanidinium ion, a tetramethylguanidinium ion, and a diazabicycloundecenium ion.

In a case where charge of a site represented by Cy in Formula (Cy1) is neutralized in a molecule, Y is not present. That is, c represents 0.

Specific examples of the cyanine compound include compounds described in Examples described below. In addition, examples of the cyanine compound include a compound described in paragraphs “0044” and “0045” of JP2009-108267A, a compound described in paragraphs “0026” to “0030” of JP2002-194040, a compound described in JP2015-172004A, a compound described in JP2015-172102A, a compound described in JP2008-088426A, and a compound described in JP2017-031394A, the contents of which are incorporated herein by reference.

(Croconium Compound)

It is preferable that the croconium compound is a compound represented by the following Formula (Cr1).

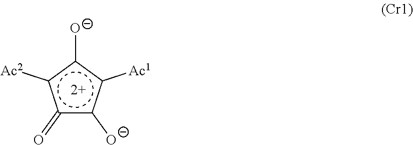

In the formulae, Ac¹ and Ac² each independently represent an aryl group, a heterocyclic group, or a group represented by Formula (Ac-1).

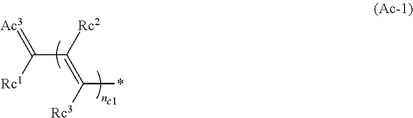

In the formula, * represents a direct bond.

Rc¹ to Rc³ each independently represent a hydrogen atom or an alkyl group.

Ac³ represents a heterocyclic group.

n_{c1} represents an integer of 0 or more.

Rc¹ and Rc² may be bonded to each other to form a ring.

Rc¹ and Ac³ may be bonded to each other to form a ring.

Rc² and Rc³ may be bonded to each other to form a ring.

In a case where n_{c1} represents 2 or more, a plurality of Rc²'s may be the same as or different from each other and a plurality of Rc³'s may be the same as or different from each other.

The number of carbon atoms in the aryl group represented by Ac¹ and Ac² is preferably 6 to 48, more preferably 6 to 22, and still more preferably 6 to 12.

It is preferable that the heterocyclic group represented by Ac¹, Ac², and Ac³ is a 5- or 6-membered heterocyclic group. In addition, the heterocycle is preferably a monocyclic or fused heterocyclic group including 2 to 8 rings, more preferably a monocyclic or fused heterocyclic group including 2 to 4 rings, still more preferably a monocyclic or fused heterocyclic group including 2 or 3 rings, and still more preferably a monocyclic or fused heterocyclic group including 2 rings. Examples of a heteroatom included in the ring of the heterocyclic group include a nitrogen atom, an oxygen atom, and a sulfur atom. Among these, a nitrogen atom or a sulfur atom is preferable. The number of heteroatoms forming the ring of the heterocyclic group is preferably 1 to 3 and more preferably 1 or 2.

Rc¹ to Rc³ in Formula (Ac-1) each independently represent a hydrogen atom or an alkyl group. The number of carbon atoms in the alkyl group represented by Rc¹ to Rc³ is preferably 1 to 20, more preferably 1 to 15, and still more preferably 1 to 8. The alkyl group may be linear, branched, or cyclic and is preferably linear or branched. It is preferable that Rc¹ to Rc³ represent a hydrogen atom.

n_{c1} in Formula (Ac-1) represents an integer of 0 or more. n_{c1} represents preferably an integer of 0 to 2, more preferably 0 or 1, and still more preferably 1.

In Formula (Ac-1), Rc¹ and Rc² may be bonded to each other to form a ring, Rc¹ and Ac³ may be bonded to each other to form a ring, and Rc² and Rc³ may be bonded to each other to form a ring. It is preferable that a linking group for forming the ring is a divalent linking group selected from the group consisting of —CO—, —O—, —NH—, an alkylene group having 1 to 10 carbon atoms, and a combination thereof. The alkylene group as the linking group may be unsubstituted or may have a substituent. Examples of the substituent include the above-described substituent T.

In Formula (Cr1), it is preferable that the group represented by Ac¹ and Ac² has a substituent. Examples of the substituent include the above-described substituent T.

In Formula (Cr1), it is preferable that Ac¹ and Ac² each independently represent an aryl group or a heterocyclic group, or it is preferable that Ac¹ and Ac² each independently represent a group represented by Formula (Ac-1).

As shown below, cations in Formula (Cr1) are present without being localized.

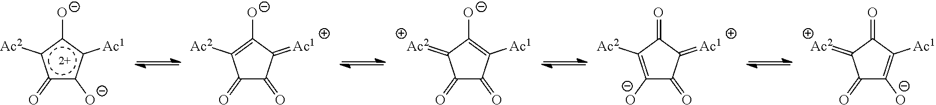

Specific examples of the croconium compound include a compound described below in Examples. In addition, examples of the croconium compound include a compound described in JP1993-155145A (JP-H5-155145A) and a compound described in JP2007-031644A, the contents of which are incorporated herein by reference.

It is preferable that the iminium compound is a compound represented by the following Formula (Im).

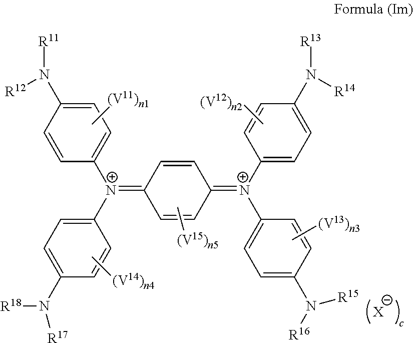

In the formula, R¹¹ to R¹⁸ each independently represent an alkyl group or an aryl group, V¹¹ to V¹⁵ each independently represent an alkyl group, an aryl group, a halogen atom, an alkoxy group, or a cyano group, X represents a counter anion, c represents the number of X's for balancing charge, and n1 to n5 each independently 0 to 4.

R¹¹ to R¹⁸ each independently represent an alkyl group or an aryl group. The number of carbon atoms in the alkyl group is preferably 1 to 20, more preferably 1 to 12, and still more preferably 1 to 8. The alkyl group may be linear, branched, or cyclic and is preferably linear or branched. The number of carbon atoms in the aryl group is preferably 6 to 25, more preferably 6 to 15, and still more preferably 6 to 12. The alkyl group and the aryl group may have a substituent or may be unsubstituted. Examples of the substituent include the groups described regarding the substituent T.

V¹¹ to V¹⁵ each independently represent an alkyl group, an aryl group, a halogen atom, an alkoxy group, or a cyano group. Examples of the halogen atom include a fluorine atom, a chlorine atom, a bromine atom, and an iodine atom. The number of carbon atoms in the alkyl group is preferably 1 to 20, more preferably 1 to 12, and still more preferably 1 to 8. The alkyl group may be linear, branched, or cyclic and is preferably linear or branched and more preferably linear. The number of carbon atoms in the aryl group is preferably 6 to 25, more preferably 6 to 15, and still more preferably 6 to 12. The number of carbon atoms in the alkoxy group is preferably 1 to 20, more preferably 1 to 12, and still more preferably 1 to 8. The alkoxy group may be linear, branched, or cyclic and is preferably linear or branched and more preferably linear.

n1 to n5 each independently 0 to 4. n1 to n4 represents preferably 0 to 2 and more preferably 0 or 1. n5 represents preferably 0 to 3 and more preferably 0 to 2.

X represents a counter anion. Examples of the counter anion include a halogen ion (Cl⁻, Br⁻, I⁻), a p-toluenesulfonate ion, an ethyl sulfate ion, PF₆⁻, BF₄⁻ or ClO₄⁻, a tris(halogenoalkylsulfonyl)methide anion (for example, (CF₃SO₂)₃C⁻), a di(halogenoalkylsulfonyl)imide anion (for example, (CF₃SO₂)₂N⁻), and a tetracyanoborate anion.

c represents the number of X's for balancing charge, for example, preferably 2.

Examples of the iminium compound include a compound described in JP2008-528706A, a compound described in JP2012-012399A, and a compound described in JP2007-092060A, the contents of which are incorporated herein by reference.

As the near infrared absorber, a commercially available product can also be used. Examples of a commercially available product of the near infrared absorber include SDO-C33 (manufactured by Arimoto Chemical Co., Ltd.); EXCOLOR IR-14, EXCOLOR IR-10A, EXCOLOR TX-EX-801B, and EXCOLOR TX-EX-805K (manufactured by Nippon Shokubai Co., Ltd.); Shigenox NIA-8041, Shigenox NIA-8042, Shigenox NIA-814, Shigenox NIA-820, and Shigenox NIA-839 (manufactured by Hakkol Chemical Co., Ltd.); Epolite V-63, Epolight 3801, and Epolight3036 (manufactured by Epolin Inc.); PRO-JET 825LDI (manufactured by Fujifilm Corporation); NK-3027 and NK-5060 (manufactured by Hayashibara Co., Ltd.); and YKR-3070 (manufactured by Mitsui Chemicals, Inc.).

The content of the near infrared absorber is preferably 3 mass % or higher, more preferably 5 mass % or higher, still more preferably 8 mass % or higher, still more preferably 10 mass % or higher, still more preferably 15 mass % or higher, and still more preferably 20 mass % or higher with respect to the total solid content of the photosensitive composition. The upper limit is preferably 60 mass % or lower, more preferably 55 mass % or lower, still more preferably 50 mass % or lower, still more preferably 45 mass % or lower, and still more preferably 40 mass % or lower.

In addition, In a case where the photosensitive composition according to the embodiment of the present invention is used as a photosensitive composition for a near infrared cut filter, from the viewpoints of the thickness of a film used and near infrared blocking properties, the content of the near infrared absorber is preferably 5 mass % or higher, more preferably 10 mass % or higher, still more preferably 15 mass % or higher, and still more preferably 20 mass % or higher with respect to the total solid content of the photosensitive composition. From the viewpoint of pattern formability, the upper limit is preferably 60 mass % or lower, more preferably 55 mass % or lower, and still more preferably 50 mass % or lower.

In addition, in a case where the photosensitive composition according to the embodiment of the present invention is used as a photosensitive composition for a near infrared transmitting filter, from the viewpoints of the thickness of a film used and near infrared blocking properties, the content of the near infrared absorber is preferably 3 mass % or higher, more preferably 5 mass % or higher, still more preferably 8 mass % or higher, still more preferably 10 mass % or higher, still more preferably 15 mass % or higher with respect to the total solid content of the photosensitive composition. From the viewpoint of pattern formability, the upper limit is preferably 50 mass % or lower, more preferably 45 mass % or lower, and still more preferably 40 mass % or lower.

In the present invention, as the near infrared absorber one kind may be used alone, or two or more kinds may be used. In a case where two or more near infrared absorbers are used, it is preferable that the total content of the two or more near infrared absorbers is in the above-described range.

(Coloring Material that Allows Transmission of Near Infrared Light and Blocks Visible Light)

The curable composition according to the embodiment of the present invention may also include the coloring material that allows transmission of near infrared light and blocks visible light (hereinafter, also referred to as “coloring material that blocks visible light”).

In the present invention, it is preferable that the coloring material that blocks visible light is a coloring material that absorbs light in a wavelength range of violet to red. In addition, in the present invention, it is preferable that the coloring material that blocks visible light is a coloring material that blocks light in a wavelength range of 450 to 650 nm. In addition, it is preferable that the coloring material that blocks visible light is a coloring material that allows transmission of light in a wavelength range of 900 to 1300 nm.

In the present invention, it is preferable that the coloring material that blocks visible light satisfies at least one of the following requirement (1) or (2).

(1): The coloring material that blocks visible light includes two or more chromatic colorants, and a combination of the two or more chromatic colorants forms black.

(2): The coloring material includes an organic black colorant.

Examples of the chromatic colorant include a red colorant, a green colorant, a blue colorant, a yellow colorant, a violet colorant, and an orange colorant. As the chromatic colorant, a pigment or a dye may be used. It is preferable that the chromatic colorant is a pigment. An average particle size (r) of the pigment satisfies preferably 20 nm≤r≤300 nm, more preferably 25 nm≤r≤250 nm, and still more preferably 30 nm≤r≤200 nm. “Average particle size” described herein denotes the average particle size of secondary particles which are aggregates of primary particles of the pigment. In addition, regarding a particle size distribution of the secondary particles of the pigment (hereinafter, simply referred to as “particle size distribution”) which can be used, secondary particles having a particle size of (average particle size±100) nm account for preferably 70 mass % or higher and more preferably 80 mass % or higher in the pigment.

As the pigment, an organic pigment is preferable. Preferable examples of the organic pigment are as follows:

Color Index (C.I.) Pigment Yellow 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 117, 118, 119, 120, 123, 125, 126, 127, 128, 129, 137, 138, 139, 147, 148, 150, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 199, 213, and 214 (all of which are yellow pigments);

C.I. Pigment Orange 2, 5, 13, 16, 17:1, 31, 34, 36, 38, 43, 46, 48, 49, 51, 52, 55, 59, 60, 61, 62, 64, 71, and 73 (all of which are orange pigments);

C.I. Pigment Red 1, 2, 3, 4, 5, 6, 7, 9, 10, 14, 17, 22, 23, 31, 38, 41, 48:1, 48:2, 48:3, 48:4, 49, 49:1, 49:2, 52:1, 52:2, 53:1, 57:1, 60:1, 63:1, 66, 67, 81:1, 81:2, 81:3, 83, 88, 90, 105, 112, 119, 122, 123, 144, 146, 149, 150, 155, 166, 168, 169, 170, 171, 172, 175, 176, 177, 178, 179, 184, 185, 187, 188, 190, 200, 202, 206, 207, 208, 209, 210, 216, 220, 224, 226, 242, 246, 254, 255, 264, 270, 272, and 279 (all of which are red pigments);

C.I. Pigment Green 7, 10, 36, 37, 58, 59, 62, and 63 (all of which are green pigments);

C.I. Pigment Violet 1, 19, 23, 27, 32, 37, and 42 (all of which are violet pigments);

and

C.I. Pigment Blue 1, 2, 15, 15:1, 15:2, 15:3, 15:4, 15:6, 16, 22, 60, 64, 66, 79, and 80 (all of which are blue pigments).

Among these organic pigments, one kind may be used alone, or two or more kinds may be used in combination.

In addition, as the yellow pigment, a metal azo pigment including at least one anion selected from an azo compound represented by the following Formula (I) or an azo compound having a tautomeric structure of the azo compound represented by Formula (I), two or more metal ions, and a melamine compound can be used.

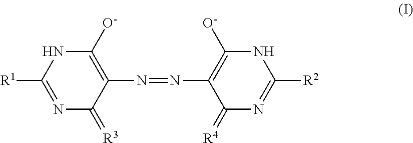

In the formula, R¹ and R² each independently represent OH or NR⁵R⁶, R³ and R⁴ each independently represent ═O or ═NR⁷, and R⁵ to R⁷ each independently represent a hydrogen atom or an alkyl group. The number of carbon atoms in the alkyl group represented by R⁵ to R⁷ is preferably 1 to 10, more preferably 1 to 6, and still more preferably 1 to 4. The alkyl group may be linear, branched, or cyclic and is preferably linear or branched and more preferably linear. The alkyl group may have a substituent. As the substituent, a halogen atom, a hydroxy group, an alkoxy group, a cyano group, or an amino group is preferable.

In Formula (I), it is preferable that R¹ and R² represent OH. In addition, it is preferable that R³ and R⁴ represent O.

It is preferable that the melamine compound in the metal azo pigment is a compound represented by the following Formula (II).

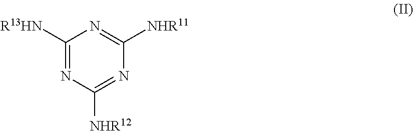

In the formula, R¹¹ to R¹³ each independently represent a hydrogen atom or an alkyl group. The number of carbon atoms in the alkyl group is preferably 1 to 10, more preferably 1 to 6, and still more preferably 1 to 4. The alkyl group may be linear, branched, or cyclic and is preferably linear or branched and more preferably linear. The alkyl group may have a substituent. As the substituent, a hydroxy group is preferable. It is preferable that at least one of R¹¹, . . . , or R¹³ represents a hydrogen atom, and it is more preferable that all of R¹¹ to R¹³ represent a hydrogen atom.

It is preferable that the above-described metal azo pigment is a metal azo pigment according to an aspect including at least one anion selected from an azo compound represented by Formula (I) or an azo compound having a tautomeric structure of the azo compound represented by Formula (I), metal ions including at least Zn²⁺ and Cu²⁺, and a melamine compound. In this aspect, the total content of Zn²⁺ and Cu²⁺ is preferably 95 to 100 mol %, more preferably 98 to 100 mol %, still more preferably 99.9 to 100 mol %, and still more preferably 100 mol % with respect to 1 mol of all the metal ions of the metal azo pigment. In addition, a molar ratio Zn²⁺:Cu²⁺ of Zn²⁺ to Cu²⁺ in the metal azo pigment is preferably 199:1 to 1:15, more preferably 19:1 to 1:1, and still more preferably 9:1 to 2:1. In addition, in this aspect, the metal azo pigment may further include a divalent or trivalent metal ion (hereinafter, also referred to as “metal ion Me1”) in addition to Zn²⁺ and Cu²⁺. Examples of the metal ion Me1 include Ni²⁺, Al³⁺, Fe²⁺, Fe³⁺, Co²⁺, Co³⁺, La³⁺, Ce³⁺, Pr³⁺, Nd²⁺, Nd³⁺, Sm²⁺, Sm³⁺, Eu²⁺, Eu³⁺, Gd³⁺, Tb³⁺, Dy³⁺, Ho³⁺, Yb²⁺, Yb³⁺, Er³⁺, Tm³⁺, Mg²⁺, Ca²⁺, Sr²⁺, Mn²⁺, Y³⁺, Sc³⁺, Ti²⁺, Ti³⁺, Nb³⁺, Mo²⁺, Mo³⁺, V²⁺, V³⁺, Zr²⁺, Zr³⁺, Cd²⁺, Cr³⁺, Pb²⁺, and Ba²⁺. Among these, at least one selected from Al³⁺, Fe²⁺, Fe³⁺, Co²⁺, Co³⁺, La³⁺, Ce³⁺, Pr³⁺, Nd³⁺, Sm³⁺, Eu³⁺, Gd³⁺, Tb³⁺, Dy³⁺, Ho³⁺, Yb³⁺, Er³⁺, Tm³⁺, Mg²⁺, Ca²⁺, Sr²⁺, Mn²⁺, or Y³⁺ is preferable, at least one selected from Al³⁺, Fe²⁺, Fe³⁺, Co²⁺, Co³⁺, La³⁺, Ce³⁺, Pr³⁺, Nd³⁺, Sm³⁺, Tb³⁺, Ho³⁺, or Sr²⁺ is more preferable, and at least one selected from Al³⁺, Fe²⁺, Fe³⁺, Co²⁺, or Co³⁺ is still more preferable. The content of the metal ion Me1 is preferably 5 mol % or lower, more preferably 2 mol % or lower, and still more preferably 0.1 mol % or lower with respect to 1 mol of all the metal ions of the metal azo pigment.

The details of the metal azo pigment can be found in paragraphs “0011” to “0062” and “0137” to “0276” of JP2017-171912A, paragraphs “0010” to “0062” and “0138” to “0295” of JP2017-171913A, paragraphs “0011” to “0062” and “0139” to “0190” of JP2017-171914A, and paragraphs “0010” to “0065” and “0142” to “0222” of JP2017-171915A, the contents of which are incorporated herein by reference.

In addition, as the red pigment, a compound having a structure in which an aromatic ring group into which a group having an oxygen atom, a sulfur atom, or a nitrogen atom bonded to an aromatic ring is introduced is bonded to a diketo pyrrolo pyrrole skeleton can also be used. This compound is preferably a compound represented by Formula (DPP1) and more preferably a compound represented by Formula (DPP2).

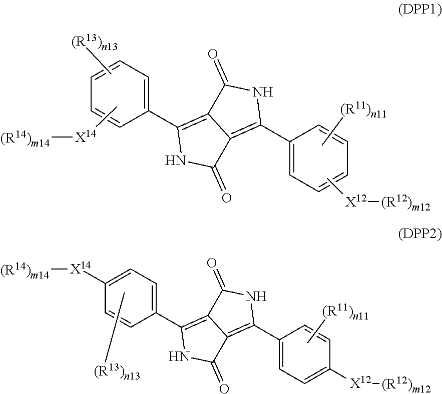

In the formula, R11 and R13 each independently represent a substituent, R¹² and R¹⁴ each independently represent a hydrogen atom, an alkyl group, an aryl group, or a heteroaryl group, n11 and n13 each independently represent an integer of 0 to 4, X¹² and X¹⁴ each independently represent an oxygen atom, a sulfur atom, or a nitrogen atom, in a case where X¹² represents an oxygen atom or a sulfur atom, m12 represents 1, in a case where X¹² represents a nitrogen atom, m12 represents 2, in a case where X¹⁴ represents an oxygen atom or a sulfur atom, m14 represents 1, and in a case where X¹⁴ represents a nitrogen atom, m14 represents 2. Specific preferable example of the substituent represented by R¹¹ and R¹³ include an alkyl group, an aryl group, a halogen atom, an acyl group, an alkoxycarbonyl group, an aryloxycarbonyl group, a heteroaryloxycarbonyl group, an amido group, a cyano group, a nitro group, a trifluoromethyl group, a sulfoxide group, and a sulfo group.

As the dye, well-known dyes can be used without any particular limitation. Examples of the dye include a dye such as a pyrazole azo dye, an anilino azo dye, a triarylmethane dye, an anthraquinone dye, an anthrapyridone dye, a benzylidene dye, an oxonol dye, a pyrazolotriazole azo dye, a pyridone azo dye, a cyanine dye, a phenothiazine dye, a pyrrolopyrazole azomethine dye, a xanthene dye, a phthalocyanine dye, a benzopyran dye, an indigo dye, and a pyrromethene dye. In addition, a polymer of the above-described dyes may be used. In addition, dyes described in JP2015-028144A and JP2015-034966A can also be used.

Examples of the organic black colorant include a bisbenzofuranone compound, an azomethine compound, a perylene compound, and an azo compound. Among these, a bisbenzofuranone compound or a perylene compound is preferable. Examples of the bisbenzofuranone compound include a compound described in JP2010-534726A, JP2012-515233A, and JP2012-515234A. For example, “Irgaphor Black” (manufactured by BASF SE) is available. Examples of the perylene compound include C.I. Pigment Black 31 and 32. Examples of the azomethine compound include compounds described in JP1989-170601A (JP-H1-170601A) and JP1990-034664A (JP-H2-034664A). For example, “CHROMOFINE BLACK A1103” (manufactured by Dainichiseika Color & Chemicals Mfg. Co., Ltd.) is available.

Examples of a preferable combination in the aspect (1) are as follows.

(1-1) An aspect in which the coloring material includes a red colorant and a blue colorant.

(1-2) An aspect in which the coloring material includes a red colorant, a blue colorant, and a yellow colorant.

(1-3) An aspect in which the coloring material includes a red colorant, a blue colorant, a yellow colorant, and a violet colorant.

(1-4) An aspect in which the coloring material includes a red colorant, a blue colorant, a yellow colorant, a violet colorant, and a green colorant.

(1-5) An aspect in which the coloring material includes a red colorant, a blue colorant, a yellow colorant, and a green colorant.

(1-6) An aspect in which the coloring material includes a red colorant, a blue colorant, and a green colorant.

(1-7) An aspect in which the coloring material includes a yellow colorant and a violet colorant.

In the aspect (2), it is preferable that the coloring material further includes a chromatic colorant. By using the organic black colorant in combination with a chromatic colorant, excellent spectral characteristics are likely to be obtained. Examples of the chromatic colorant which can be used in combination with the organic black colorant include a red colorant, a blue colorant, and a violet colorant. Among these, a red colorant or a blue colorant is preferable. In addition, regarding a mixing ratio between the chromatic colorant and the organic black colorant, the amount of the chromatic colorant is preferably 10 to 200 parts by mass and more preferably 15 to 150 parts by mass with respect to 100 parts by mass of the organic black colorant.

In a case where the photosensitive composition according to the embodiment of the present invention includes the coloring material that blocks visible light, the content of the coloring material that blocks visible light is preferably 3 mass % or higher, more preferably 4 mass % or higher, still more preferably 5 mass % or higher, and still more preferably 6 mass % or higher with respect to the total solid content of the photosensitive composition. The upper limit is preferably 55 mass % or lower, more preferably 50 mass % or lower, and still more preferably 45 mass % or lower.

In addition, the total content of the near infrared absorber and the coloring material that blocks visible light is preferably 5 mass % or higher, more preferably 7 mass % or higher, still more preferably 10 mass % or higher, and still more preferably 12 mass % or higher with respect to the total solid content of the photosensitive composition. The upper limit is preferably 60 mass % or lower, more preferably 55 mass % or lower, and still more preferably 50 mass % or lower.

In addition, the content of the coloring material that blocks visible light is preferably 3 parts by mass or more, more preferably 5 parts by mass or more, still more preferably 7 parts by mass or more, and still more preferably 10 parts by mass or more with respect to 100 parts by mass of the near infrared absorber. The upper limit is preferably 200 parts by mass or less, more preferably 190 parts by mass or less, and still more preferably 180 parts by mass or less.

<<Photoinitiator B>>

The photosensitive composition according to the embodiment of the present invention includes the photoinitiator B. Examples of the photoinitiator include a photoradical polymerization initiator and a photocationic polymerization initiator. The photoinitiator can be selected and used depending on the kind of the compound C described below. In a case where the radically polymerizable compound is used as the compound C, it is preferable that the photoradical polymerization initiator is used as the photoinitiator B. In a case where the cationically polymerizable compound is used as the compound C, it is preferable that the photocationic polymerization initiator is used as the photoinitiator B.

It is preferable that the photoinitiator B includes at least one compound selected from an alkylphenone compound, an acylphosphine compound, a benzophenone compound, a thioxanthone compound, a triazine compound, or an oxime compound, and it is more preferable that the photoinitiator B includes an oxime compound.

Examples of the alkylphenone compound include a benzyldimethylketal compound, an α-hydroxyalkylphenone compound, and an α-aminoalkylphenone compound.

Examples of the benzyldimethylketal compound include 2,2-dimethoxy-2-phenylacetophenone. Examples of a commercially available product include IRGACURE-651 (manufactured by BASF SE).

Examples of the α-hydroxyalkylphenone compound include 1-hydroxy-cyclohexyl-phenyl-ketone, 2-hydroxy-2-methyl-1-phenyl-propane-1-one, 1-[4-(2-hydroxyethoxy)-phenyl]-2-hydroxy-2-methyl-1-propane-1-one, and 2-hydroxy-1-{4-[4-(2-hydroxy-2-methyl-propionyl)-benzyl]phenyl}-2-methyl-propane-1-one. Examples of a commercially available product of the α-hydroxyalkylphenone compound include IRGACURE-184, DAROCUR-1173, IRGACURE-500, IRGACURE-2959, and IRGACURE-127 (all of which are manufactured by BASF SE).

Examples of the α-aminoalkylphenone compound include 2-methyl-1-(4-methylthiophenyl)-2-morpholinopropan-1-one, 2-benzyl-2-dimethylamino-1-(4-morpholinophenyl)-1-butanone, and 2-dimethylamino-2-[(4-methylphenyl)methyl]-1-[4-(4-morpholinyl)phenyl]-1-butanone. Examples of a commercially available product of the α-aminoalkylphenone compound include IRGACURE-907, IRGACURE-369, and IRGACURE-379 (all of which are manufactured by BASF SE).

Examples of the acylphosphine compound include 2,4,6-trimethylbenzoyl-diphenyl-phosphine oxide and bis(2,4,6-trimethylbenzoyl)-phenylphosphine oxide. Examples of a commercially available product of the acylphosphine compound include IRGACURE-819 and IRGACURE-TPO (all of which are manufactured by BASF SE).

Examples of the benzophenone compound include benzophenone, methyl o-benzoylbenzoate, 4-phenylbenzophenone, 4-benzoyl-4′-methyldiphenyl sulfide, 3,3′,4,4′-tetra(t-butyl peroxy carbonyl)benzophenone, and 2,4,6′-trimethyl benzophenone.

Examples of the thioxanthone compound include 2-isopropylthioxanthone, 4-isopropylthioxanthone, 2,4-diethylthioxanthone, 2,4-dichlorothioxanthone, and 1-chloro-4-propoxythioxanthone.

Examples of the triazine compound include 2,4-bis(trichloromethyl)-6-(4-methoxyphenyl)-1,3,5-triazine, 2,4-bis(trichloromethyl)-6-(4-methoxynaphthyl)-1,3,5-triazine, 2,4-bis(trichloromethyl)-6-piperonyl-1,3,5-triazine, 2,4-bis(trichloromethyl)-6-(4-methoxyscrew)-1,3,5-triazine, 2,4-bis(trichloromethyl)-6-[2-(5-methylfuran-2-yl)ethenyl]-1,3,5-triazine, 2,4-bis(trichloromethyl)-6-[2-(furan-2-yl)ethenyl]-1,3,5-triazine, 2,4-bis(trichloromethyl)-6-[2-(4-di ethylamino-2-methyl phenyl)ethenyl]-1,3,5-triazine, and 2,4-bis(trichloromethyl)-6-[2-(3,4-dimethoxypheny)ethenyl]-1,3,5-triazine.

Examples of the oxime compound include a compound described in JP2001-233842A, a compound described in JP2000-080068A, a compound described in JP2006-342166A, a compound described in J. C. S. Perkin II (1979, pp. 1653 to 1660), a compound described in J. C. S. Perkin II (1979, pp. 156 to 162), a compound described in Journal of Photopolymer Science and Technology (1995, pp. 202 to 232), a compound described in JP2000-066385A, a compound described in JP2000-080068A, a compound described in JP2004-534797A, a compound described in JP2006-342166A, a compound described in JP2017-019766A, a compound described in JP6065596B, a compound described in WO2015/152153A, and a compound described in WO2017/051680A. Specific examples of the oxime compound include 3-benzoyloxyiminobutane-2-one, 3-acetoxyiminobutane-2-one, 3-propionyloxyiminobutane-2-one, 2-acetoxyiminopentane-3-one, 2-acetoxyimino-1-phenylpropane-1-one, 2-benzoyloxyimino-1-phenylpropane-1-one, 3-(4-toluene sulfonyloxy)iminobutane-2-one, and 2-ethoxycarbonyloxyimino-1-phenylpropane-1-one. Examples of a commercially available product of the oxime compound include IRGACURE-OXE01, IRGACURE-OXE02, IRGACURE-OXE03, or IRGACURE-OXE04 (all of which are manufactured by BASF SE), TR-PBG-304 (manufactured by Changzhou Tronly New Electronic Materials Co., Ltd.), and ADEKA OPTOMER N-1919 (manufactured by Adeka Corporation, a photopolymerization initiator 2 described in JP2012-014052A). As the oxime compound, a compound having no colorability or a compound having high transparency that is not likely to discolor other components can also be preferably used. Examples of a commercially available product of the oxime compound include ADEKA ARKLS NCI-730, NCI-831, and NCI-930 (all of which are manufactured by Adeka Corporation).

In the present invention, an oxime compound having a fluorene ring can also be used as the photoinitiator B. Specific examples of the oxime compound having a fluorene ring include a compound described in JP2014-137466A. The content of this specification is incorporated herein by reference.

In the present invention, an oxime compound having a fluorine atom can also be used as the photoinitiator B. Specific examples of the oxime compound having a fluorine atom include a compound described in JP2010-262028A, Compound 24 and 36 to 40 described in JP2014-500852A, and Compound (C-3) described in JP2013-164471A. The content of this specification is incorporated herein by reference.

In the present invention, as the photoinitiator B, an oxime compound having a nitro group can be used. It is preferable that the oxime compound having a nitro group is a dimer. Specific examples of the oxime compound having a nitro group include compounds described in paragraphs “0031” to “0047” of JP2013-114249A and paragraphs “0008” to “0012” and “0070” to “0079” of JP2014-137466A, compounds described in paragraphs “0007” to 0025” of JP4223071B, and ADEKA ARKLS NCI-831 (manufactured by Adeka Corporation).

In the present invention, as the photoinitiator B, an oxime compound having a benzofuran skeleton can also be used. Specific examples include OE-01 to OE-75 described in WO2015/036910A.

Hereinafter, specific examples of the oxime compound which are preferably used in the present invention are shown below, but the present invention is not limited thereto.

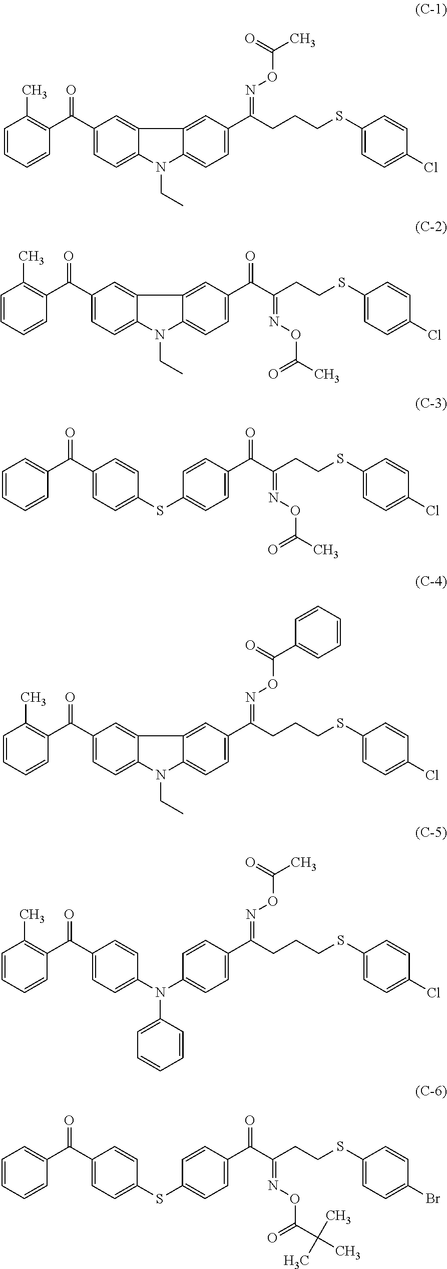 [SMILES: CCn1c2ccc(C(=O)c3ccccc3C)cc2c2cc(/C(CCCSc3ccc(Cl)cc3)=N/OC(C)=O)ccc21 ; CCn1c2ccc(C(=O)/C(CCSc3ccc(Cl)cc3)=N/OC(C)=O)cc2c2cc(C(=O)c3ccccc3C)ccc21 ; CC(=O)O/N=C(\CCSc1ccc(Cl)cc1)C(=O)c1ccc(Sc2ccc(C(=O)c3ccccc3)cc2)cc1 ; CCn1c2ccc(C(=O)c3ccccc3C)cc2c2cc(/C(CCCSc3ccc(Cl)cc3)=N/OC(=O)c3ccccc3)ccc21 ; CC(=O)O/N=C(\CCCSc1ccc(Cl)cc1)c1ccc(N(c2ccccc2)c2ccc(C(=O)c3ccccc3C)cc2)cc1 ; CC(C)(C)C(=O)O/N=C(\CCSc1ccc(Br)cc1)C(=O)c1ccc(Sc2ccc(C(=O)c3ccccc3)cc2)cc1]

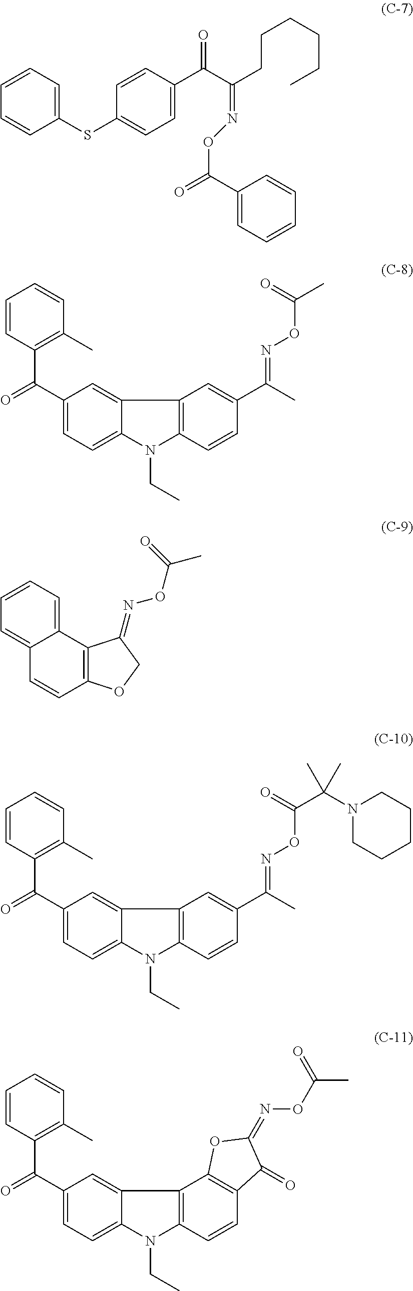

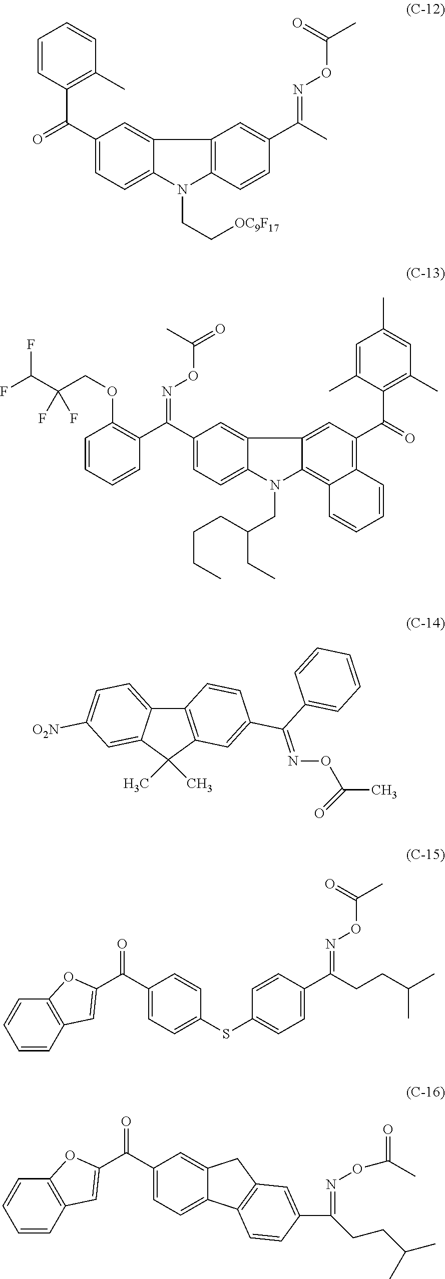

In the present invention, as the photoinitiator B, a photoradical polymerization initiator having two functional groups or three or more functional groups may be used. By using this photoradical polymerization initiator, two or more radicals are generated from one molecule of the photoradical polymerization initiator. Therefore, excellent sensitivity can be obtained. In addition, in a case where a compound having an asymmetric structure is used, crystallinity deteriorates, solubility in a solvent or the like is improved, precipitation is not likely to occur over time, and temporal stability of the photosensitive composition can be improved. Specific examples of the photoradical polymerization initiator having two functional groups or three or more functional groups include a dimer of an oxime compound described in JP2010-527339A, JP2011-524436A, WO2015/004565A, paragraphs “0412” to “0417” of JP2016-532675A, or paragraphs “0039” to “0055” of WO2017/033680A, a compound (E) and a compound (G) described in JP2013-522445A, Cmpd 1 to 7 described in WO2016/034963A, an oxime ester photoinitiator described in paragraph “0007” of JP2017-523465A, a photoinitiator described in paragraphs “0020” to “0033” of JP2017-167399A, and a photopolymerization initiator (A) described in paragraphs “0017” to “0026” of JP2017-151342A.

In the present invention, a pinacol compound can also be used as the photoinitiator B. Examples of the pinacol compound include benzopinacol, 1,2-dimethoxy-1,1,2,2-tetraphenylethane, 1,2-diethoxy-1,1,2,2-tetraphenylethane, 1,2-diphenoxy-1,1,2,2-tetraphenylethane, 1,2-dimethoxy-1,1,2,2-tetra(4-methylphenyl)ethane, 1,2-diphenoxy-1,1,2,2-tetra(4-methoxyphenyl)ethane, 1,2-bis(trimethylsilloxy)-1,1,2,2-tetraphenylethane, 1,2-bis(triethylsilloxy)-1,1,2,2-tetraphenylethane, 1,2-bis(t-butyldimethylsilloxy)-1,1,2,2-tetraphenylethane, 1-hydroxy-2-trimethylsilloxy-1,1,2,2-tetraphenylethane, 1-hydroxy-2-triethylsilloxy-1,1,2,2-tetraphenylethane, and 1-hydroxy-2-t-butyldimethylsilloxy-1,1,2,2-tetraphenylethane. In addition, the details of the pinacol compound can be found in JP2014-523939A and JP2014-521772A, the contents of which are incorporated herein by reference.

In the present invention, it is preferable that the photoinitiator B includes the photoinitiator b1 that satisfies the following condition 1. In this aspect, a large amount of an active species such as a radical is likely to be instantaneously generated by pulse exposure, and the desired effects of the present invention is likely to be more significant.

Condition 1: after a propylene glycol monomethyl ether acetate solution including 0.035 mmol/L of the photoinitiator b1 is exposed to pulses of light having a wavelength of 355 nm under conditions of a maximum instantaneous illuminance of 375000000 W/m², pulse duration: 8 nanoseconds, and frequency: 10 Hz, a quantum yield q₃₅₅ is 0.05 or higher.

The quantum yield q₃₅₅ of the photoinitiator b1 is preferably 0.10 or higher, more preferably 0.15 or higher, still more preferably 0.25 or higher, still more preferably 0.35 or higher, and still more preferably 0.45 or higher. In addition, the active species generated from the photoinitiator B due to the exposure under the condition 1 is a radical.

In the this specification, the quantum yield q₃₅₅ of the photoinitiator b1 is a value obtained by dividing the number of decomposed molecules in the photoinitiator b1 after the pulse exposure under the condition 1 by the number of absorbed photons in the photoinitiator b1. Regarding the number of absorbed photons, the number of irradiated photons is obtained from the exposure time during the pulse exposure under the above-described condition 1, an absorbance at 355 nm before and after exposure is converted into a transmittance, and the number of irradiated photons is multiplied by (1-transmittance) to obtain the number of absorbed photons. Regarding the number of decomposed molecules, a decomposition rate of the photoinitiator b1 is obtained from the absorbance of the photoinitiator b1 after exposure, and the decomposition rate is multiplied by the number of molecules present in the photoinitiator b1 to obtain the number of decomposed molecules. In addition, regarding the absorbance of the initiator b1, a propylene glycol monomethyl ether acetate solution including 0.035 mmol/L of the photoinitiator b1 is put into an optical cell of 1 cm×1 cm×4 cm, and the absorbance of the photoinitiator b1 can be measured using a spectrophotometer. As the spectrophotometer, for example, HP8453 (manufactured by Agilent Technologies Inc.) can be used. Examples of the photoinitiator b1 that satisfies the above-described condition 1 include IRGACURE-OXE01, OXE02, and OXE03 (all of which are manufactured by BASF SE). In addition, a compound having the following structure can be preferably used as the photoinitiator b1 that satisfies the above-described condition 1. In particular, from the viewpoint of adhesiveness, IRGACURE-OXE01 and OXE02 are preferably used.

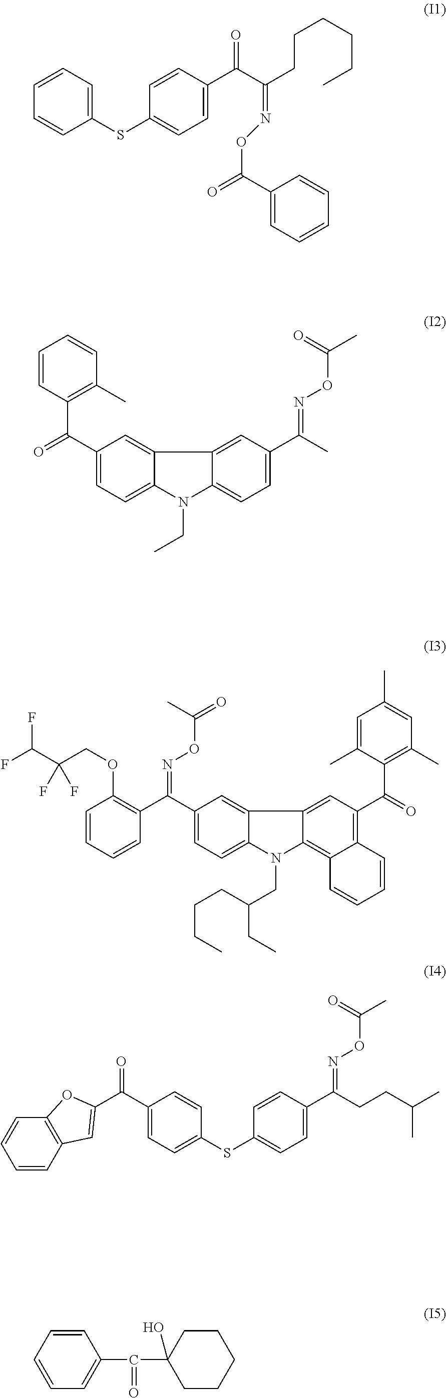 [SMILES: CCCCCC/C(=N/OC(=O)c1ccccc1)C(=O)c1ccc(Sc2ccccc2)cc1 ; CCn1c2ccc(C(=O)c3ccccc3C)cc2c2cc(/C(C)=N/OC(C)=O)ccc21 ; CCCCC(CC)Cn1c2ccc(/C(=N\OC(C)=O)c3ccccc3OCC(F)(F)C(F)F)cc2c2cc(C(=O)c3c(C)cc(C)cc3C)c3ccccc3c21 ; CC(=O)O/N=C(\CCC(C)C)c1ccc(Sc2ccc(C(=O)c3cc4ccccc4o3)cc2)cc1 ; O=C(c1ccccc1)C1(O)CCCCC1]

In addition, it is more preferable that the photoinitiator b1 satisfies the following condition 2.

Condition 2: after a film having a thickness of 1.0 μm and including 5 mass % of the photoinitiator b1 and 95 mass % of a resin is exposed to pulses of light having a wavelength of 265 nm under conditions of a maximum instantaneous illuminance of 375000000 W/m², pulse duration: 8 nanoseconds, and frequency: 10 Hz, a quantum yield q₂₆₅ is 0.05 or higher.

The quantum yield q₂₆₅ of the photoinitiator b1 is preferably 0.10 or higher, more preferably 0.15 or higher, still more preferably 0.20 or higher.

In this specification, the quantum yield q₂₆₅ of the photoinitiator b1 is a value obtained by dividing the number of decomposed molecules in the photoinitiator b1 per 1 cm² of the film after the pulse exposure under the condition 2 by the number of absorbed photons in the photoinitiator b1. Regarding the number of absorbed photons, the number of irradiated photons was obtained from the exposure time during the pulse exposure under the condition 2, and the number of irradiated photons per 1 cm² of the film was multiplied by (1-transmittance) to obtain the number of absorbed photons. Regarding the number of decomposed molecules in the photoinitiator b1 per 1 cm² of the film after exposure, a decomposition rate of the photoinitiator b1 is obtained from a change in the absorbance of the film before and after exposure is obtained, and the decomposition rate of the photoinitiator b1 is multiplied by the number of molecules present in the photoinitiator b1 per 1 cm² of the film. The weight of the film per 1 cm² of the film area is obtained by setting the film density as 1.2 g/cm³, and the number of molecules present in the photoinitiator b1 per 1 cm² of the film is obtained as “((Weight of Film per 1 cm² of Film×5 mass % (Content of PhotoInitiator b1)/Molecular Weight of PhotoInitiator b1)×6.02×10²³ (Avogadro's Number)”.

In addition, it is preferable that the photoinitiator b1 used in the present invention satisfies the following condition 3.

condition 3: after a film including 5 mass % of the photoinitiator b1 and a resin is exposed to one pulse of light having a wavelength in a wavelength range of 248 to 365 nm under conditions of a maximum instantaneous illuminance of 62/500,0000 W/m², pulse duration: 8 nanoseconds, and frequency: 10 Hz, an active species concentration in the film reaches 0.000000001 mmol or higher per 1 cm² of the film.

The active species concentration in the film under the condition 3 per 1 cm² of the film reaches preferably 0.000000005 mmol or higher, more preferably 0.00000001 mmol or higher, still more preferably 0.00000003 mmol or higher, and still more preferably 0.0000001 mmol or higher.

In this specification, the active species concentration in the above-described film is obtained by multiplying a quantum yield of the photoinitiator b1 with respect to the light having a measurement wavelength by (1-transmittance of film) to calculate a decomposition rate per number of incident photons and calculating the density of the photoinitiator b1 decomposed per 1 cm² of the film from “mol number of photons per one pulse”×“decomposition rate of photoinitiator b1 per number of incident photons”. In order to calculate the active species concentration, a value calculated assuming that the entirety of the photoinitiator b1 decomposed by light irradiation is an active species (that does not disappear during an intermediate reaction).

The resin used for the measurement under the condition 2 or 3 is not particularly limited as long as it has compatibility to the photoinitiator b1. For example, a resin (A) having the following structure is preferably used. A numerical value added to a repeating unit represents a molar ratio, a weight-average molecular weight is 40000, and a dispersity (Mn/Mw) is 5.0.

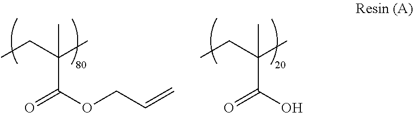

From the viewpoint of a high concentration of the active species generated, as the photoinitiator b1, an alkylphenone compound or an oxime compound is preferable, and an oxime compound is more preferable. In addition, as the photoinitiator b1, an initiator that is likely to cause two-photon absorption to occur is preferable. The two-photon absorption refers to an excitation process of simultaneously absorbing two photons.

The photoinitiator B used in the present invention may consist of only one photoinitiator or may include two or more photoinitiators. In a case where the photoinitiator B includes two or more photoinitiators, each of the initiators may be the photoinitiator b1 that satisfies the above-described condition 1. In addition, the photoinitiator B may include one or more photoinitiators b1 that satisfy the above-described condition 1 and one or more photoinitiators b2 that do not satisfy the above-described condition 1. From the viewpoint of easily generating a necessary amount of an active species, it is preferable that two or more initiators included in the photoinitiator B consist of only the photoinitiator b1 that satisfies the above-described condition 1. In addition, from the viewpoint of easily suppressing desensitization over time, it is preferable that two or more photoinitiators included in the photoinitiator B includes one or more photoinitiators b1 that satisfy the above-described condition 1 and one or more photoinitiators b2 that do not satisfy the above-described condition 1. Examples of the photoinitiator b2 that does not satisfy the above-described condition 1 include a pinacol compound such as benzopinacol.

From the viewpoint of easily adjusting the sensitivity, it is preferable that the photoinitiator B used in the present invention include two or more photoinitiators.

From the viewpoint of curing properties, it is preferable that the photoinitiator B used in the present invention satisfies the following condition 1a.

Condition 1a: after a propylene glycol monomethyl ether acetate solution including 0.035 mmol/L of a mixture is exposed to pulses of light having a wavelength of 355 nm under conditions of a maximum instantaneous illuminance of 375000000 W/m², pulse duration: 8 nanoseconds, and frequency: 10 Hz, a quantum yield q₃₅₅ is preferably 0.05 or higher, more preferably 0.10 or higher, still more preferably 0.15 or higher, still more preferably 0.25 or higher, still more preferably 0.35 or higher, and still more preferably 0.45 or higher, the mixture being obtained by mixing two or more photoinitiators at a ratio at which the photosensitive composition includes the two or more photoinitiators.

In addition, from the viewpoint of curing properties, it is preferable that the photoinitiator B used in the present invention satisfies the following condition 2a.

Condition 2a: after a film having a thickness of 1.0 μm and including 5 mass % of a mixture and 95 mass % of a resin is exposed to pulses of light having a wavelength of 265 nm under conditions of a maximum instantaneous illuminance of 375000000 W/m², pulse duration: 8 nanoseconds, and frequency: 10 Hz, a quantum yield q₂₆₅ is 0.05 or higher, more preferably 0.10 or higher, still more preferably 0.15 or higher, and still more preferably 0.20 or higher, the mixture being obtained by mixing two or more photoinitiators at a ratio at which the photosensitive composition includes the two or more photoinitiators.

In addition, from the viewpoint of curing properties, it is preferable that the photoinitiator B used in the present invention satisfies the following condition 3a.

Condition 3a: after a film including 5 mass % of a mixture and a resin is exposed to pulses of light having a wavelength in a wavelength range of 248 to 365 nm for 0.1 seconds under conditions of a maximum instantaneous illuminance of 62/500,0000 W/m², pulse duration: 8 nanoseconds, and frequency: 10 Hz, an active species concentration in the film reaches preferably 0.000000001 mmol or higher, more preferably 0.000000005 mmol or higher, still more preferably 0.00000001 mmol or higher, still more preferably 0.00000003 mmol or higher, and most preferably 0.0000001 mmol or higher per 1 cm² of the film, the mixture being obtained by mixing two or more photoinitiators at a ratio at which the photosensitive composition includes the two or more photoinitiators.

From the viewpoint of sensitivity, the content of the photoinitiator B is preferably 40 mass % or lower, more preferably 35 mass % or lower, and still more preferably 30 mass % or lower with respect to the total solid content of the photosensitive composition. From the viewpoint of pattern formability, the lower limit is preferably 0.1 mass % or higher, more preferably 0.5 mass % or higher, and still more preferably 1 mass % or higher. In addition, from the viewpoint of sensitivity, the content of the photoinitiator B is preferably 0.1 to 800 parts by mass with respect to 100 parts by mass of the compound C described below. The upper limit is preferably 700 parts by mass or less, more preferably 650 parts by mass or less, and still more preferably 600 parts by mass or less. From the viewpoint of pattern formability, the lower limit is preferably 0.5 parts by mass and more preferably 1 part by mass. In a case where the photosensitive composition according to the embodiment of the present invention includes two or more photoinitiators B, it is preferable that the total content of the two or more photoinitiators B is in the above-described range.

In addition, from the viewpoint of sensitivity, the content of the photoinitiator b1 is preferably 40 mass % or lower, more preferably 35 mass % or lower, and still more preferably 30 mass % or lower with respect to the total solid content of the photosensitive composition. From the viewpoint of pattern formability, the lower limit is preferably 0.1 mass % or higher, more preferably 0.5 mass % or higher, and still more preferably 1 mass % or higher. In addition, from the viewpoint of sensitivity, the content of the photoinitiator b1 is preferably 0.1 to 800 parts by mass with respect to 100 parts by mass of the compound C described below. The upper limit is preferably 700 parts by mass or less, more preferably 650 parts by mass or less, and still more preferably 600 parts by mass or less. From the viewpoint of pattern formability, the lower limit is preferably 0.5 parts by mass and more preferably 1 part by mass. In a case where the photosensitive composition according to the embodiment of the present invention includes two or more photoinitiators b1, it is preferable that the total content of the two or more photoinitiators b1 is in the above-described range.

<<Compound C>>

The photosensitive composition according to the embodiment of the present invention includes the compound C that is cured by reacting an active species generated from the photoinitiator B. Examples of the compound C include a polymerizable compound such as a radically polymerizable compound or a cationically polymerizable compound. Examples of the radically polymerizable compound include a compound having an ethylenically unsaturated bond group such as a vinyl group, a (meth)allyl group, or a (meth)acryloyl group. Examples of the cationically polymerizable compound include a compound having a cyclic ether group such as an epoxy group or an oxetanyl group.

The compound C may be a monomer (hereinafter, also referred to as “polymerizable monomer”) or a polymer (also referred to as “polymerizable polymer”. The molecular weight of the polymerizable monomer is preferably lower than 2000, more preferably 1500 or lower, and still more preferably 1000 or lower. The lower limit is preferably 100 or higher and more preferably 150 or higher. The weight-average molecular weight (Mw) of the polymerizable polymer is preferably 2000 to 2000000. The upper limit is preferably 1000000 or lower and more preferably 500000 or lower. The lower limit is preferably 3000 or higher and more preferably 5000 or higher. The polymerizable polymer can also be used as a resin described below.

In the present invention, a combination of a polymerizable monomer and a polymerizable polymer may be used as the compound C. By using a combination of a polymerizable monomer and a polymerizable polymer, a film having a smaller thickness can be easily formed. In a case where a combination of a polymerizable monomer and a polymerizable polymer is used, the content of the polymerizable monomer is preferably 0.1 to 2000 parts by mass, more preferably 0.5 to 1900 parts by mass, and still more preferably 1 to 1800 parts by mass with respect to 100 parts by mass of the polymerizable polymer.

In the present invention, the compound C is preferably a radically polymerizable compound and more preferably a radically polymerizable monomer. By exposing the radically polymerizable compound to pulses of light, a radical is generated from the radically polymerizable compound such that the radically polymerizable compound can be more efficiently cured, and a photosensitive composition having excellent curing properties can be obtained. In particular, in the case of the radically polymerizable monomer, a radical can be more effectively generated, and the radically polymerizable monomer can be more efficiently cured.

(Polymerizable Monomer)

The polymerizable monomer is preferably a polymerizable monomer having two or more functional groups, more preferably a polymerizable monomer having 2 to 15 functional groups, still more preferably a polymerizable monomer having 2 to 10 functional groups, and still more preferably a polymerizable monomer having 2 to 6 functional groups.

In addition, in the present invention, it is also preferable that a polymerizable monomer having a fluorene skeleton is used as the polymerizable monomer. It is presumed that, even in a case where a large amount of an active species such as a radical is instantaneously generated from the photoinitiator B due to pulse exposure, for example, a self-reaction in which polymerizable groups react with each other in the same molecule is not likely to occur in the polymerizable monomer having a fluorene skeleton. As a result, the polymerizable monomer can be efficiently cured by pulse exposure, and a film having a high crosslinking density or the like can be formed.

Examples of the polymerizable monomer having a fluorene skeleton include a compound having a partial structure represented by the following Formula (Fr).

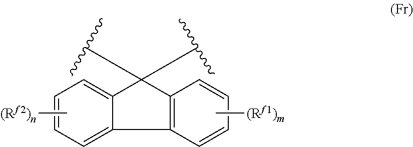

In the formula, a wave line represents a direct bond, R^{f1} and R^{f2} each independently represent a substituent, and m and n each independently represent an integer of 0 to 5. In a case where m represents 2 or more, m R^{f1}'s may be the same as or different from each other, or two R^{f1}'s among m R^{f1}'s may be bonded to each other to form a ring. In a case where n represents 2 or more, n R^{f2}'s may be the same as or different from each other, or two R^{f2}'s among n R^{f2}'s may be bonded to each other to form a ring. Examples of the substituent represented by R^{f1} and R^{f2} include a halogen atom, a cyano group, a nitro group, an alkyl group, an aryl group, a heteroaryl group, —OR^{f11}, —COR^{f12}, —COOR^{f13}, —OCOR^{f14}, —NR^{f15}R^{f16}, —NHCOR^{f17}, —CONR^{f18}R^{f19}, —NHCONR^{f20}R^{f21}, —NHCOOR^{f22}, —SR^{f23}, —SO₂R^{f24}, —SO₂OR^{f25}, —NHSO₂R^{f26}, and —SO₂NR^{f27}R^{f28}. R^{f11} to R^{f28} each independently represents a hydrogen atom, an alkyl group, an aryl group, or a heteroaryl group.

The polymerizable group value of the polymerizable monomer is preferably 2 mmol/g or higher, more preferably 6 mmol/g or higher, and still more preferably 10 mmol/g or higher. From the viewpoint of refining a pattern, the polymerizable group value is still more preferably 10.5 mmol/g or higher. The upper limit is preferably 70 mmol/g or lower. The polymerizable group value of the polymerizable monomer can be calculated by dividing the number of polymerizable groups in one molecule of the polymerizable monomer by the molecular weight of the polymerizable monomer.

[Radically Polymerizable Monomer]

The radically polymerizable monomer is preferably a compound having two or more ethylenically unsaturated bond groups (compound having two or more functional groups), more preferably a compound having 2 to 15 ethylenically unsaturated bond groups (compound having 2 to 15 functional groups), still more preferably a compound having 2 to 10 ethylenically unsaturated bond groups (compound having 2 to 10 functional groups), and still more preferably a compound having 2 to 6 ethylenically unsaturated bond groups (compound having 2 to 6 functional groups). Specifically, the radically polymerizable monomer is preferably a (meth)acrylate compound having two or more functional groups, more preferably a (meth)acrylate compound having 2 to 15 functional groups, still more preferably a (meth)acrylate compound having 2 to 10 functional groups, and still more preferably a (meth)acrylate compound having 2 to 6 functional groups. Specific examples of the polymerizable monomer include compounds described in paragraphs “0095” to “0108” of JP2009-288705A, paragraph “0227” of JP2013-029760 and paragraphs “0254” to “0257” of JP2008-292970A, the contents of which are incorporated herein by reference.

The ethylenically unsaturated bond group value (hereinafter, referred to as “C═C value”) of the radically polymerizable monomer is preferably 2 mmol/g or higher, more preferably 6 mmol/g or higher, and still more preferably 10 mmol/g or higher. From the viewpoint of refining a pattern, the polymerizable group value is still more preferably 10.5 mmol/g or higher. The upper limit is preferably 70 mmol/g or lower. The C═C value of the radically polymerizable monomer can be calculated by dividing the number of ethylenically unsaturated bond groups in one molecule of the polymerizable monomer by the molecular weight of the radically polymerizable monomer.

The radically polymerizable monomer is preferably a radically polymerizable monomer having a fluorene skeleton and more preferably a radically polymerizable monomer having a partial structure represented by Formula (Fr). In addition, the radically polymerizable monomer having a fluorene skeleton is preferably a compound having two or more ethylenically unsaturated bond groups, more preferably a compound having 2 to 15 ethylenically unsaturated bond groups, still more preferably a compound having 2 to 10 ethylenically unsaturated bond groups, and still more preferably a compound having 2 to 6 ethylenically unsaturated bond groups. Specific examples of the radically polymerizable monomer having a fluorene skeleton include a compound having the following structure. In addition, examples of a commercially available product of the radically polymerizable monomer having a fluorene skeleton include OGSOL EA-0200 and EA-0300 (manufactured by Osaka Gas Chemicals Co., Ltd., a (meth)acrylate monomer having a fluorene skeleton).

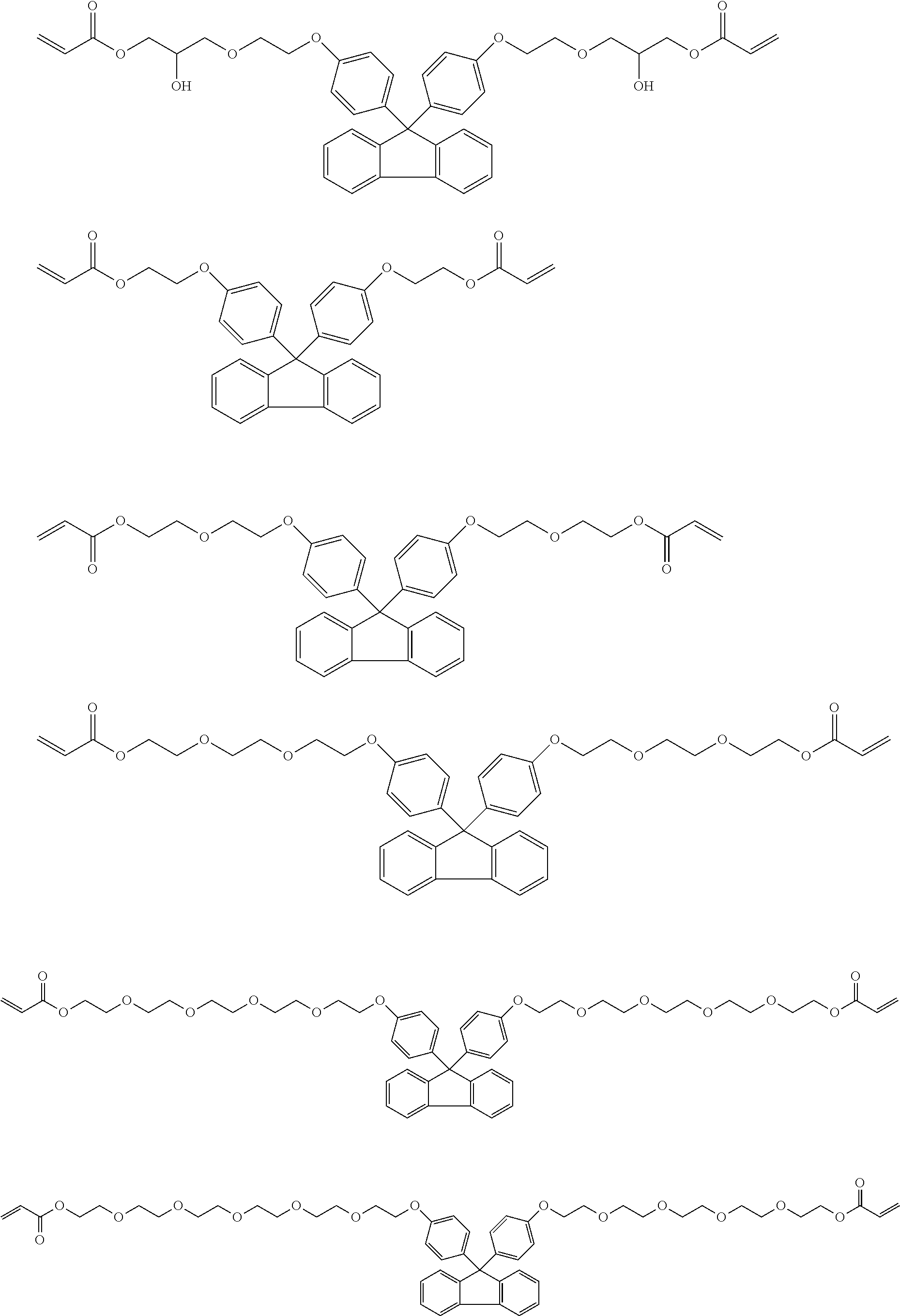

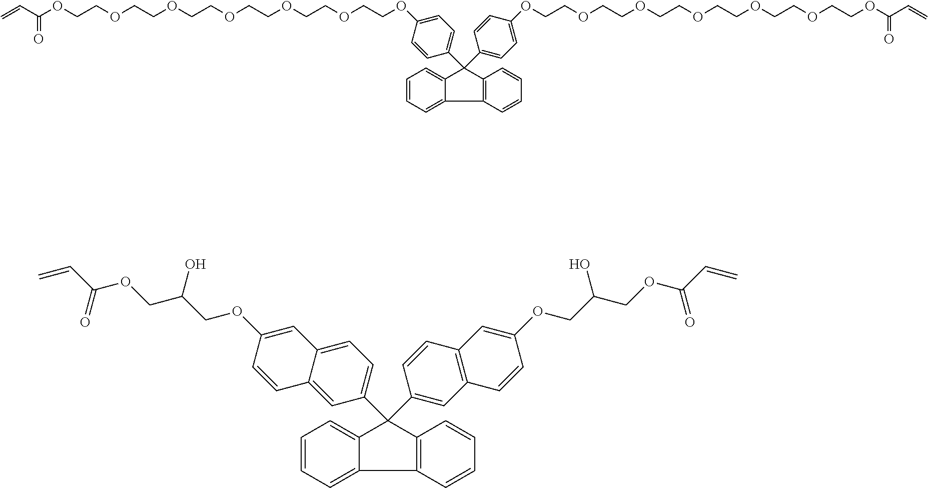

As the radically polymerizable monomer, compounds represented by the following Formulae (MO-1) to (MO-6) can also be preferably used. In a case where T in the formulae represents an oxyalkylene group, a terminal thereof on a carbon atom side is bonded to R.

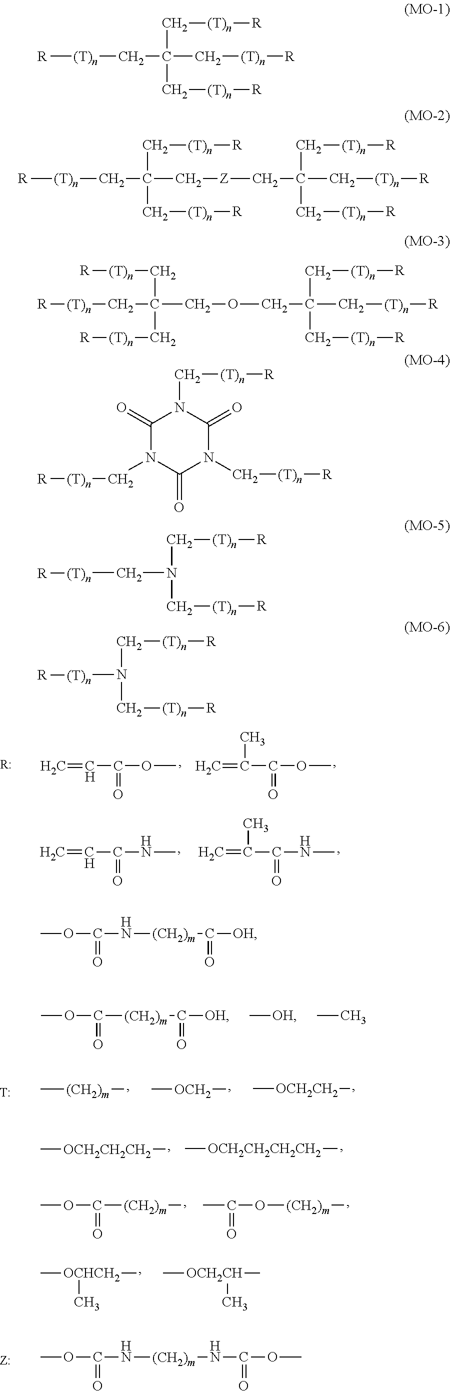

In the formulae, n represents 0 to 14, and m represents 1 to 8. A plurality of R's and a plurality of T's which are present in one molecule may be the same as or different from each other.

At least one of a plurality of R's which are present in each of the compounds represented by Formula (MO-1) to (MO-6) represents —OC(═O)CH═CH₂, —OC(═O)C(CH₃)═CH₂, —NHC(═O)CH═CH₂, or —NHC(═O)C(CH₃)═CH₂.

Specific examples of the polymerizable compounds represented by Formulae (MO-1) to (MO-6) include compounds described in paragraphs “0248” to “0251” of JP2007-269779A.

It is also preferable that the radically polymerizable monomer is a compound having a caprolactone structure. As the compound having a caprolactone structure, a compound represented by the following Formula (Z-1) is preferable.

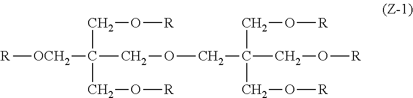

In Formula (Z-1), all of six R's represent a group represented by Formula (Z-2), or one to five R's among the six R's represent a group represented by Formula (Z-2) and the remaining R's represent a group represented by Formula (Z-3), an acid group, or a hydroxy group.

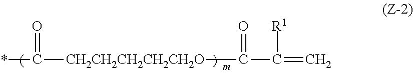

In Formula (Z-2), R¹ represents a hydrogen atom or a methyl group, m represents an integer of 1 or 2, and “*” represents a direct bond.

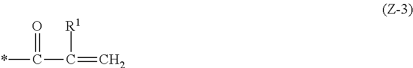

In Formula (Z-3), R¹ represents a hydrogen atom or a methyl group, and “*” represents a direct bond.

As the radically polymerizable monomer, a compound represented by Formula (Z-4) or (Z-5) can also be used.

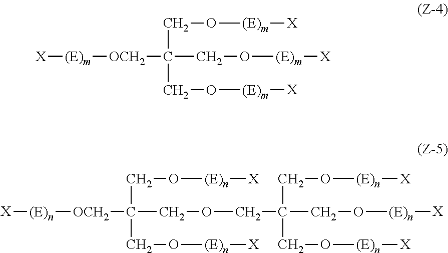

In Formulae (Z-4) and (Z-5), E's each independently represent —((CH₂)_{y}CH₂O)— or —((CH₂)_{y}CH(CH₃)O)—, y's each independently represent an integer of 0 to 10, and X's each independently represent a (meth)acryloyl group, a hydrogen atom, or a carboxyl group. In Formula (Z-4), the total number of (meth)acryloyl groups is 3 or 4, m's each independently represent an integer of 0 to 10, and the sum of m's is an integer of 0 to 40. In Formula (Z-5), the total number of (meth)acryloyl groups is 5 or 6, n's each independently represent an integer of 0 to 10, and the sum of n's is an integer of 0 to 60.

In Formula (Z-4), m represents preferably an integer of 0 to 6 and more preferably an integer of 0 to 4. In addition, the sum of m's is preferably an integer of 2 to 40, more preferably an integer of 2 to 16, and still more preferably an integer of 4 to 8.

In Formula (Z-5), n represents preferably an integer of 0 to 6 and more preferably an integer of 0 to 4. In addition, the sum of n's is preferably an integer of 3 to 60, more preferably an integer of 3 to 24, and still more preferably an integer of 6 to 12.

In addition, it is preferable that, in —((CH₂)_{y}CH₂O)— or —((CH₂)_{y}CH(CH₃)O)— of Formula (Z-4) or (Z-5), a terminal thereof on an oxygen atom side is bonded to X.

As the radically polymerizable monomer, dipentaerythritol triacrylate (KAYARAD D-330 as a commercially available product; manufactured by Nippon Kayaku Co., Ltd.), dipentaerythritol tetraacrylate (as a commercially available product, KAYARAD D-320 manufactured by Nippon Kayaku Co., Ltd.), dipentaerythritol penta(meth)acrylate (KAYARAD D-310 as a commercially available product; manufactured by Nippon Kayaku Co., Ltd.), dipentaerythritol hexa(meth)acrylate (as a commercially available product, KAYARAD DPHA manufactured by Nippon Kayaku Co., Ltd.; NK ESTER A-DPH-12E manufactured by Shin-Nakamura Chemical Co., Ltd.), a compound having a structure in which the (meth)acryloyl group is bonded through an ethylene glycol or a propylene glycol residue (for example, SR454 and SR499 available from Sartomer), NK ESTER A-TMMT (manufactured by Shin-Nakamura Chemical Co., Ltd.), or KAYARAD RP-1040 and DPCA-20 (manufactured by Nippon Kayaku Co., Ltd.) is also preferably used. In addition, as the radically polymerizable monomer, a trifunctional (meth)acrylate compound such as trimethylolpropane tri(meth)acrylate, trimethylolpropane propyleneoxy-modified tri(meth)acrylate, trimethylolpropane ethyleneoxy-modified tri(meth)acrylate, isocyanuric acid ethyleneoxy-modified (meth)acrylate, or pentaerythritol tri(meth)acrylate is also preferably used. Examples of a commercially available product of the trifunctional (meth)acrylate compound include ARONIX M-309, M-310, M-321, M-350, M-360, M-313, M-315, M-306, M-305, M-303, M-452, and M-450 (all of which are manufactured by Toagosei Co., Ltd.), NK ESTER A9300, A-GLY-9E, A-GLY-20E, A-TMM-3, A-TMM-3L, A-TMM-3LM-N, A-TMPT, and TMPT (manufactured by Shin-Nakamura Chemical Co., Ltd.), KAYARAD GPO-303, TMPTA, THE-330, TPA-330, and PET-30 (manufactured by Nippon Kayaku Co., Ltd.), and TMPEOTA (manufactured by Daicel-Allnex Ltd.). As the radically polymerizable monomer, a compound having an acid group such as a carboxyl group, a sulfo group, or a phosphate group is also preferably used. Examples of a commercially available product of the radically polymerizable monomer having an acid group include ARONIX M-305, M-510, and M-520 (manufactured by Toagosei Co., Ltd.). The acid value of the radically polymerizable monomer having an acid group is preferably 0.1 to 40 mgKOH/g. The lower limit is preferably 5 mgKOH/g or higher. The upper limit is preferably 30 mgKOH/g or lower.

[Cationically Polymerizable Monomer]

The cationically polymerizable monomer is preferably a compound having two or more cyclic ether groups (compound having two or more functional groups), more preferably a compound having 2 to 15 cyclic ether groups (compound having 2 to 15 functional groups), still more preferably a compound having 2 to 10 cyclic ether groups (compound having 2 to 10 functional groups), and still more preferably a compound having 2 to 6 cyclic ether groups (compound having 2 to 6 functional groups). As specific examples, compounds described in paragraphs “0034” to “0036” of JP2013-011869A and paragraphs “0085” to “0090” of JP2014-089408A can also be used. The contents of this specification are incorporated herein by reference.

Examples of the cationically polymerizable monomer include a compound represented by the following Formula (EP1).

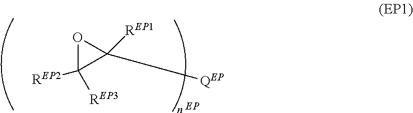

In Formula (EP1), R^{EP1} to R^{EP3} each independently represent a hydrogen atom, a halogen atom, or an alkyl group. The alkyl group may have a cyclic structure or may have a substituent. In addition, R^{EP1} and R^{EP2}, or R^{EP2} and R^{EP3} may be bonded to each other to form a ring structure. Q^{EP} represents a single bond or an n^{EP}-valent organic group. R^{EP1} to R^{EP3} may be bonded to Q^{EP} to form a ring structure. n^{EP} represents an integer of 2 or more, preferably 2 to 10, and more preferably 2 to 6. In a case where Q^{EP} represents a single bond, n^{EP} represents 2. The details of R^{EP1} to R^{EP3} and Q^{EP} can be found in paragraphs “0087” and “0088” of JP2014-089408A, the content of which is incorporated herein by reference. Specific examples of the compound represented by Formula (EP1) include a compound described in paragraph “0090” of JP2014-089408A and a compound described in paragraph “0151” of JP2010-054632A, the contents of which are incorporated herein by reference.

Examples of a commercially available product of the cationically polymerizable monomer include ADEKA GLYCILOL series manufactured by Adeka Corporation (for example, ADEKA GLYCILOL ED-505) and EPOLEAD series manufactured by Daicel Corporation (for example, EPOLEAD GT401).

(Polymerizable Polymer)

Examples of the polymerizable polymer include a resin that includes a repeating unit having a polymerizable group and an epoxy resin.

Examples of the repeating unit having a polymerizable group include the following (A2-1) to (A2-4).

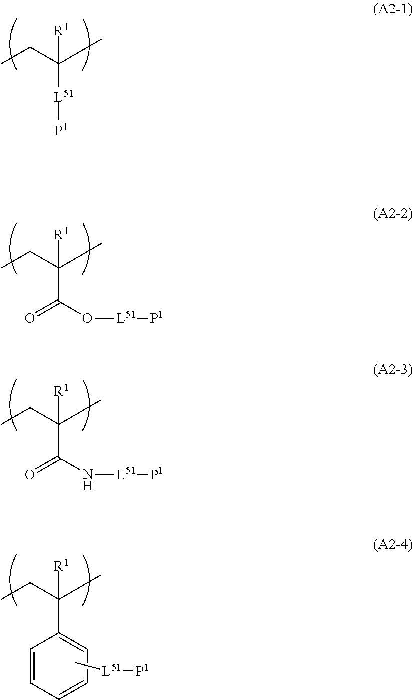

R¹ represents a hydrogen atom or an alkyl group. The number of carbon atoms in the alkyl group is preferably 1 to 5, more preferably 1 to 3, and still more preferably 1. It is preferable that R¹ represents a hydrogen atom or a methyl group.

L⁵¹ represents a single bond or a divalent linking group. Examples of the divalent linking group include an alkylene group, an arylene group, —O—, —S—, —CO—, —COO—, —OCO—, —SO₂—, —NR¹⁰— (R¹⁰ represents a hydrogen atom or an alkyl group and preferably a hydrogen atom), and a group consisting of a combination thereof. The number of carbon atoms in the alkylene group is preferably 1 to 30, more preferably 1 to 15, and still more preferably 1 to 10. The alkylene group may have a substituent but is preferably unsubstituted. The alkylene group may be linear, branched, or cyclic. In addition, the cyclic alkylene group may be monocyclic or polycyclic. The number of carbon atoms in the arylene group is preferably 6 to 18, more preferably 6 to 14, and still more preferably 6 to 10.

P¹ represents a polymerizable group. Examples of the polymerizable group include: an ethylenically unsaturated bond group such as a vinyl group, a (meth)allyl group, or a (meth)acryloyl group; and a cyclic ether group such as an epoxy group or an oxetanyl group.

Examples of the epoxy resin include an epoxy resin which is a glycidyl-etherified product of a phenol compound, an epoxy resin which is a glycidyl-etherified product of various novolac resins, an alicyclic epoxy resin, an aliphatic epoxy resin, a heterocyclic epoxy resin, a glycidyl ester epoxy resin, a glycidyl amine epoxy resin, an epoxy resin which is a glycidylated product of a halogenated phenol, a condensate of a silicon compound having an epoxy group and another silicon compound, and a copolymer of a polymerizable unsaturated compound having an epoxy group and another polymerizable unsaturated compound. The epoxy equivalent of the epoxy resin is preferably 310 to 3300 g/eq, more preferably 310 to 1700 g/eq, and still more preferably 310 to 1000 g/eq. Examples of a commercially available product of the epoxy resin include EHPE 3150 (manufactured by Daicel Corporation), EPICLON N-695 (manufactured by DIC Corporation), and MARPROOF G-0150M, G-0105SA, G-0130SP, G-0250SP, G-1005S, G-1005SA, G-1010S, G-2050M, G-01100, or G-01758 (manufactured by NOF Corporation, an epoxy group-containing polymer). As the epoxy resin, epoxy resins described in paragraphs “0153” to “0155” of JP2014-043556A and paragraph “0092” of JP2014-089408A can also be used, the contents of which are incorporated herein by reference.

As the polymerizable polymer, a resin having a fluorene skeleton can also be preferably used. Examples of the resin having a fluorene skeleton include a resin having the following structure. In the following structural formula, A represents a residue of a carboxylic dianhydride selected from pyromellitic dianhydride, benzophenone tetracarboxylic dianhydride, biphenyl tetracarboxylic dianhydride, or diphenyl ether tetracarboxylic dianhydride, and M represents a phenyl group or a benzyl group. The details of the resin having a fluorene skeleton can be found in US2017/0102610A, the content of which is incorporated herein by reference.

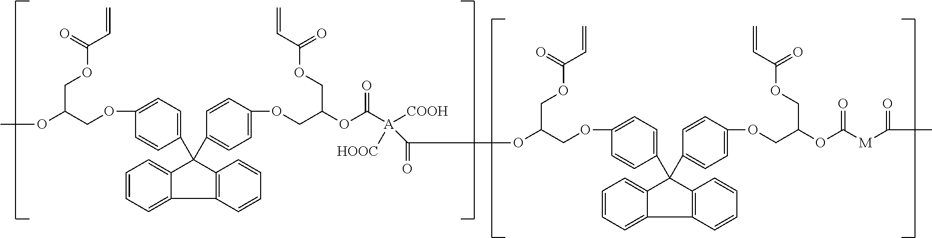

The polymerizable group value of the polymerizable polymer is preferably 0.5 to 3 mmol/g. The upper limit is preferably 2.5 mmol/g or lower and more preferably 2 mmol/g or lower. The lower limit is preferably 0.9 mmol/g or higher and more preferably 1.2 mmol/g or higher. The polymerizable group value of the polymerizable polymer refers to a numerical value representing the molar amount of the polymerizable group value per 1 g of the solid content of the polymerizable polymer. In addition, the C═C value of the polymerizable polymer is preferably 0.6 to 2.8 mmol/g. The upper limit is preferably 2.3 mmol/g or lower and more preferably 1.8 mmol/g or lower. The lower limit is preferably 1.0 mmol/g or higher and more preferably 1.3 mmol/g or higher. The C═C value of the polymerizable polymer refers to a numerical value representing the molar amount of the ethylenically unsaturated bond group per 1 g of the solid content of the polymerizable polymer.

It is also preferable that the polymerizable polymer includes a repeating unit having an acid group. The above-described polymer can be used as an alkali-soluble resin. Examples of the acid group include a carboxyl group, a phosphate group, a sulfo group, and a phenolic hydroxy group. Among these, a carboxyl group is preferable. In a case where the polymerizable polymer includes a repeating unit having an acid group, the acid value of the polymerizable polymer is preferably 30 to 200 mgKOH/g. The lower limit is preferably 50 mgKOH/g or higher, more preferably 70 mgKOH/g or higher, and still more preferably 100 mgKOH/g or higher. The upper limit is preferably 180 mgKOH/g or lower and more preferably 150 mgKOH/g or lower.

Specific examples of the polymerizable polymer include a resin having the following structure.

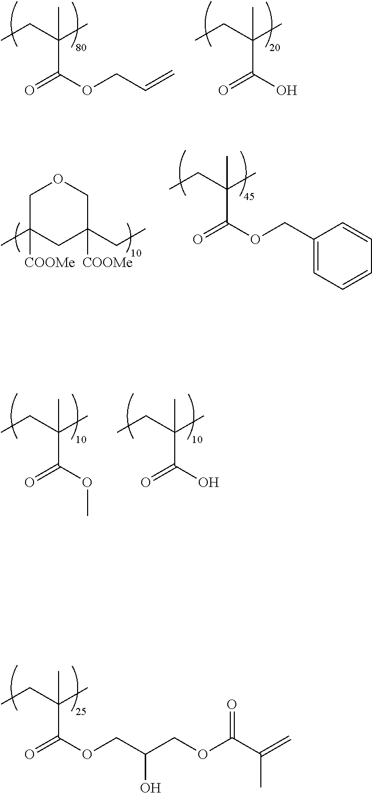

The content of the compound C is preferably 0.1% to 70 mass % with respect to the total solid content of the photosensitive composition. From the viewpoint of developability, the upper limit is preferably 60 mass % or lower and more preferably 30 mass % or lower. From the viewpoint of pattern formability, the lower limit is preferably 1 mass % or higher, more preferably 2 mass % or higher, and still more preferably 5 mass % or higher. The content of the compound C is more preferably 5% to 30 mass % with respect to the total solid content of the photosensitive composition.

From the viewpoint of developability, the content of the polymerizable monomer is preferably 70 mass % or lower, more preferably 60 mass % or lower, and still more preferably 30 mass % or lower with respect to the total solid content of the photosensitive composition. From the viewpoint of pattern formability, the lower limit is preferably 0.1 mass % or higher, more preferably 1 mass % or higher, still more preferably 2 mass % or higher, and still more preferably 5 mass % or higher.

From the viewpoint of developability, the content of the polymerizable polymer is preferably 70 mass % or lower, more preferably 60 mass % or lower, and still more preferably 30 mass % or lower with respect to the total solid content of the photosensitive composition. From the viewpoint of pattern formability, the lower limit is preferably 0.1 mass % or higher, more preferably 1 mass % or higher, still more preferably 2 mass % or higher, and still more preferably 5 mass % or higher.

<<Resin>>

The photosensitive composition according to the embodiment of the present invention may include a resin. The resin according to the embodiment of the present invention refers to an organic compound having a molecular weight of 2000 or higher other than the near infrared absorber and the chromatic colorant. The resin is added, for example, in order to disperse particles of the pigments and the like in the composition or to be added as a binder. The resin which is mainly used to disperse particles of the pigments and the like will also be called a dispersant. However, the above-described uses of the resin are merely exemplary, and the resin can be used for purposes other than the uses. The resin having a polymerizable group is a component that also corresponds to the compound C.

The weight-average molecular weight (Mw) of the resin is preferably 2000 to 2000000. The upper limit is preferably 1000000 or lower and more preferably 500000 or lower. The lower limit is preferably 3000 or higher and more preferably 5000 or higher.

Examples of the resin include a (meth)acrylic resin, an enethiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamide imide resin, a polyolefin resin, a cyclic olefin resin, a polyester resin, and a styrene resin. Among these resins, one kind may be used alone, or a mixture of two or more kinds may be used. As the cyclic olefin resin, a norbornene resin can be preferably used from the viewpoint of improving heat resistance. Examples of a commercially available product of the norbornene resin include ARTON series (for example, ARTON F4520, manufactured by JSR Corporation). In addition, as the resin, a resin described in Examples of WO2016/088645A, a resin described in JP2017-057265A, a resin described in JP2017-032685A, a resin described in JP2017-075248A, or a resin described in JP2017-066240A can also be used, the contents of which are incorporated herein by reference.

In the present invention, it is preferable that a resin having an acid group is used as the resin. In this aspect, the developability of the photosensitive composition can be improved, and a pixel having excellent rectangularity can be easily formed. Examples of the acid group include a carboxyl group, a phosphate group, a sulfo group, and a phenolic hydroxy group. Among these, a carboxyl group is preferable. The resin having an acid group can be used as, for example, an alkali-soluble resin.

It is preferable that the resin having an acid group further includes a repeating unit having an acid group at a side chain, and it is more preferable that the content of the repeating unit having an acid group at a side chain is preferably 5 to 70 mol % with respect to all the repeating units of the resin. The upper limit of the content of the repeating unit having an acid group at a side chain is preferably 50 mol % or lower and more preferably 30 mol % or lower. The lower limit of the content of the repeating unit having an acid group at a side chain is preferably 10 mol % or higher and more preferably 20 mol % or higher.

It is preferable that the resin having an acid group is a resin which includes a repeating unit having a carboxyl group at a side chain. Specific examples of the resin include an alkali-soluble phenol resin such as a methacrylic acid copolymer, an acrylic acid copolymer, an itaconic acid copolymer, a crotonic acid copolymer, a maleic acid copolymer, a partially esterified maleic acid copolymer, or a novolac resin, an acidic cellulose derivative having a carboxyl group at a side chain thereof, and a resin obtained by adding an acid anhydride to a polymer having a hydroxy group. In particular, a copolymer of (meth)acrylic acid and another monomer which is copolymerizable with the (meth)acrylic acid is preferable as the alkali-soluble resin. Examples of the monomer which is copolymerizable with the (meth)acrylic acid include an alkyl (meth)acrylate, an aryl (meth)acrylate, and a vinyl compound. Examples of the alkyl (meth)acrylate and the aryl (meth)acrylate include methyl (meth)acrylate, ethyl (meth)acrylate, propyl (meth)acrylate, butyl (meth)acrylate, isobutyl (meth)acrylate, pentyl (meth)acrylate, hexyl (meth)acrylate, octyl (meth)acrylate, phenyl (meth)acrylate, benzyl (meth)acrylate, tolyl (meth)acrylate, naphthyl (meth)acrylate, and cyclohexyl (meth)acrylate. Examples of the vinyl compound include styrene, α-methylstyrene, vinyl toluene, glycidyl methacrylate, acrylonitrile, vinyl acetate, N-vinylpyrrolidone, tetrahydrofurfuryl methacrylate, a polystyrene macromonomer, and a polymethyl methacrylate macromonomer. Examples of other monomers include a N-position-substituted maleimide monomer described in JP1998-300922A (JP-H10-300922A) such as N-phenylmaleimide or N-cyclohexylmaleimide. As the other monomer which is copolymerizable with the (meth)acrylic acid, one kind may be used alone, or two or more kinds may be used in combination. The details of the resin having an acid group can be found in paragraphs “0558” to “0571” of JP2012-208494A (corresponding to paragraphs “0685” to “0700” of US2012/0235099A) and paragraphs “0076” to “0099” of JP2012-198408A, the contents of which are incorporated herein by reference. In addition, as the resin having an acid group, a commercially available product may also be used. Examples of the commercially available product include ACRYBASE FF-426 (manufactured by Fujikura Kasei Co., Ltd.).

The acid value of the resin having an acid group is preferably 30 to 200 mgKOH/g. The lower limit is preferably 50 mgKOH/g or higher, more preferably 70 mgKOH/g or higher, and still more preferably 100 mgKOH/g or higher. The upper limit is preferably 180 mgKOH/g or lower and more preferably 150 mgKOH/g or lower.

It is also preferable that the resin used in the present invention includes a repeating unit derived from monomer components including a compound represented by the following Formula (ED1) and/or a compound represented by the following Formula (ED2) (hereinafter, these compounds will also be referred to as “ether dimer”) is also preferable.

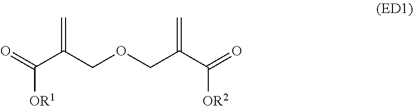

In Formula (ED1), R¹ and R² each independently represent a hydrogen atom or a hydrocarbon group having 1 to 25 carbon atoms which may have a substituent.

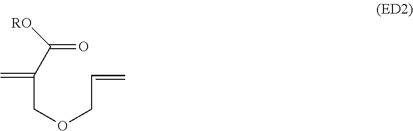

In Formula (ED2), R represents a hydrogen atom or an organic group having 1 to 30 carbon atoms. The details of Formula (ED2) can be found in JP2010-168539A, the content of which is incorporated herein by reference.

Specific examples of the ether dimer can be found in paragraph “0317” of JP2013-029760A, the content of which is incorporated herein by reference.

It is also preferable that the resin used in the present invention includes a repeating unit which is derived from a compound represented by the following Formula (X).

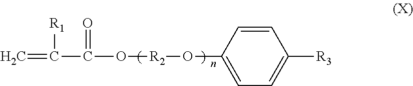

In Formula (X), R₁ represents a hydrogen atom or a methyl group, R₂ represents an alkylene group having 2 to 10 carbon atoms, and R3 represents a hydrogen atom or an alkyl group having 1 to 20 carbon atoms which may have a benzene ring. n represents an integer of 1 to 15.

Examples of the resin having an acid group include resins having the following structures.

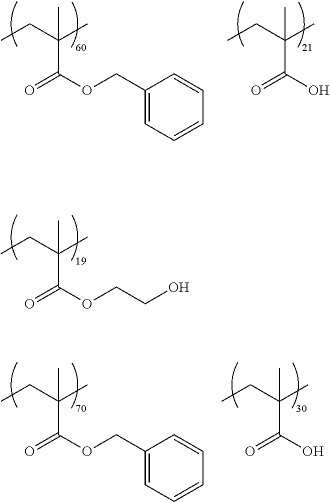

The photosensitive composition according to the embodiment of the present invention may include a resin as a dispersant. Examples of the dispersant include an acidic dispersant (acidic resin) and a basic dispersant (basic resin). Here, the acidic dispersant (acidic resin) refers to a resin in which the content of an acid group is more than the content of a basic group. In a case where the sum of the amount of an acid group and the amount of a basic group in the acidic dispersant (acidic resin) is represented by 100 mol %, the amount of the acid group in the acidic resin is preferably 70 mol % or higher and more preferably substantially 100 mol %. The acid group in the acidic dispersant (acidic resin) is preferably a carboxyl group. An acid value of the acidic dispersant (acidic resin) is preferably 40 to 105 mgKOH/g, more preferably 50 to 105 mgKOH/g, and still more preferably 60 to 105 mgKOH/g. In addition, the basic dispersant (basic resin) refers to a resin in which the amount of a basic group is more than the amount of an acid group. In a case where the sum of the amount of an acid group and the amount of a basic group in the basic dispersant (basic resin) is represented by 100 mol %, the amount of the basic group in the basic resin is preferably higher than 50 mol %. The basic group in the basic dispersant is preferably an amino group.

It is preferable that the resin used as the dispersant further includes a repeating unit having an acid group. In a case where the resin used as the dispersant further includes a repeating unit having an acid group, a photosensitive composition having excellent developability can be obtained, and the generation of development residues can be effectively suppressed during the formation of a pixel using a photolithography method.

It is preferable that the resin used as the dispersant is a graft copolymer. Since the graft copolymer has affinity to the solvent due to the graft chain, the pigment dispersibility and the dispersion stability over time are excellent. The details of the graft copolymer can be found in the description of paragraphs “0025” to “0094” of JP2012-255128A, the content of which is incorporated herein by reference. In addition, specific examples of the graft copolymer include the following resins. The following resin may also be a resin having an acid group (alkali-soluble resin). In addition, other examples of the graft copolymer include resins described in paragraphs “0072” to “0094” of JP2012-255128A, the content of which is incorporated herein by reference.

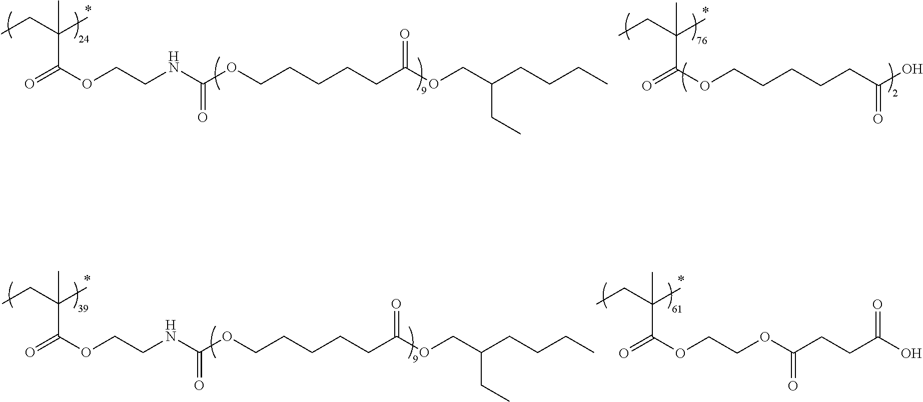

In addition, in the present invention, as the resin (dispersant), an oligoimine dispersant having a nitrogen atom at at least either a main chain or a side chain is also preferably used. As the oligoimine dispersant, a resin, which includes a structural unit having a partial structure X with a functional group (pKa: 14 or lower) and a side chain including a side chain Y having 40 to 10000 atoms and has a basic nitrogen atom at at least either a main chain or a side chain, is preferable. The basic nitrogen atom is not particularly limited as long as it is a nitrogen atom exhibiting basicity. The oligoimine dispersant can be found in the description of paragraphs “0102” to “0166” of JP2012-255128A, the content of which is incorporated herein by reference.

In addition, it is also preferable that the resin used as a dispersant is a resin that includes a repeating unit having an ethylenically unsaturated bond group at a side chain. The content of the repeating unit having an ethylenically unsaturated bond group at a side chain is preferably 10 mol % or higher, more preferably 10% to 80 mol %, and still more preferably 20% to 70 mol % with respect to all the repeating units of the resin.

The dispersant is available as a commercially available product, and specific examples thereof include Disperbyk-111 and 161 (manufactured by BYK Chemie). In addition, a pigment dispersant described in paragraphs “0041” to “0130” of JP2014-130338A can also be used, the content of which is incorporated herein by reference. In addition, the resin having an acid group or the like can also be used as a dispersant.

The content of the resin (in a case where the compound C includes a polymerizable polymer, including the content of the polymerizable polymer) is preferably 0.1% to 80 mass % with respect to the total solid content of the photosensitive composition. From the viewpoint of developability, the lower limit is preferably 0.5 mass % or higher, more preferably 1 mass % or higher, and still more preferably 5 mass % or higher. From the viewpoint of pattern formability, the upper limit is preferably 75 mass % or lower, more preferably 70 mass % or lower, and still more preferably 60 mass % or lower.

In addition, the content of the resin having an acid group (in a case where the compound C includes a polymerizable polymer having an acid group, including the content of the polymerizable polymer having an acid group) is preferably 0.1% to 80 mass % with respect to the total solid content of the photosensitive composition. From the viewpoint of developability, the lower limit is preferably 0.5 mass % or higher, more preferably 1 mass % or higher, and still more preferably 5 mass % or higher. From the viewpoint of pattern formability, the upper limit is preferably 70 mass % or lower and more preferably 60 mass % or lower.

In addition, from the viewpoint of developability, the content of the resin having an acid group is preferably 1 mass % or higher, more preferably 3 mass % or higher, still more preferably 5 mass % or higher, and still more preferably 10 mass % or higher with respect to the total content of the resin. The upper limit may be 100 mass % or lower, 95 mass % or lower, or 90 mass % or lower.

In addition, the total content of the polymerizable monomer and the resin is preferably 10% to 90 mass % with respect to the total solid content of the photosensitive composition. From the viewpoint of pattern formability, the lower limit is preferably 15 mass % or higher, more preferably 20 mass % or higher, and still more preferably 25 mass % or higher. From the viewpoint of pattern formability, the upper limit is preferably 85 mass % or lower, more preferably 80 mass % or lower, and still more preferably 70 mass % or lower. In addition, the content of the resin is preferably 0.1 to 2000 parts by mass with respect to 100 parts by mass of the polymerizable monomer. From the viewpoint of developability, the lower limit is preferably 1 part by mass or more and more preferably 3 parts by mass or more. From the viewpoint of pattern formability, the upper limit is preferably 1800 parts by mass or less and more preferably 1500 parts by mass or less.

<<Silane Coupling Agent>>

The photosensitive composition according to the embodiment of the present invention may include a silane coupling agent. In a case where the photosensitive composition according to the embodiment of the present invention includes a silane coupling agent, the adhesiveness of the obtained film with a support can be improved. In the present invention, the silane coupling agent refers to a silane compound having a functional group other than a hydrolyzable group. In addition, the hydrolyzable group refers to a substituent directly linked to a silicon atom and capable of forming a siloxane bond due to at least one of a hydrolysis reaction or a condensation reaction. Examples of the hydrolyzable group include a halogen atom, an alkoxy group, and an acyloxy group. Among these, an alkoxy group is preferable. That is, it is preferable that the silane coupling agent is a compound having an alkoxysilyl group. Examples of the functional group other than a hydrolyzable group include a vinyl group, a (meth)allyl group, a (meth)acryloyl group, a mercapto group, an epoxy group, an oxetanyl group, an amino group, an ureido group, a sulfide group, an isocyanate group, and a phenyl group. Among these, an amino group, a (meth)acryloyl group, or an epoxy group is preferable. Specific examples of the silane coupling agent include a compound described in paragraphs “0018” to “0036” of JP2009-288703A and a compound described in paragraphs “0056” to “0066” of JP2009-242604A, the contents of which are incorporated herein by reference.

The content of the silane coupling agent is preferably 0.1% to 5 mass % with respect to the total solid content of the photosensitive composition. The upper limit is preferably 3 mass % or lower, and more preferably 2 mass % or lower. The lower limit is preferably 0.5 mass % or higher and more preferably 1 mass % or higher. As the silane coupling agent, one kind may be used alone, or two or more kinds may be used. In a case where two or more surfactants are used in combination, it is preferable that the total content of the two or more surfactants is in the above-described range.

<<Pigment Derivative>>

The photosensitive composition according to the embodiment of the present invention may further include a pigment derivative. Examples of the pigment derivative include a compound having a structure in which a portion of a pigment is substituted with an acid group, a basic group, a group having a salt structure, or a phthalimidomethyl group. As the pigment derivative, a compound represented by Formula (B1) is preferable.

PL-(X)ₙ)ₘ (B1)

In Formula (B1), P represents a colorant structure, L represents a single bond or a linking group, X represents an acid group, a basic group, a group having a salt structure, or a phthalimidomethyl group, m represents an integer of 1 or more, n represents an integer of 1 or more, in a case where m represents 2 or more, a plurality of L's and a plurality of X's may be different from each other, and in a case where n represents 2 or more, a plurality of X's may be different from each other.

The colorant structure represented by P is preferably at least one selected from a pyrrolopyrrole colorant structure, a diketo pyrrolopyrrole colorant structure, a quinacridone colorant structure, an anthraquinone colorant structure, a dianthraquinone colorant structure, a benzoisoindole colorant structure, a thiazine indigo colorant structure, an azo colorant structure, a quinophthalone colorant structure, a phthalocyanine colorant structure, a naphthalocyanine colorant structure, a dioxazine colorant structure, a perylene colorant structure, a perinone colorant structure, a benzimidazolone colorant structure, a benzothiazole colorant structure, a benzimidazole colorant structure, and a benzoxazole colorant structure, and more preferably at least one selected from a pyrrolopyrrole colorant structure, a diketo pyrrolo pyrrolopyrrole colorant structure, a quinacridone colorant structure, or a benzimidazolone colorant structure.

Examples of the linking group represented by L include a hydrocarbon group, a heterocyclic group, —NR—, —SO₂—, —S—, —O—, —CO—, and a group consisting of a combination thereof. R represents a hydrogen atom, an alkyl group, or an aryl group.

Examples of the acid group represented by X include a carboxyl group, a sulfo group, a carboxylic acid amide group, a sulfonic acid amide group, and an imide acid group. As the carboxylic acid amide group, a group represented by —NHCOR^{X1} is preferable. As the sulfonic acid amide group, a group represented by —NHSO₂R^{X2} is preferable. As the imide acid group, a group represented by —SO₂NHSO₂R^{X3}, —CONHSO₂R^{X4}, —CONHCOR^{X5}, or —SO₂NHCOR^{X6} is preferable. R^{X1} to R^{X6} each independently represent a hydrocarbon group or a heterocyclic group. The hydrocarbon group and the heterocyclic group represented by R^{X1} to R^{X6} may further have a substituent. As the substituent which may be further included, a halogen atom is preferable, and a fluorine atom is more preferable. Examples of the basic group represented by X include an amino group. Examples of the salt structure represented by X include a salt of the acid group or the basic group described above.

Examples of a pigment derivative include a compound described in Examples described below. In addition, for example, compounds described in JP1981-118462A (JP-S56-118462A), JP1988-264674A (JP-S63-264674A), JP1989-217077A (JP-H1-217077A), JP1991-009961A (JP-H3-009961A), JP1991-026767A (JP-H3-026767A), JP1991-153780A (JP-H3-153780A), JP1991-045662A (JP-H3-045662A), JP1992-285669A (JP-H4-285669A), JP1994-145546A (JP-H6-145546A), JP1994-212088A (JP-H6-212088A), JP1994-240158A (JP-H6-240158A), JP1998-030063A (JP-H10-030063A), JP1998-195326A (JP-H10-195326A), paragraphs “0086” to “0098” of WO2011/024896A, paragraphs “0063” to “0094” of WO2012/102399A, and paragraph “0082” of WO2017/038252A can be used, the content of which is incorporated herein by reference.

The content of the pigment derivative is preferably 1 to 50 parts by mass with respect to 100 parts by mass of the pigment. The lower limit value is preferably 3 parts by mass or more and more preferably 5 parts by mass or more. The upper limit value is preferably 40 parts by mass or less and more preferably 30 parts by mass or less. In a case where the content of the pigment derivative is in the above-described range, the pigment dispersibility can be improved, and aggregation of the pigment can be efficiently suppressed. As the pigment derivative, one kind may be used alone, or two or more kinds may be used in combination. In a case where two or more ultraviolet absorbers are used in combination, it is preferable that the total content of the two or more ultraviolet absorbers is in the above-described range.

<<Solvent>>

The photosensitive composition according to the embodiment of the present invention may include a solvent. Examples of the solvent include an organic solvent. Basically, the solvent is not particularly limited as long as it satisfies the solubility of the respective components and the application properties of the composition. Examples of the organic solvent include esters, ethers, ketones, and aromatic hydrocarbons. The details of the organic solvent can be found in paragraph “0223” of WO2015/166779A, the content of which is incorporated herein by reference. In addition, an ester solvent in which a cyclic alkyl group is substituted or a ketone solvent in which a cyclic alkyl group is substituted can also be preferably used. Specific examples of the organic solvent include polyethylene glycol monomethyl ether, dichloromethane, methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, cyclohexyl acetate, cyclopentanone, ethyl carbitol acetate, butyl carbitol acetate, propylene glycol monomethyl ether, and propylene glycol monomethyl ether acetate. In the present invention, as the organic solvent, one kind may be used alone, or two or more kinds may be used in combination. In addition, 3-methoxy-N,N-dimethylpropanamide or 3-butoxy-N,N-dimethylpropanamide is also preferable from the viewpoint of improving solubility. In this case, it may be preferable that the content of the aromatic hydrocarbon (for example, benzene, toluene, xylene, or ethylbenzene) as the solvent is low (for example, 50 mass parts per million (ppm) or lower, 10 mass ppm or lower, or 1 mass ppm or lower with respect to the total mass of the organic solvent) in consideration of environmental aspects and the like.

In the present invention, a solvent having a low metal content is preferably used. For example, the metal content in the solvent is preferably 10 mass parts per billion (ppb) or lower. Optionally, a solvent having a metal content at a mass parts per trillion (ppt) level may be used. For example, such a high-purity solvent is available from Toyo Gosei Co., Ltd. (The Chemical Daily, Nov. 13, 2015).

Examples of a method of removing impurities such as metal from the solvent include distillation (for example, molecular distillation or thin-film distillation) and filtering using a filter. The pore size of a filter used for the filtering is preferably 10 μm or less, more preferably 5 μm or less, and still more preferably 3 μm or less. As a material of the filter, polytetrafluoroethylene, polyethylene, or nylon is preferable.

The solvent may include an isomer (a compound having the same number of atoms and a different structure). In addition, the organic solvent may include only one isomer or a plurality of isomers.

In the present invention, as the organic solvent, an organic solvent containing 0.8 mmol/L or lower of a peroxide is preferable, and an organic solvent containing substantially no peroxide is more preferable.

The content of the solvent in the photosensitive composition is preferably 10% to 95 mass %, more preferably 20% to 90 mass %, and still more preferably 30% to 90 mass %.

In addition, it is preferable that the photosensitive composition according to the embodiment of the present invention does not substantially include an environmentally regulated material from the viewpoint of environmental regulations. In the present invention, not substantially including the environmentally regulated material represents that the content of the environmentally regulated material in the photosensitive composition is 50 mass ppm or lower, preferably 30 mass ppm or lower, more preferably 10 mass ppm or lower, and still more preferably 1 mass ppm or lower. Examples of the environmentally regulated material include: benzene; an alkylbenzene such as toluene or xylene; and a halogenated benzene such as chlorobenzene. These compounds are registered as environmentally regulated materials based on Registration Evaluation Authorization and Restriction of Chemicals (REACH) regulation, Pollutant Release and Transfer Register (PRTR) method, Volatile Organic Compounds (VOC) regulation, and the like, and the amount thereof used and a handling method thereof are strictly regulated. These compounds are used as solvents in a case where each of the components or the like used in the photosensitive composition according to the embodiment of the present invention is manufactured, and may be incorporated into the photosensitive composition as residual solvents. From the viewpoints of safety for humans and consideration of the environment, it is preferable that these materials are reduced as much as possible. Examples of a method of reducing the environmentally regulated material include a method of distilling off the environmentally regulated material from the system by heating or depressurizing the system such that the temperature of the system is higher than or equal to a boiling point of the environmentally regulated material. In addition, in a case where a small amount of environmentally regulated material is removed by distillation, a method of azeotroping the environmentally regulated material with a solvent having the same boiling point as that of the corresponding solvent is also useful to increase the efficiency. In addition, in a case where a radically polymerizable compound is included, in order to suppress intermolecular crosslinking caused by the progress of a radical polymerization reaction during distillation under reduced pressure, a polymerization inhibitor or the like may be added for distillation under reduced pressure. This distillation method can be performed in, for example, any of a step of raw materials, a step of a reaction product (for example, a resin solution or a polyfunctional monomer solution after polymerization) obtained from a reaction of the raw materials, or a step of a composition prepared by mixing these compounds with each other.

<<Polymerization Inhibitor>>

The photosensitive composition according to the embodiment of the present invention may include a polymerization inhibitor. Examples of the polymerization inhibitor include hydroquinone, p-methoxyphenol, di-tert-butyl-p-cresol, pyrogallol, t-butylcatechol, benzoquinone, 4,4′-thiobis(3-methyl-6-tert-butylphenol), 2,2′-methylenebis(4-methyl-6-t-butylphenol), and N-nitrosophenylhydroxyamine salt (for example, an ammonium salt or a cerium (III) salt). Among these, p-methoxyphenol is preferable. The content of the polymerization inhibitor is preferably 0.001% to 5 mass % with respect to the total solid content of the photosensitive composition.

<<Surfactant>>

The photosensitive composition according to the embodiment of the present invention may include a surfactant. As the surfactants, various surfactants such as a fluorine surfactant, a nonionic surfactant, a cationic surfactant, an anionic surfactant, or a silicone surfactant can be used. The details of the surfactant can be found in paragraphs “0238” to “0245” of WO2015/166779A, the content of which is incorporated herein by reference.

In the present invention, it is preferable that the surfactant is a fluorine surfactant. By the photosensitive composition containing a fluorine surfactant, liquid characteristics (in particular, fluidity) are further improved, and liquid saving properties can be further improved. In addition, a film having reduced thickness unevenness can be formed.

The fluorine content in the fluorine surfactant is preferably 3 to 40 mass %, more preferably 5 to 30 mass %, and still more preferably 7 to 25 mass %. The fluorine surfactant in which the fluorine content is in the above-described range is effective from the viewpoints of the uniformity in the thickness of the coating film and liquid saving properties, and the solubility thereof in the composition is also excellent.

Examples of the fluorine surfactant include a surfactant described in paragraphs “0060” to “0064” of JP2014-041318A (paragraphs “0060” to “0064” of corresponding WO2014/017669A) and a surfactant described in paragraphs “0117” to “0132” of JP2011-132503A, the contents of which are incorporated herein by reference. Examples of a commercially available product of the fluorine surfactant include: MEGAFACE F171, F172, F173, F176, F177, F141, F142, F143, F144, R30, F437, F475, F479, F482, F554, F780, EXP, and MFS-330 (all of which are manufactured by DIC Corporation); FLUORAD FC430, FC431, and FC171 (all of which are manufactured by Sumitomo 3M Ltd.); SURFLON S-382, SC-101, SC-103, SC-104, SC-105, SC-1068, SC-381, SC-383, S-393, and KH-40 (all of which are manufactured by Asahi Glass Co., Ltd.); and POLYFOX PF636, PF656, PF6320, PF6520, and PF7002 (all of which are manufactured by OMNOVA Solutions Inc.).

In addition, as the fluorine surfactant, an acrylic compound having a molecular structure which has a functional group having a fluorine atom and in which the functional group having a fluorine atom is cut and a fluorine atom is volatilized during heat application can also be preferably used. Examples of the fluorine surfactant include MEGAFACE DS series (manufactured by DIC Corporation, The Chemical Daily, Feb. 22, 2016, Nikkei Business Daily, Feb. 23, 2016), for example, MEGAFACE DS-21.

In addition, as the fluorine surfactant, a polymer of a fluorine-containing vinyl ether compound having a fluorinated alkyl group or a fluorinated alkylene ether group and a hydrophilic vinyl ether compound is also preferable. The details of this fluorine surfactant can be found in JP2016-216602A, the content of which is incorporated herein by reference.

As the fluorine surfactant, a block polymer can also be used. Examples of the block polymer include a compound described in JP2011-089090A. As the fluorine surfactant, a fluorine-containing polymer compound can be preferably used, the fluorine-containing polymer compound including: a repeating unit derived from a (meth)acrylate compound having a fluorine atom; and a repeating unit derived from a (meth)acrylate compound having 2 or more (preferably 5 or more) alkyleneoxy groups (preferably an ethyleneoxy group and a propyleneoxy group). For example, the following compound can also be used as the fluorine surfactant used in the present invention.

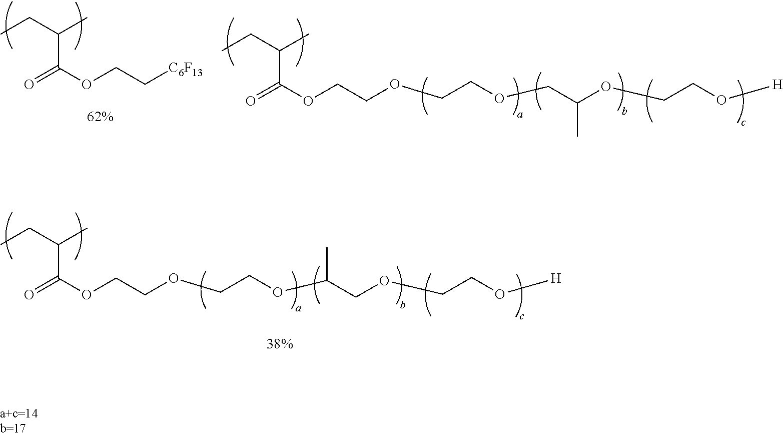

The weight-average molecular weight of the compound is preferably 3,000 to 50,000 and, for example, 14,000. In the compound, “%” representing the proportion of a repeating unit is mol %.

In addition, as the fluorine surfactant, a fluorine-containing polymer having an ethylenically unsaturated bond group at a side chain can also be used. Specific examples include a compound described in paragraphs “0050” to “0090” and paragraphs “0289” to “0295” of JP2010-164965A, for example, MEGAFACE RS-101, RS-102, RS-718K, and RS-72-K manufactured by DIC Corporation. As the fluorine surfactant, a compound described in paragraphs “0015” to “0158” of JP2015-117327A can also be used.

Examples of the nonionic surfactant include glycerol, trimethylolpropane, trimethylolethane, an ethoxylate and a propoxylate thereof (for example, glycerol propoxylate or glycerol ethoxylate), polyoxyethylene lauryl ether, polyoxyethylene stearyl ether, polyoxyethylene oleyl ether, polyoxyethylene octylphenyl ether, polyoxyethylene nonylphenyl ether, polyethylene glycol dilaurate, polyethylene glycol distearate, sorbitan fatty acid esters, PLURONIC L10, L31, L61, L62, 10R5, 17R2, and 25R2 (manufactured by BASF SE), TETRONIC 304, 701, 704, 901, 904, and 150R1 (manufactured by BASF SE)), SOLSPERSE 20000 (manufactured by Lubrication Technology Inc.), NCW-101, NCW-1001, and NCW-1002 (all of which are manufactured by Fujifilm Wako Pure Chemical Corporation), PIONIN D-6112, D-6112-W, and D-6315 (all of which are manufactured by Takemoto Oil&Fat Co., Ltd.), and OLFINE E1010, SURFYNOL 104, 400, and 440 (all of which are manufactured by Nissin Chemical Co., Ltd.).

Examples of the silicone surfactant include: TORAY SILICONE DC3PA, TORAY SILICONE SH7PA, TORAY SILICONE DC11PA, TORAY SILICONE SH21PA, TORAY SILICONE SH28PA, TORAY SILICONE SH29PA, TORAY SILICONE SH30PA, and TORAY SILICONE SH8400 (all of which are manufactured by Dow Corning Corporation); TSF-4440, TSF-4300, TSF-4445, TSF-4460, and TSF-4452 (all of which are manufactured by Momentive Performance Materials Inc.); KP-341, KF-6001, and KF-6002 (all of which are manufactured by Shin-Etsu Chemical Co., Ltd.); and BYK307, BYK323, and BYK330 (all of which are manufactured by BYK-Chemie Japan K.K.). In addition, as the silicone surfactant, a compound having the following structure can also be used.

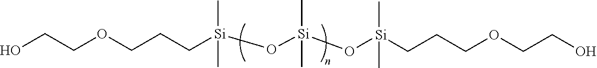

The content of the surfactant is preferably 0.001 mass % to 5.0 mass % and more preferably 0.005% to 3.0 mass % with respect to the total solid content of the photosensitive composition. As the surfactant, one kind may be used alone, or two or more kinds may be used. In a case where two or more surfactants are used in combination, it is preferable that the total content of the two or more surfactants is in the above-described range.

<<Ultraviolet Absorber>>

The photosensitive composition according to the embodiment of the present invention may include an ultraviolet absorber. As the ultraviolet absorber, a conjugated diene compound, an amino diene compound, a salicylate compound, a benzophenone compound, a benzotriazole compound, an acrylonitrile compound, a hydroxyphenyltriazine compound an indole compound, or a triazine compound can be used. The details of the ultraviolet absorber can be found in paragraphs “0052” to “0072” of JP2012-208374A, paragraphs “0317” to “0334” of JP2013-068814A, and paragraphs “0061” to “0080” of JP2016-162946A, the contents of which are incorporated herein by reference. Specific examples of the ultraviolet absorber include compounds having the following structures. Examples of a commercially available product of the ultraviolet absorber include UV-503 (manufactured by Daito Chemical Co., Ltd.). In addition, examples of the benzotriazole compound include MYUA series (manufactured by Miyoshi Oil&Fat Co., Ltd.; The Chemical Daily, Feb. 1, 2016).

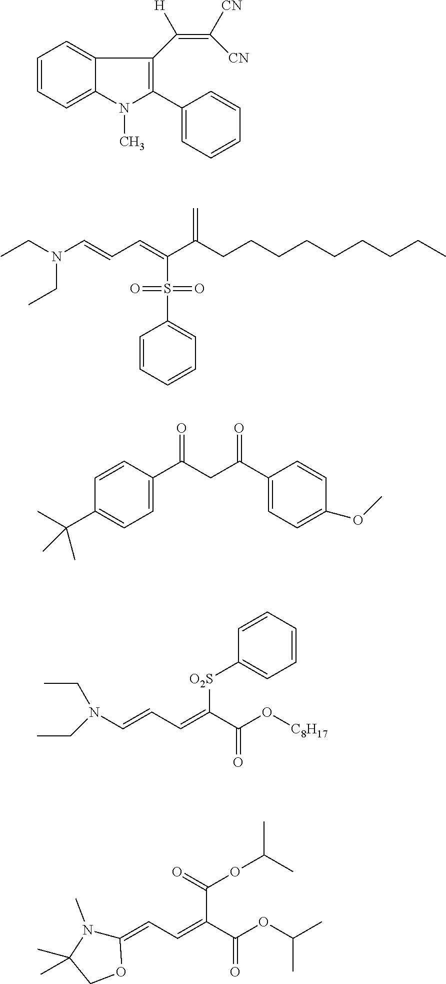

The content of the ultraviolet absorber is preferably 0.01% 7 mass % with respect to the total solid content of the photosensitive composition. From the viewpoint of pattern formability, the upper limit is preferably 6 mass % or lower, more preferably 5 mass % or lower, and still more preferably 4 mass % or lower. From the viewpoint of sensitivity, the lower limit is preferably 0.05 mass % or higher and more preferably 0.1 mass % or higher.

It is also preferable that the photosensitive composition according to the embodiment of the present invention substantially includes an ultraviolet absorber from the viewpoint of sensitivity. The photosensitive composition according to the embodiment of the present invention not substantially including an ultraviolet absorber represents that the content of the ultraviolet absorber is preferably 0.005 mass % or lower, more preferably 0.001 mass % or lower, and still more preferably 0 mass % with respect to the total solid content of the photosensitive composition.

<<Antioxidant>>

The photosensitive composition according to the embodiment of the present invention may include an antioxidant. Examples of the antioxidant include a phenol compound, a phosphite compound, and a thioether compound. As the phenol compound, any phenol compound which is known as a phenol antioxidant can be used. Preferable examples of the phenol compound include a hindered phenol compound. A compound having a substituent at a position (ortho position) adjacent to a phenolic hydroxy group is preferable. As the substituent, a substituted or unsubstituted alkyl group having 1 to 22 carbon atoms is preferable. In addition, as the antioxidant, a compound having a phenol group and a phosphite group in the same molecule is also preferable. In addition, as the antioxidant, a phosphorus antioxidant can also be preferably used. Examples of the phosphorus antioxidant include tris[2-[[2,4,8,10-tetrakis(1,1-dimethylethyl)dibenzo[d,f][1,3,2]dioxaphosphepin-6-yl]oxy]ethyl]amine, tris[2-[(4,6,9,11-tetra-tert-butyldibenzo[d,f][1,3,2]dioxaphosphepin-2-yl)oxy]ethyl]amine, and ethyl bis(2,4-di-tert-butyl-6-methylphenyl)phosphite. Examples of the commercially available product of the antioxidant include ADEKA STAB AO-20, ADEKA STAB AO-30, ADEKA STAB AO-40, ADEKA STAB AO-50, ADEKA STAB AO-50F, ADEKA STAB AO-60, ADEKA STAB AO-60G, ADEKA STAB AO-80, and ADEKA STAB AO-330 (all of which are manufactured by Adeka Corporation).

The content of the antioxidant is preferably 0.1% to 5 mass % with respect to the total solid content of the photosensitive composition. From the viewpoint of pattern formability, the upper limit is preferably 6 mass % or lower, more preferably 5 mass % or lower, and still more preferably 4 mass % or lower. From the viewpoint of resist sensitivity, the lower limit is preferably 0.2 mass % or higher, more preferably 0.3 mass % or higher, and still more preferably 0.4 mass % or higher.

From the viewpoint of resist sensitivity, it is also preferable that the photosensitive composition according to the embodiment of the present invention does not substantially includes an antioxidant. The photosensitive composition according to the embodiment of the present invention not substantially including an antioxidant represents that the content of the antioxidant is preferably 0.05 mass % or lower, more preferably 0.01 mass % or lower, and still more preferably 0 mass % with respect to the total solid content of the photosensitive composition.

<<Other Components>>

Optionally, the photosensitive composition according to the embodiment of the present invention may further include a sensitizer, a curing accelerator, a filler, a thermal curing accelerator, a plasticizer, and other auxiliary agents (for example, conductive particles, an antifoaming agent, a flame retardant, a leveling agent, a peeling accelerator, an aromatic chemical, a surface tension adjuster, or a chain transfer agent). By the composition appropriately including the components, properties such as film properties can be adjusted. The details of the components can be found in, for example, paragraph “0183” of JP2012-003225A (corresponding to paragraph “0237” of US2013/0034812A) and paragraphs “0101” to “0104” and “0107” to “0109” of JP2008-250074A, the contents of which are incorporated herein by reference. In addition, the photosensitive composition according to the embodiment of the present invention may optionally include a potential antioxidant. The potential antioxidant is a compound in which a portion that functions as the antioxidant is protected by a protective group and this protective group is desorbed by heating the compound at 100° C. to 250° C. or by heating the compound at 80° C. to 200° C. in the presence of an acid/a base catalyst. Examples of the potential antioxidant include a compound described in WO2014/021023A, WO2017/030005A, and JP2017-008219A. Examples of a commercially available product of the potential antioxidant include ADEKA ARKLS GPA-5001 (manufactured by Adeka Corporation).

For example, in a case where a film is formed by coating, the viscosity (23° C.) of the photosensitive composition according to the embodiment of the present invention is preferably 1 to 100 mPa·s. The lower limit is more preferably 2 mPa·s or higher and still more preferably 3 mPa·s or higher. The upper limit is preferably 50 mPa·s or lower, more preferably 30 mPa·s or lower, and still more preferably 15 mPa·s or lower.

The concentration of solid contents of the photosensitive composition according to the embodiment of the present invention is preferably 0.01% to 50 mass %. From the viewpoint of film thickness, the lower limit is preferably 0.02 mass % or higher, more preferably 0.03 mass % or higher, and still more preferably 0.05 mass % or higher. From the viewpoint of storage stability, the upper limit is preferably 45 mass % or lower, more preferably 40 mass % or lower, and still more preferably 35 mass % or lower.

<Storage Container>

A storage container of the photosensitive composition according to the embodiment of the present invention is not particularly limited, and a well-known storage container can be used. In addition, as the storage container, in order to suppress infiltration of impurities into the raw materials or the composition, a multilayer bottle in which a container inner wall having a six-layer structure is formed of six kinds of resins or a bottle in which a container inner wall having a seven-layer structure is formed of six kinds of resins is preferably used. Examples of the container include a container described in JP2015-123351A.

<Method of Preparing Photosensitive Composition>

The photosensitive composition according to the embodiment of the present invention can be prepared by mixing the above-described components with each other. During the preparation of the photosensitive composition, all the components may be dissolved or dispersed in a solvent at the same time to prepare the photosensitive composition. Optionally, two or more solutions or dispersion liquids to which the respective components are appropriately added may be prepared, and the solutions or dispersion liquids may be mixed with each other during use (during application) to prepare the photosensitive composition.

In addition, in a case where the photosensitive composition according to the embodiment of the present invention includes particles of a pigment or the like, it is preferable that a process of dispersing the particles is provided. Examples of a mechanical force used for dispersing the particles in the process of dispersing the particles include compression, squeezing, impact, shearing, and cavitation. Specific examples of the process include a beads mill, a sand mill, a roll mill, a ball mill, a paint shaker, a Microfluidizer, a high-speed impeller, a sand grinder, a flow jet mixer, high-pressure wet atomization, and ultrasonic dispersion. During the pulverization of the particles using a sand mill (beads mill), it is preferable that the process is performed under conditions for increasing the pulverization efficiency, for example, by using beads having a small size and increasing the filling rate of the beads. In addition, it is preferable that coarse particles are removed by filtering, centrifugal separation, and the like after pulverization. In addition, as the process and the disperser for dispersing the particles, a process and a disperser described in “Complete Works of Dispersion Technology, Johokiko Co., Ltd., Jul. 15, 2005”, “Dispersion Technique focusing on Suspension (Solid/Liquid Dispersion) and Practical Industrial Application, Comprehensive Reference List, Publishing Department of Management Development Center, Oct. 10, 1978”, and paragraph “0022” JP2015-157893A can be suitably used. In addition, in the process of dispersing the particles, particles may be refined in a salt milling step. A material, a device, process conditions, and the like used in the salt milling step can be found in, for example, JP2015-194521A and JP2012-046629A.

During the preparation of the photosensitive composition according to the embodiment of the present invention, it is preferable that the photosensitive composition is filtered through a filter, for example, in order to remove foreign matter or to reduce defects. As the filter, any filter which is used in the related art for filtering or the like can be used without any particular limitation. Examples of a material of the filter include: a fluororesin such as polytetrafluoroethylene (PTFE); a polyamide resin such as nylon (for example, nylon-6 or nylon-6,6); and a polyolefin resin (including a polyolefin resin having a high density and an ultrahigh molecular weight) such as polyethylene or polypropylene (PP). Among these materials, polypropylene (including high-density polypropylene) or nylon is preferable. The pore size of the filter is suitably about 0.01 to 7.0 μm and is preferably about 0.01 to 3.0 μm and more preferably about 0.05 to 0.5 μm. In a case where the pore size of the filter is in the above-described range, fine foreign matter can be reliably removed. In addition, it is preferable that a fibrous filter material is used. Examples of the fibrous filter material include polypropylene fiber, nylon fiber, and glass fiber. Specific examples include a filter cartridge of SBP type series (for example, SBP008), TPR type series (for example, TPR002 or TPR005), and SHPX type series (for example, SHPX003) all of which are manufactured by Roki Techno Co., Ltd. In a case where a filter is used, a combination of different filters (for example, a first filter and a second filter) may be used. At this time, the filtering using each of the filters may be performed once, or twice or more. In addition, a combination of filters having different pore sizes in the above-described range may be used. In addition, the filtering using the first filter may be performed only on the dispersion liquid, and the filtering using the second filter may be performed on a mixture of the dispersion liquid and other components.

<Method of Manufacturing Optical Filter>

Next, a method of manufacturing an optical filter using the photosensitive composition according to the embodiment of the present invention will be described. Examples of the kind of the optical filter include a near infrared cut filter and a near infrared transmitting filter.

The method of manufacturing an optical filter according to an embodiment of the present invention includes: a step (photosensitive composition layer forming step) of applying the above-described photosensitive composition according to the embodiment of the present invention to a support to form a photosensitive composition layer; a step (exposure step) of exposing (pulse exposure) the photosensitive composition layer to pulses of light in a pattern shape; and a step (development step) of forming a pixel by removing a non-exposed portion of the photosensitive composition layer by development. Hereinafter, the respective steps will be described.

(Photosensitive Composition Layer Forming Step)

In the photosensitive composition layer forming step, the above-described photosensitive composition according to the embodiment of the present invention is applied to a support to form a photosensitive composition layer. Examples of the support include a substrate formed of a material such as silicon, non-alkali glass, soda glass, PYREX (registered trade name) glass, or quartz glass. In addition, for example, an InGaAs substrate is preferably used. In addition, a charge coupled device (CCD), a complementary metal-oxide semiconductor (CMOS), a transparent conductive film, or the like may be formed on the support. In addition, a black matrix that separates pixels from each other may be formed on the support. In addition, optionally, an undercoat layer may be provided on the support to improve adhesiveness with a layer above the support, to prevent diffusion of materials, or to make a surface of the substrate flat.

As a method of applying the photosensitive composition to the support, a well-known method can be used. Examples of the well-known method include: a drop casting method; a slit coating method; a spray coating method; a roll coating method; a spin coating method; a cast coating method; a slit and spin method; a pre-wetting method (for example, a method described in JP2009-145395A); various printing methods including jet printing such as an ink jet method (for example, an on-demand method, a piezoelectric method, or a thermal method) or a nozzle jet method, flexographic printing, screen printing, gravure printing, reverse offset printing, and metal mask printing; a transfer method using a mold or the like; and a nanoimprint lithography method. The application method using an ink jet method is not particularly limited, and examples thereof include a method (in particular, pp. 115 to 133) described in “Extension of Use of Ink Jet—Infinite Possibilities in Patent—” (February, 2005, S.B. Research Co., Ltd.) and methods described in JP2003-262716A, JP2003-185831A, JP2003-261827A, JP2012-126830A, and JP2006-169325A. In addition, as the method of applying the photosensitive composition, methods described in WO2017/030174A and WO2017/018419A can also be used, the contents of which are incorporated herein by reference.

The photosensitive composition may be dried (pre-baked) after being applied to the support. In a case where pre-baking is performed, the pre-baking temperature is preferably 150° C. or lower, more preferably 120° C. or lower, and still more preferably 110° C. or lower. The lower limit is, for example, 50° C. or higher or 80° C. or higher. The pre-baking time is preferably 10 to 3000 seconds, more preferably 40 to 2500 seconds, and still more preferably 80 to 2200 seconds. Drying can be performed using a hot plate, an oven, or the like.

(Exposure Step)

Next, the photosensitive composition layer formed on the support as described above is exposed (pulse exposure) to pulses of light in a pattern shape. By exposing the photosensitive composition layer to pulses of light through a mask having a predetermined mask pattern, the photosensitive composition layer can be exposed to pulses of light in a pattern shape. As a result, the exposed portion of the photosensitive composition layer can be cured.

The light used for the pulse exposure may be light having a wavelength of longer than 300 nm or light having a wavelength of 300 nm or shorter. From the viewpoint of easily obtaining higher pattern formability or curing properties, the light used for the exposure is preferably light having a wavelength of 300 nm or shorter, more preferably light having a wavelength of 270 nm or shorter, and still more preferably light having a wavelength of 250 nm or shorter. In addition, the above-described light is preferably light having a wavelength of 180 nm or longer. Specific examples of the light include a KrF ray (wavelength: 248 nm) and an ArF ray (wavelength: 193 nm). From the viewpoint of easily obtaining higher pattern formability, curing properties, and the like, a KrF ray (wavelength: 248 nm) is preferable.

It is preferable that the pulse exposure condition is the following condition. From the viewpoint of instantaneously generating a large amount of an active species such as a radical easily, the pulse duration is preferably 100 nanoseconds (ns) or shorter, more preferably 50 nanoseconds or shorter, and still more preferably 30 nanoseconds or shorter. The lower limit of the pulse duration is not particularly limited and may be 1 femtoseconds (fs) or longer or 10 femtoseconds (fs) or longer. From the viewpoint of easily thermally polymerizing the compound C due to exposure heat, the frequency is preferably 1 kHz or higher, more preferably 2 kHz or higher, and still more preferably 4 kHz or higher. From the viewpoint of easily suppressing deformation of a substrate or the like caused by exposure heat, the upper limit of the frequency is preferably 50 kHz or lower, more preferably 20 kHz or lower, and still more preferably 10 kHz or lower. From the viewpoint of curing properties, the maximum instantaneous illuminance is preferably 50000000 W/m² or higher, more preferably 100000000 W/m² or higher, and still more preferably 200000000 W/m² or higher. In addition, from the viewpoint of high illuminance reciprocity failure, the upper limit of the maximum instantaneous illuminance is preferably 1000000000 W/m² or lower, more preferably 800000000 W/m² or lower, and still more preferably 500000000 W/m² or lower. The exposure dose is preferably 1 to 1000 mJ/cm². The upper limit is preferably 500 mJ/cm² or lower and more preferably 200 mJ/cm² or lower. The lower limit is preferably 10 mJ/cm² or higher, more preferably 20 mJ/cm² or higher, and still more preferably 30 mJ/cm² or higher.

The oxygen concentration during exposure can be appropriately selected. The exposure may be performed not only in air but also in a low-oxygen atmosphere having an oxygen concentration of 19 vol % or lower (for example, 15 vol %, 5 vol %, or substantially 0 vol %) or in a high-oxygen atmosphere having an oxygen concentration of higher than 21 vol % (for example, 22 vol %, 30 vol %, or 50 vol %).

(Development Step)

Next, after the exposure step, a pixel (pattern) is formed by removing a non-exposed portion of the photosensitive composition layer by development. The non-exposed portion of the photosensitive composition layer can be removed by development using a developer. As a result, the non-exposed portion of the photosensitive composition layer in the exposure step is eluted into the developer, and only the portion that is photocured in the above-described exposure step remains on the support. For example, the temperature of the developer is preferably 20° C. to 30° C. The development time is preferably 20 to 180 seconds. In addition, in order to further improve residue removing properties, a step of shaking the developer off per 60 seconds and supplying a new developer may be repeated multiple times.

As the developer, an alkaline aqueous solution in which the above alkaline agent is diluted with pure water is preferable. Examples of the alkaline agent include: an organic alkaline compound such as ammonia, ethylamine, diethylamine, dimethylethanolamine, diglycolamine, diethanolamine, hydroxyamine, ethylenediamine, tetramethylammonium hydroxide, tetraethylammonium hydroxide, tetrapropyl ammonium hydroxide, tetrabutylammonium hydroxide, ethyltrimethylammonium hydroxide, benzyltrimethylammonium hydroxide, dimethyl bis(2-hydroxyethyl)ammonium hydroxide, choline, pyrrole, piperidine, or 1,8-diazabicyclo[5.4.0]-7-undecene; and an inorganic alkaline compound such as sodium hydroxide, potassium hydroxide, sodium carbonate, sodium bicarbonate, sodium silicate, or sodium metasilicate. From the viewpoints of environment and safety, it is preferable that the alkaline agent is a compound having a high molecular weight. A concentration of the alkaline agent in the alkaline aqueous solution is preferably 0.001 to 10 mass % and more preferably 0.01 to 1 mass %. In addition, the developer may further include a surfactant. Examples of the surfactant include the above-described surfactants. Among these, a nonionic surfactant is preferable. From the viewpoint of easiness of transport, storage, and the like, the developer may be obtained by temporarily preparing a concentrated solution and diluting the concentrated solution to a necessary concentration during use. The dilution factor is not particularly limited and, for example, can be set to be in a range of 1.5 to 100 times. In a case where the alkaline aqueous solution is used as the developer, it is preferable that the layer is rinsed with pure water after development.

After the development and drying, an additional exposure treatment or a heating treatment (post-baking) can also be performed. The additional exposure treatment or the post-baking is a treatment which is performed after development to completely cure the film. In a case where the additional exposure treatment is performed, as light used for the exposure, for example, a g-ray, a h-ray, or an i-ray is preferable, and an i-ray is more preferable. In addition, a combination of the above-described rays may be used.

It is preferable that the thickness of the pixel (pattern) to be formed is appropriately selected depending on the kind of the pixel. For example, the thickness of the pixel is preferably 2.0 μm or less, more preferably 1.0 μm or less, and still more preferably 0.3 to 1.0 pin. The upper limit is preferably 0.8 μm or less and more preferably 0.6 μm or less. The lower limit value is preferably 0.4 μm or more.

In addition, it is preferable that the size (line width) of the pixel (pattern) to be formed is selected depending on the use or the kind of the pixel. For example, the size of the pixel is preferably 2.0 μm or less. The upper limit is preferably 1.0 μm or less and more preferably 0.9 μm or less. The lower limit value is preferably 0.4 μm or more.

In a case where an optical filter including plural kinds of pixels is manufactured, at least one kind of pixel may be formed through the above-described steps, and it is preferable that a pixel to be initially formed (the first kind of pixel) is formed through the above-described steps. A pixel to be secondly or subsequently formed (the second or subsequent kind of pixel) may be formed through the above-described steps or may be formed by exposure using continuous light.

### EXAMPLES

Hereinafter, the present invention will be described in more detail using examples. However, the present invention is not limited to the following examples as long as it does not depart from the scope of the present invention. Unless specified otherwise, “part(s)” represents “part(s) by mass”. In addition, in the following structural formulae, Me represents a methyl group, Et represents an ethyl group, and Ph represents a phenyl group.

<Measurement of Weight-Average Molecular Weight (Mw) of Resin>

The weight-average molecular weight of the resin can be measured under the following conditions by gel permeation chromatography (GPC).

Kind of column: a column in which TOSOH TSK gel Super HZM-H, TOSOH TSK gel Super HZ4000, and TOSOH TSK gel Super HZ2000 were linked to each other

Developing solvent: tetrahydrofuran

Column temperature: 40° C.

Flow rate (sample injection volume): 1.0 μL (sample concentration: 0.1 mass %)

Device name: HLC-8220 GPC (manufactured by Tosoh Corporation)

Detector: refractive index (RI) detector

Calibration curve base resin: a polystyrene resin

<Manufacturing of Pigment Dispersion Liquid>

Raw materials shown in the Table 1 below were mixed with each other, 230 parts by mass of zirconia beads having a diameter of 0.3 mm were further added to the mixture, and the solution was dispersed using a paint shaker for 5 hours. Next, the beads were separated by filtration. As a result, a pigment dispersion liquid was manufactured. Numerical values in the following table are represented by “part(s) by mass”.

TABLE 1

| | | | Dispersing Auxiliary | | | | | |
|---|---|---|---|---|---|---|---|---|
| | | | Agent | | | | | |
| | Coloring Material and Near | | (Pigment Derivative | | | | | |
| | Infrared Absorber | | or Resin) | | Dispersant | | Solvent | |
| | | Part(s) | | Part(s) | | Part(s) | | Part(s) |
| | Kind | by Mass | Kind | by Mass | Kind | by Mass | Kind | by Mass |
| Pigment Dispersion | PR254 | 12.00 | | | C1 | 4.2 | J1 | 83.80 |
| Liquid R-1 | | | | | | | | |
| Pigment Dispersion | PR254 | 8.3 | B1 | 2.3 | C2 | 4.4 | J1 | 81.30 |
| Liquid R-2 | PY139 | 3.7 | | | | | | |
| Pigment Dispersion | PY139 | 11.00 | B1 | 1.59 | C2 | 4.4 | J1 | 83.01 |
| Liquid Y-1 | | | | | | | | |
| Pigment Dispersion | PY150 | 11.00 | B1 | 1.59 | C2 | 4.4 | J1 | 83.01 |
| Liquid Y-2 | | | | | | | | |
| Pigment Dispersion | PV23 | 14.20 | P1 | 2 | C2 | 3.8 | J1 | 70.00 |
| Liquid V-1 | | | | | | | J2 | 10.00 |
| Pigment Dispersion | PB15:6 | 12.59 | | | C2 | 4.4 | J1 | 83.01 |
| Liquid B-1 | | | | | | | | |
| Pigment Dispersion | PB15:6 | 10.00 | | | C2 | 4.4 | J1 | 83.01 |
| Liquid B-2 | PV23 | 2.59 | | | | | | |
| Pigment Dispersion | IB | 12.59 | | | C1 | 4.4 | J1 | 83.01 |
| Liquid Bk-1 | | | | | | | | |
| Pigment Dispersion | PBk32 | 12.59 | | | C2 | 4.4 | J1 | 83.01 |
| Liquid Bk-2 | | | | | | | | |
| Pigment Dispersion | PR254 | 6.92 | | | C3 | 8.1 | J1 | 73.9 |
| Liquid Bk-3 | PY139 | 4.02 | | | | | | |
| | PB15:6 | 7.06 | | | | | | |
| Pigment Dispersion | K1 | 11.00 | B1 | 1.59 | C2 | 6 | J1 | 81.41 |
| Liquid IR-1 | | | | | | | | |
| Pigment Dispersion | K2 | 6.70 | K3 | 0.8 | C3 | 6.0 | J1 | 86.50 |
| Liquid IR-2 | | | | | | | | |
| Pigment Dispersion | K2 | 6.70 | K4 | 0.8 | | | | |
| Liquid IR-3 | | | | | C3 | 6.0 | J1 | 86.50 |
| Pigment Dispersion | K2 | 6.70 | K5 | 0.8 | | | | |
| Liquid IR-4 | | | | | C2 | 6 | J1 | 86.50 |
| Pigment Dispersion | K6 | 6.70 | B1 | 0.8 | | | | |
| Liquid IR-5 | | | | | C2 | 6 | J1 | 86.50 |
| Pigment Dispersion | K7 | 6.70 | B1 | 0.8 | | | | |
| Liquid IR-6 | | | | | | | | |
| Pigment Dispersion | K8 | 6.70 | B1 | 0.8 | C2 | 6 | J1 | 86.50 |
| Liquid IR-7 | | | | | | | | |

<Preparation of Photosensitive Composition>

Raw materials shown in the following table were mixed and stirred at a ratio (part(s) by mass) shown in the following table, and the mixture was filtered through a nylon filter (manufactured by Pall Corporation) having a pore size of 0.45 μm. As a result, compositions according to Preparation Examples 1 to 52 were prepared. Numerical values in the following table are represented by “part(s) by mass”.

TABLE 2

| | | Prepar- | Prepar- | Prepar- | Prepar- | Prepar- | Prepar- | Prepar- | Prepar- | Prepar- | Prepar- |
|---|---|---|---|---|---|---|---|---|---|---|---|
| | | ation | ation | ation | ation | ation | ation | ation | ation | ation | ation |
| | | Exam- | Exam- | Exam- | Exam- | Exam- | Exam- | Exam- | Exam- | Exam- | Exam- |
| | | ple 1 | ple 2 | ple 3 | ple 4 | ple 5 | ple 6 | ple 7 | ple 8 | ple 9 | ple 10 |
| Near | A1 | 3.5 | | | | | | | | | |
| Infrared | A2 | | 3.5 | | | | | | | | |
| Absorber | A3 | | | 3.5 | | | | | | | |
| | A4 | | | | 3.5 | | | | | | |
| | A5 | | | | | 3.5 | | | | | |
| | A6 | | | | | | 3.5 | | | | |
| | A7 | | | | | | | 3.5 | | | |
| | A8 | | | | | | | | 3.5 | | |
| | A9 | | | | | | | | | 3.5 | |
| | A10 | | | | | | | | | | 3.5 |
| | A11 | | | | | | | | | | |
| | A12 | | | | | | | | | | |
| | A13 | | | | | | | | | | |
| | A14 | | | | | | | | | | |
| | A15 | | | | | | | | | | |
| | A16 | | | | | | | | | | |
| | A17 | | | | | | | | | | |
| | A18 | | | | | | | | | | |
| | A19 | | | | | | | | | | |
| | A20 | | | | | | | | | | |
| | A21 | | | | | | | | | | |
| | A22 | | | | | | | | | | |
| | A23 | | | | | | | | | | |
| Pigment | R-1 | | | | | | | | | | |
| Dispersion | R-2 | | | | | | | | | | |
| Liquid | Y-1 | | | | | | | | | | |
| | Y-2 | | | | | | | | | | |
| | V-1 | | | | | | | | | | |
| | B-1 | | | | | | | | | | |
| | B-2 | | | | | | | | | | |
| | Bk-1 | | | | | | | | | | |
| | Bk-2 | | | | | | | | | | |
| | Bk-3 | | | | | | | | | | |
| | IR-1 | | | | | | | | | | |
| | IR-2 | | | | | | | | | | |
| | IR-3 | | | | | | | | | | |
| | IR-4 | | | | | | | | | | |
| | IR-5 | | | | | | | | | | |
| | IR-6 | | | | | | | | | | |
| | IR-7 | | | | | | | | | | |
| Poly- | D1 | | | | | | | | | | |
| merizable | D2 | | | | | | | | | | |
| Compound | D3 | | | | | | | | | | |
| | D4 | | | | | | | | | | |
| | D5 | 2.80 | 2.80 | 2.80 | 2.80 | 2.80 | 2.80 | 2.80 | 2.80 | 2.80 | 2.80 |
| | D7 | | | | | | | | | | |
| | D8 | | | | | | | | | | |
| Photo- | I1 | 1.260 | 1.260 | 1.260 | 1.260 | 1.260 | 1.260 | 1.260 | 1.260 | 1.260 | 1.260 |
| initiator | I2 | | | | | | | | | | |
| | I3 | | | | | | | | | | |
| | I4 | | | | | | | | | | |
| | I5 | | | | | | | | | | |
| | I6 | | | | | | | | | | |
| | I7 | | | | | | | | | | |
| | I8 | | | | | | | | | | |
| Resin | P1 | | | | | | | | | | |
| | P2 | | | | | | | | | | |
| | P3 | 10.19 | 10.19 | 10.19 | 10.19 | 10.19 | 10.19 | 10.19 | 10.19 | 10.19 | 10.19 |
| | P4 | | | | | | | | | | |
| Silane | H1 | | | | | | | | | | |
| Coupling | | | | | | | | | | | |
| Agent | | | | | | | | | | | |
| Ultraviolet | U1 | | | | | | | | | | |
| Absorber | U2 | | | | | | | | | | |
| Surfactant | W1 | | | | | | | | | | |
| | W2 | 9.67 | 9.67 | 9.67 | 9.67 | 9.67 | 9.67 | 9.67 | 9.67 | 9.67 | 9.67 |
| Antioxidant | Y1 | | | | | | | | | | |
| Poly- | G1 | 0.0001 | 0.0001 | 0.0001 | 0.0001 | 0.0001 | 0.0001 | 0.0001 | 0.0001 | 0.0001 | 0.0001 |
| merization | | | | | | | | | | | |
| Inhibitor | | | | | | | | | | | |
| Solvent | J1 | | | | | | | | | | |
| | J2 | 72.58 | 72.58 | 72.58 | 72.58 | 72.58 | 72.58 | 72.58 | 72.58 | 72.58 | 72.58 |
| | J3 | | | | | | | | | | |

TABLE 3

| | | Prepar- | Prepar- | Prepar- | Prepar- | Prepar- | Prepar- | Prepar- | Prepar- | Prepar- | Prepar- |
|---|---|---|---|---|---|---|---|---|---|---|---|
| | | ation | ation | ation | ation | ation | ation | ation | ation | ation | ation |
| | | Exam- | Exam- | Exam- | Exam- | Exam- | Exam- | Exam- | Exam- | Exam- | Exam- |
| | | ple 11 | ple 12 | ple 13 | ple 14 | ple 15 | ple 16 | ple 17 | ple 18 | ple 19 | ple 20 |
| Near | A1 | | | | | | | | | | |
| Infrared | A2 | | | | | | | | | | |
| Absorber | A3 | | | | | | | | | | |
| | A4 | | | | | | | | | | |
| | A5 | | | | | | | | | | |
| | A6 | | | | | | | | | | |
| | A7 | | | | | | | | | | |
| | A8 | | | | | | | | | | |
| | A9 | | | | | | | | | | |
| | A10 | | | | | | | | | | |
| | A11 | 3.5 | | | | | | | | | |
| | A12 | | 3.5 | | | | | | | | |
| | A13 | | | 3.5 | | | | | | | |
| | A14 | | | | 3.5 | | | | | | |
| | A15 | | | | | 3.5 | | | | | |
| | A16 | | | | | | 3.5 | | | | |
| | A17 | | | | | | | 3.5 | | | |
| | A18 | | | | | | | | 3.5 | | |
| | A19 | | | | | | | | | 3.5 | |
| | A20 | | | | | | | | | | 3.5 |
| | A21 | | | | | | | | | | |
| | A22 | | | | | | | | | | |
| | A23 | | | | | | | | | | |
| Pigment | R-1 | | | | | | | | | | |
| Dispersion | R-2 | | | | | | | | | | |
| Liquid | Y-1 | | | | | | | | | | |
| | Y-2 | | | | | | | | | | |
| | V-1 | | | | | | | | | | |
| | B-1 | | | | | | | | | | |
| | B-2 | | | | | | | | | | |
| | Bk-1 | | | | | | | | | | |
| | Bk-2 | | | | | | | | | | |
| | Bk-3 | | | | | | | | | | |
| | IR-1 | | | | | | | | | | |
| | IR-2 | | | | | | | | | | |
| | IR-3 | | | | | | | | | | |
| | IR-4 | | | | | | | | | | |
| | IR-5 | | | | | | | | | | |
| | IR-6 | | | | | | | | | | |
| | IR-7 | | | | | | | | | | |
| Poly- | D1 | | | | | | | | | | |
| merizable | D2 | | | | | | | | | | |
| Compound | D3 | | | | | | | | | | |
| | D4 | | | | | | | | | | |
| | D5 | 2.80 | 2.80 | 2.80 | 2.80 | 2.80 | 2.80 | 2.80 | 2.80 | 2.80 | 2.80 |
| | D7 | | | | | | | | | | |
| | D8 | | | | | | | | | | |
| Photo- | I1 | 1.260 | 1.260 | 1.260 | 1.260 | 1.260 | 1.260 | 1.260 | 1.260 | 1.260 | 1.260 |
| initiator | I2 | | | | | | | | | | |
| | I3 | | | | | | | | | | |
| | I4 | | | | | | | | | | |
| | I5 | | | | | | | | | | |
| | I6 | | | | | | | | | | |
| | I7 | | | | | | | | | | |
| | I8 | | | | | | | | | | |
| Resin | P1 | | | | | | | | | | |
| | P2 | | | | | | | | | | |
| | P3 | 10.19 | 10.19 | 10.19 | 10.19 | 10.19 | 10.19 | 10.19 | 10.19 | 10.19 | 10.19 |
| | P4 | | | | | | | | | | |
| Silane | H1 | | | | | | | | | | |
| Coupling | | | | | | | | | | | |
| Agent | | | | | | | | | | | |
| Ultraviolet | U1 | | | | | | | | | | |
| Absorber | U2 | | | | | | | | | | |
| Surfactant | W1 | | | | | | | | | | |
| | W2 | 9.67 | 9.67 | 9.67 | 9.67 | 9.67 | 9.67 | 9.67 | 9.67 | 9.67 | 9.67 |
| Antioxidant | Y1 | | | | | | | | | | |
| Poly- | G1 | 0.0001 | 0.0001 | 0.0001 | 0.0001 | 0.0001 | 0.0001 | 0.0001 | 0.0001 | 0.0001 | 0.0001 |
| merization | | | | | | | | | | | |
| Inhibitor | | | | | | | | | | | |
| Solvent | J1 | | | | | | | | | | |
| | J2 | 72.58 | 72.58 | 72.58 | 72.58 | 72.58 | 72.58 | 72.58 | 72.58 | 72.58 | 72.58 |
| | J3 | | | | | | | | | | |

TABLE 4

| | | Prepar- | Prepar- | Prepar- | Prepar- | Prepar- | Prepar- | Prepar- | Prepar- | Prepar- | Prepar- |
|---|---|---|---|---|---|---|---|---|---|---|---|
| | | ation | ation | ation | ation | ation | ation | ation | ation | ation | ation |
| | | Exam- | Exam- | Exam- | Exam- | Exam- | Exam- | Exam- | Exam- | Exam- | Exam- |
| | | ple 21 | ple 22 | ple 23 | ple 24 | ple 25 | ple 26 | ple 27 | ple 28 | ple 29 | ple 30 |
| Near | A1 | | | | | | | | | | |
| Infrared | A2 | | | | | | | | | | |
| Absorber | A3 | | | | | | | | | | |
| | A4 | | | | | | | | | | |
| | A5 | | | | | | | | | | |
| | A6 | | | | | | | | | | |
| | A7 | | | | | | | | | | |
| | A8 | | | | | | | | | | |
| | A9 | | | | | | | | | | |
| | A10 | | | | | | | | | | |
| | A11 | | | | | | | | | | |
| | A12 | | | | | | | | | | |
| | A13 | | | | | | | | | | |
| | A14 | | | | | | | | | | |
| | A15 | | | | | | | | | | |
| | A16 | | | | | | | | | | |
| | A17 | | | | | | | | | | |
| | A18 | | | | | | | | | | |
| | A19 | | | | | | | | | | |
| | A20 | | | | | | | | | | |
| | A21 | 3.5 | | | | | | | | | |
| | A22 | | 3.5 | | | | | | | | |
| | A23 | | | 3.5 | | | | | | | |
| Pigment | R-1 | | | | | | | | | | |
| Dispersion | R-2 | | | | | | | | | | |
| Liquid | Y-1 | | | | | | | | | | |
| | Y-2 | | | | | | | | | | |
| | V-1 | | | | | | | | | | |
| | B-1 | | | | | | | | | | |
| | B-2 | | | | | | | | | | |
| | Bk-1 | | | | | | | | | | |
| | Bk-2 | | | | | | | | | | |
| | Bk-3 | | | | | | | | | | |
| | IR-1 | | | | | | | | | | |
| | IR-2 | | | | | | | | | | |
| | IR-3 | | | | | | | | | | |
| | IR-4 | | | | 77.95 | 77.95 | 77.95 | 77.95 | 63.20 | 77.95 | 77.95 |
| | IR-5 | | | | | | | | | | |
| | IR-6 | | | | | | | | | | |
| | IR-7 | | | | | | | | | | |
| Poly- | D1 | | | | | | | | | | |
| merizable | D2 | | | | | | | | | | |
| Compound | D3 | | | | | | | | | 1.26 | |
| | D4 | | | | 1.26 | 1.10 | 1.42 | 0.65 | 1.50 | | 1.26 |
| | D5 | 2.80 | 2.80 | 2.80 | | | | | | | |
| | D7 | | | | 1.22 | 1.10 | 1.42 | 0.70 | 1.50 | 1.22 | 1.22 |
| | D8 | | | | | | | | | | |
| Photo- | I1 | 1.260 | 1.260 | 1.260 | 0.784 | 0.784 | 0.784 | 0.500 | 1.027 | 0.784 | 0.600 |
| initiator | I2 | | | | | | | | | | 0.184 |
| | I3 | | | | | | | | | | |
| | I4 | | | | | | | | | | |
| | I5 | | | | | | | | | | |
| | I6 | | | | | | | | | | |
| | I7 | | | | | | | | | | |
| | I8 | | | | | | | | | | |
| Resin | P1 | | | | | | | | | | |
| | P2 | | | | | | | | | | |
| | P3 | 10.19 | 10.19 | 10.19 | 1.403 | 1.403 | 1.403 | 0.7 | 1.403 | 1.403 | 1.403 |
| | P4 | | | | | | | | | | |
| Silane | H1 | | | | | | | | | | |
| Coupling | | | | | | | | | | | |
| Agent | | | | | | | | | | | |
| Ultraviolet | U1 | | | | 0.474 | 0.79 | 0.158 | | 0.17 | 0.474 | 0.474 |
| Absorber | U2 | | | | | | | | | | |
| Surfactant | W1 | | | | 2.5 | 2.5 | 2.5 | 2.5 | 2.5 | 2.5 | 2.5 |
| | W2 | 9.67 | 9.67 | 9.67 | | | | | | | |
| Antioxidant | Y1 | | | | 0.158 | 0.158 | 0.158 | 0.158 | 0.17 | 0.158 | 0.158 |
| Poly- | G1 | 0.0001 | 0.0001 | 0.0001 | 0.001 | 0.001 | 0.001 | 0.001 | 0.001 | 0.001 | 0.001 |
| merization | | | | | | | | | | | |
| Inhibitor | | | | | | | | | | | |
| Solvent | J1 | | | | 14.253 | 14.212 | 14.213 | 16.841 | 28.54 | 14.25 | 14.25 |
| | J2 | 72.58 | 72.58 | 72.58 | | | | | | | |
| | J3 | | | | | | | | | | |

TABLE 5

| | | Prepar- | Prepar- | Prepar- | Prepar- | Prepar- | Prepar- | Prepar- | Prepar- | Prepar- | Prepar- |
|---|---|---|---|---|---|---|---|---|---|---|---|
| | | ation | ation | ation | ation | ation | ation | ation | ation | ation | ation |
| | | Exam- | Exam- | Exam- | Exam- | Exam- | Exam- | Exam- | Exam- | Exam- | Exam- |
| | | ple 31 | ple 32 | ple 33 | ple 34 | ple 35 | ple 36 | ple 37 | ple 38 | ple 39 | ple 40 |
| Near | A1 | | | | | | | | | | |
| Infrared | A2 | | | | | | | | | | |
| Absorber | A3 | | | | | | | | | | |
| | A4 | | | | | | | | | | |
| | A5 | | | | | | | | | | |
| | A6 | | | | | | | | | | |
| | A7 | | | | | | | | | | |
| | A8 | | | | | | | | | | |
| | A9 | | | | | | | | | | |
| | A10 | | | | | | | | | | |
| | A11 | | | | | | | | | | |
| | A12 | | | | | | | | | | |
| | A13 | | | | | | | | | | |
| | A14 | | | | | | | | | | |
| | A15 | | | | | | | | | | |
| | A16 | | | | | | | | | | |
| | A17 | | | | | | | | | | |
| | A18 | | | | | | | | | | |
| | A19 | | | | | | | | | | |
| | A20 | | | | | | | | | | |
| | A21 | | | | | | | | | | |
| | A22 | | | | | | | | | | |
| | A23 | | | | | | | | | | |
| Pigment | R-1 | | | | | | | | | | |
| Dispersion | R-2 | | | | | | | | | | 17.16 |
| Liquid | Y-1 | | | | | | | | | | 13.14 |
| | Y-2 | | | | | | | | | | |
| | V-1 | | | | | | | | | | 6.18 |
| | B-1 | | | | | | | | | | 18.27 |
| | B-2 | | | | | | | | | | |
| | Bk-1 | | | | | | | | | | |
| | Bk-2 | | | | | | | | | | |
| | Bk-3 | | | | | | | | | | |
| | IR-1 | | | | | | | | | | 21.50 |
| | IR-2 | | | | | | | | | | |
| | IR-3 | | | | | | | | | | |
| | IR-4 | 77.95 | 77.95 | 77.95 | 77.95 | 77.95 | 77.95 | | | | |
| | IR-5 | | | | | | | 77.95 | | | |
| | IR-6 | | | | | | | | 77.95 | | |
| | IR-7 | | | | | | | | | 77.95 | |
| Poly- | D1 | | | | | | | | | | 0.80 |
| merizable | D2 | | | | | | | | | | 1.00 |
| Compound | D3 | | | | | | | | | | 0.80 |
| | D4 | 1.26 | 1.26 | 1.26 | 1.26 | | 2.48 | 1.26 | 1.26 | 1.26 | |
| | D5 | | | | | | | | | | |
| | D7 | 0.72 | 1.22 | 1.22 | 1.22 | | | 1.22 | 1.22 | 1.22 | |
| | D8 | | | | | 2.48 | | | | | |
| Photo- | I1 | 0.784 | | | 0.684 | 0.684 | 0.684 | 0.784 | 0.784 | 0.784 | |
| initiator | I2 | | | | | | | | | | |
| | I3 | | | | | | | | | | 0.540 |
| | I4 | | | | | | | | | | 0.400 |
| | I5 | | | | | | | | | | |
| | I6 | | 0.784 | | | | | | | | |
| | I7 | | | 0.784 | | | | | | | |
| | I8 | | | | 0.100 | 0.100 | 0.100 | | | | |
| Resin | P1 | | | | | | | | | | |
| | P2 | | | | | | | | | | 2.99 |
| | P3 | 1.403 | 1.403 | 1.403 | 1.403 | 1.403 | 1.403 | 1.403 | 1.403 | 1.403 | 5.98 |
| | P4 | | | | | | | | | | |
| Silane | H1 | 0.50 | | | | | | | | | |
| Coupling | | | | | | | | | | | |
| Agent | | | | | | | | | | | |
| Ultraviolet | U1 | 0.474 | 0.474 | 0.474 | 0.474 | 0.474 | 0.474 | 0.474 | 0.474 | 0.474 | 2.99 |
| Absorber | U2 | | | | | | | | | | 2.99 |
| | W1 | 2.5 | 2.5 | 2.5 | 2.5 | 2.5 | 2.5 | 2.5 | 2.5 | 2.5 | |
| Surfactant | W2 | | | | | | | | | | 0.04 |
| Antioxidant | Y1 | 0.158 | 0.158 | 0.158 | 0.158 | 0.158 | 0.158 | 0.158 | 0.158 | 0.158 | 2.99 |
| Poly- | G1 | 0.001 | 0.001 | 0.001 | 0.001 | 0.001 | 0.001 | 0.001 | 0.001 | 0.001 | 0.0013 |
| merization | | | | | | | | | | | |
| Inhibitor | | | | | | | | | | | |
| Solvent | J1 | 14.25 | 14.25 | 14.25 | 14.25 | 14.25 | 14.25 | 14.25 | 14.25 | 14.25 | 2.23 |
| | J2 | | | | | | | | | | |
| | J3 | | | | | | | | | | |

TABLE 6

| | | Prepar- | Prepar- | Prepar- | Prepar- | Prepar- | Prepar- | Prepar- | Prepar- | Prepar- | Prepar- |
|---|---|---|---|---|---|---|---|---|---|---|---|
| | | ation | ation | ation | ation | ation | ation | ation | ation | ation | ation |
| | | Exam- | Exam- | Exam- | Exam- | Exam- | Exam- | Exam- | Exam- | Exam- | Exam- |
| | | ple 41 | ple 42 | ple 43 | ple 44 | ple 45 | ple 46 | ple 47 | ple 48 | ple 49 | ple 50 |
| Near | A1 | | | | | | | | | | |
| Infrared | A2 | | | | | | | | | | |
| Absorber | A3 | | | | | | | | | | |
| | A4 | | | | | | | | | | |
| | A5 | | | | | | | | | | |
| | A6 | | | | | | | | | | |
| | A7 | | | | | | | | | | |
| | A8 | | | | | | | | | | |
| | A9 | | | | | | | | | | |
| | A10 | | | | | | | | | | |
| | A11 | | | | | | | | | | |
| | A12 | | | | | | | | | | |
| | A13 | | | | | | | | 3.5 | 3.5 | 1.45 |
| | A14 | | | | | | | | | | |
| | A15 | | | | | | | | | | |
| | A16 | | | | | | | | | | |
| | A17 | | | | | | | | | | |
| | A18 | | | | | | | | | | |
| | A19 | | | | | | | | | | |
| | A20 | | | | | | | | | | |
| | A21 | | | | | | | | | | |
| | A22 | | | | | | | | | | |
| | A23 | | | | | | | | | | |
| Pigment | R-1 | | | | | 20.45 | | 25.69 | | | |
| Dispersion | R-2 | 18.49 | 24.37 | | | | | | | | |
| Liquid | Y-1 | 14.28 | | 16.95 | 7.82 | 13.14 | | 14.23 | 9.50 | 9.50 | 4.40 |
| | Y-2 | | | | | | | | | | |
| | V-1 | | | | | 6.18 | | | | | |
| | B-1 | 27.22 | | 15.45 | | 8.27 | | 24.99 | 12.50 | 12.50 | |
| | B-2 | | 38.04 | | 20.34 | | | | | | 15.64 |
| | Bk-1 | | | | 34.77 | | | | | | 41.66 |
| | Bk-2 | | | 32.16 | | | | | 45.20 | 43.20 | |
| | Bk-3 | | | | | | 49.01 | | | | |
| | IR-1 | 21.50 | 20.00 | 21.50 | 20.00 | 21.50 | | | 16.10 | | 17.75 |
| | IR-2 | | | | | | | 23.73 | | | |
| | IR-3 | | | | | | 26.11 | | | | |
| | IR-4 | | | | | | | | | | |
| | IR-5 | | | | | | | | | | |
| | IR-6 | | | | | | | | | 20.10 | |
| | IR-7 | | | | | | | | | | |
| Poly- | D1 | 0.92 | 0.54 | 1.89 | | 2.60 | | 1.13 | 1.04 | 1.89 | |
| merizable | D2 | 0.26 | | | | | | 0.72 | | | |
| Compound | D3 | 0.20 | | | | | | | | | |
| | D4 | 0.92 | | | | | 2.87 | | 0.85 | | |
| | D5 | | 1.00 | | 1.98 | | | 0.76 | | | 1.98 |
| | D7 | | 1.00 | | 1.98 | | | 0.76 | | | 1.98 |
| | D8 | | | | | | | | | | |
| Photo- | I1 | | 0.876 | | | 0.940 | 0.261 | | 0.315 | | |
| initiator | I2 | 0.793 | | | 0.344 | | 0.910 | | 0.340 | | 0.344 |
| | I3 | | | 0.655 | | | | 1.065 | | | |
| | I4 | | | | 0.340 | | | | | | 0.340 |
| | I5 | | | | | | | | | 0.655 | |
| | I6 | | | | | | | | | | |
| | I7 | | | | | | | | | | |
| | I8 | | | | | | | | | | |
| Resin | P1 | 2.45 | 3.41 | 2.53 | 2.95 | 2.88 | 1.64 | 2.3 | 2.33 | 0.53 | 2.95 |
| | P2 | | | | | | | | | | |
| | P3 | | | | | | | | | | |
| | P4 | | | | | | | | | | |
| Silane | H1 | | 0.53 | | | | | | | | |
| Coupling | | | | | | | | | | | |
| Agent | | | | | | | | | | | |
| Ultraviolet | U1 | | | | | | | | | | |
| Absorber | U2 | | | | | | | | | | |
| Surfactant | W1 | | | | | | | | | | |
| | W2 | 0.04 | 0.04 | 0.04 | 0.04 | 0.04 | 0.05 | 0.05 | 0.04 | 0.04 | 0.04 |
| Antioxidant | Y1 | | | | | | | 1 | | | |
| Poly- | G1 | 0.0011 | 0.0013 | 0.0009 | 0.001 | 0.0013 | 0.0014 | 0.0013 | 0.0009 | 0.0009 | 0.001 |
| merization | | | | | | | | | | | |
| Inhibitor | | | | | | | | | | | |
| Solvent | J1 | 12.93 | 10.19 | 8.82 | 9.43 | 22.00 | 19.15 | 3.57 | 8.28 | 8.08 | 10.23 |
| | J2 | | | | | 2 | | | | | |
| | J3 | | | | | | | | | | 1.23 |

TABLE 7

| | | Preparation | Preparation |
|---|---|---|---|
| | | Example 51 | Example 52 |
| Near | A1 | | |
| Infrared | A2 | | |
| Absorber | A3 | | |
| | A4 | | |
| | A5 | | |
| | A6 | | |
| | A7 | | |
| | A8 | | |
| | A9 | | |
| | A10 | | |
| | A11 | | |
| | A12 | | |
| | A13 | | |
| | A14 | | |
| | A15 | | |
| | A16 | | |
| | A17 | | |
| | A18 | | |
| | A19 | | |
| | A20 | | |
| | A21 | | |
| | A22 | | |
| | A23 | | |
| Pigment | R-1 | | |
| Dispersion | R-2 | | |
| Liquid | Y-1 | 12.50 | 2.85 |
| | Y-2 | | |
| | V-1 | | |
| | B-1 | 12.50 | |
| | B-2 | | 9.25 |
| | Bk-1 | | 21.10 |
| | Bk-2 | 43.20 | 20.10 |
| | Bk-3 | | |
| | IR-1 | | 7.50 |
| | IR-2 | | |
| | IR-3 | | |
| | IR-4 | | |
| | IR-5 | | |
| | IR-6 | 20.10 | 20.10 |
| | IR-7 | | |
| Polymerizable | D1 | 1.89 | |
| Compound | D2 | | |
| | D3 | | |
| | D4 | | |
| | D5 | | 1.98 |
| | D7 | | 1.98 |
| | D8 | | |
| Photoinitiator | I1 | | |
| | I2 | | 0.344 |
| | I3 | | |
| | I4 | | 0.340 |
| | I5 | 0.655 | |
| | I6 | | |
| | I7 | | |
| | I8 | | |
| Resin | P1 | 0.53 | 2.95 |
| | P2 | | |
| | P3 | | |
| | P4 | | |
| Silane | H1 | | |
| Coupling | | | |
| Agent | | | |
| Ultraviolet | U1 | | |
| Absorber | U2 | | |
| Surfactant | W1 | | |
| | W2 | 0.04 | 0.04 |
| Antioxidant | Y1 | | |
| Polymerization | G1 | 0.0009 | 0.001 |
| Inhibitor | | | |
| Solvent | J1 | 8.58 | 10.23 |
| | J2 | | |
| | J3 | | 1.23 |

The raw materials shown above in the table are as follows.

(Coloring Material)

PR254: C.I. Pigment Red 254

PY139: C.I. Pigment Yellow 139

PY150: C.I. Pigment Yellow 150

PV23: C.I. Pigment Violet 23

PB15:16: C.I. Pigment Blue 15:6

IB: IRGAPHOR BLACK (manufactured by BASF SE)

PBk 32: C.I. Pigment Black 32

(Near Infrared Absorber)

A1 to A18, A20 to A23, K1, K2, K7, K8: compounds having the following structures

A19: NK-5060 (manufactured by Hayashibara Co., Ltd., Cyanine Compound)

K6: lanthanum boride (LaB₆—F, manufactured by Japan New Metals Co., Ltd.)

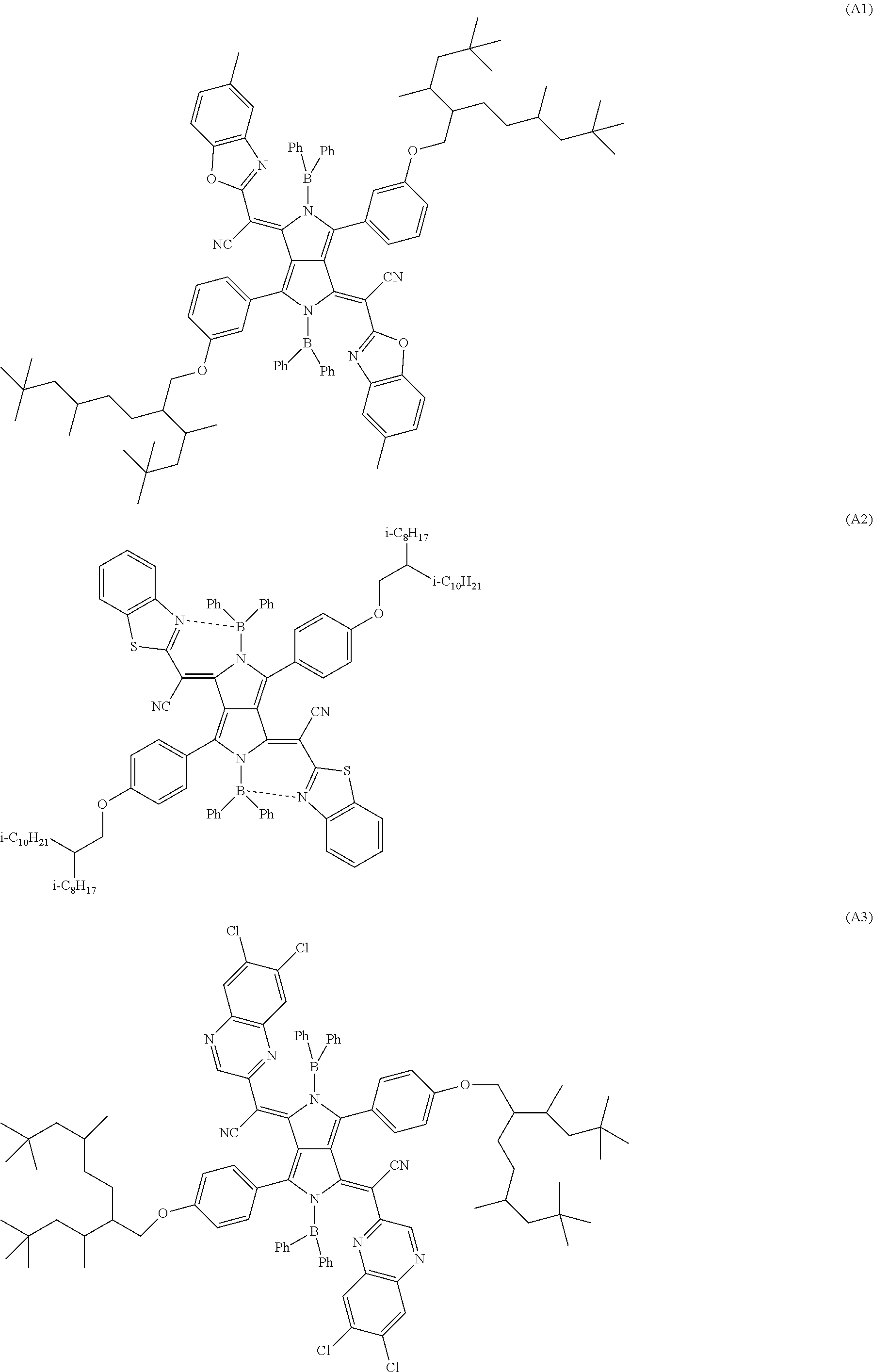

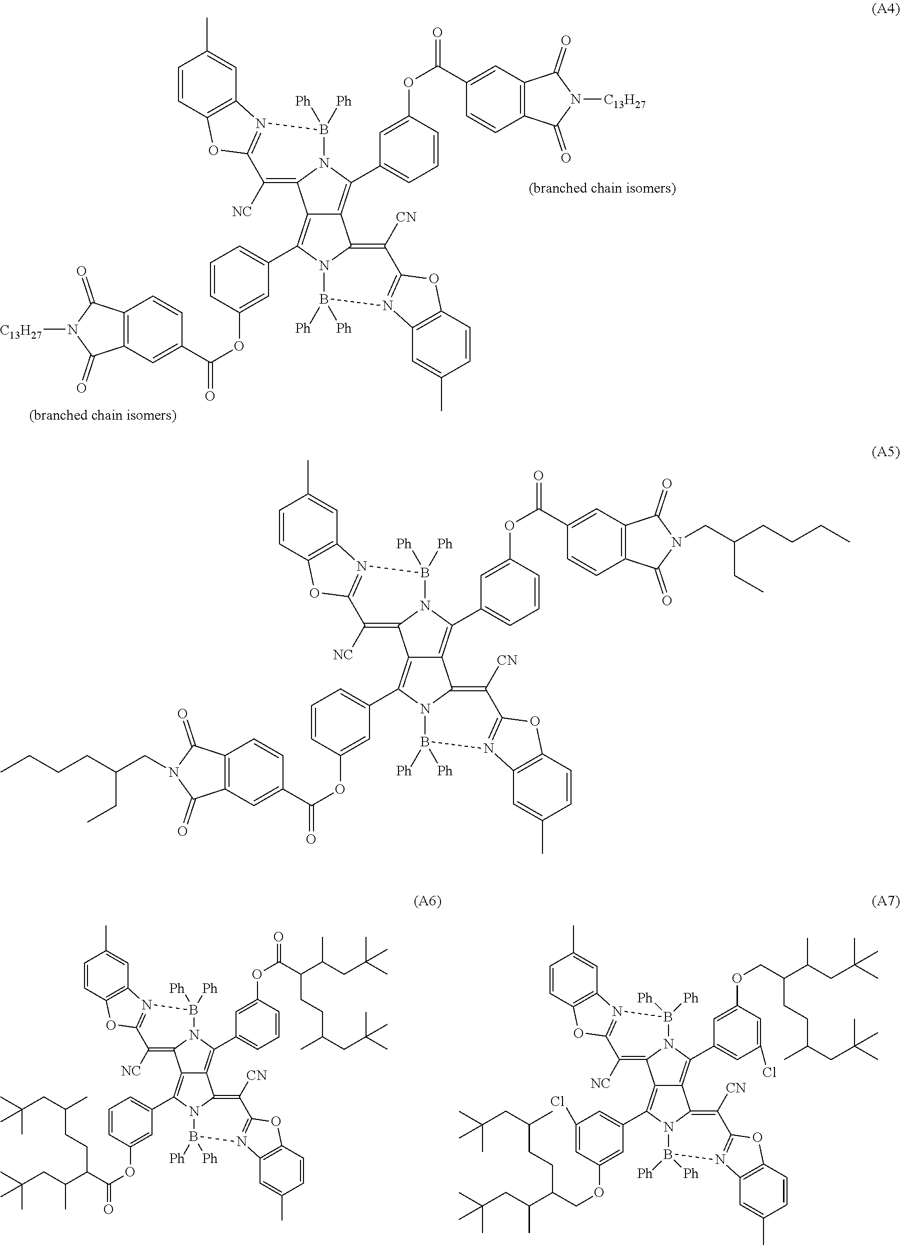

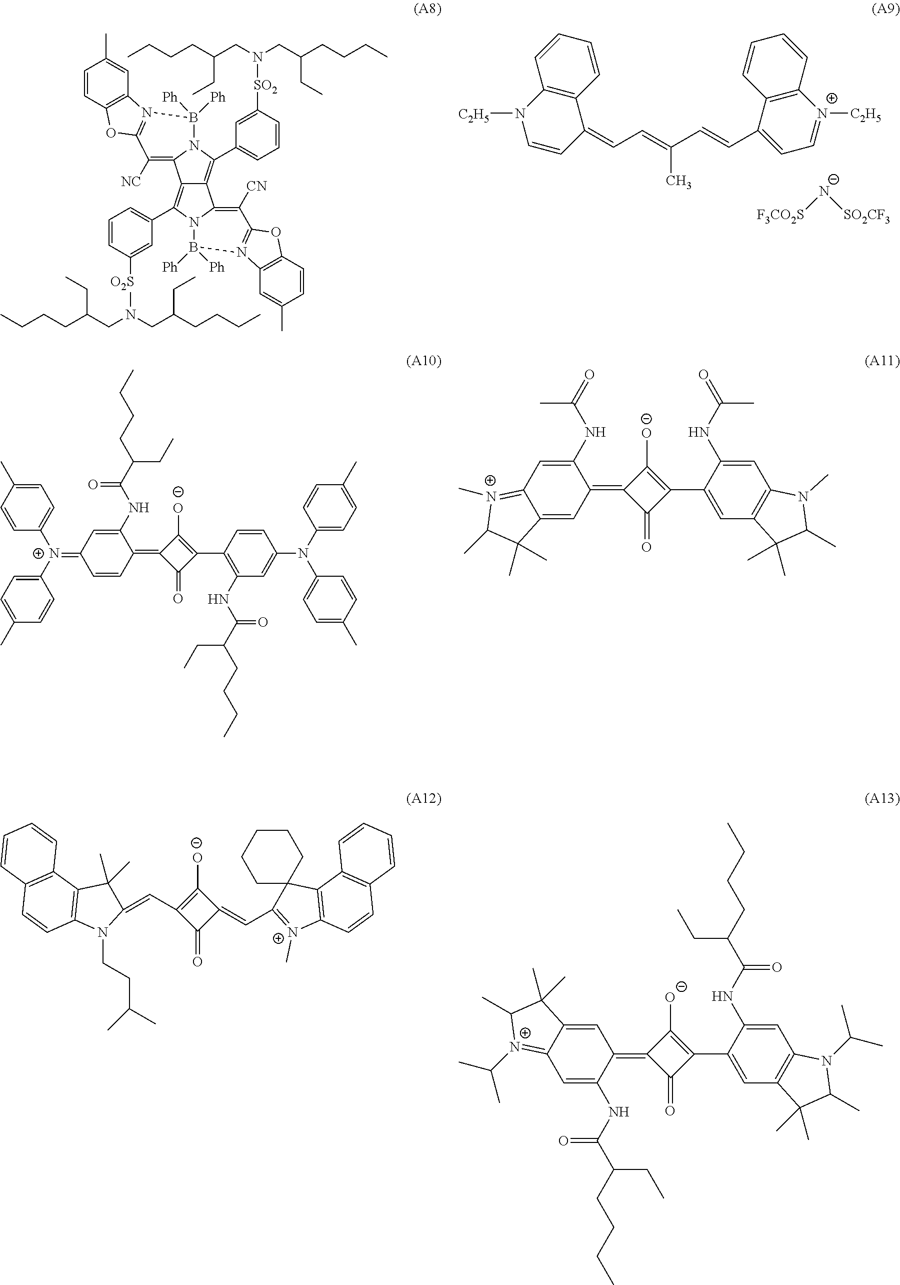

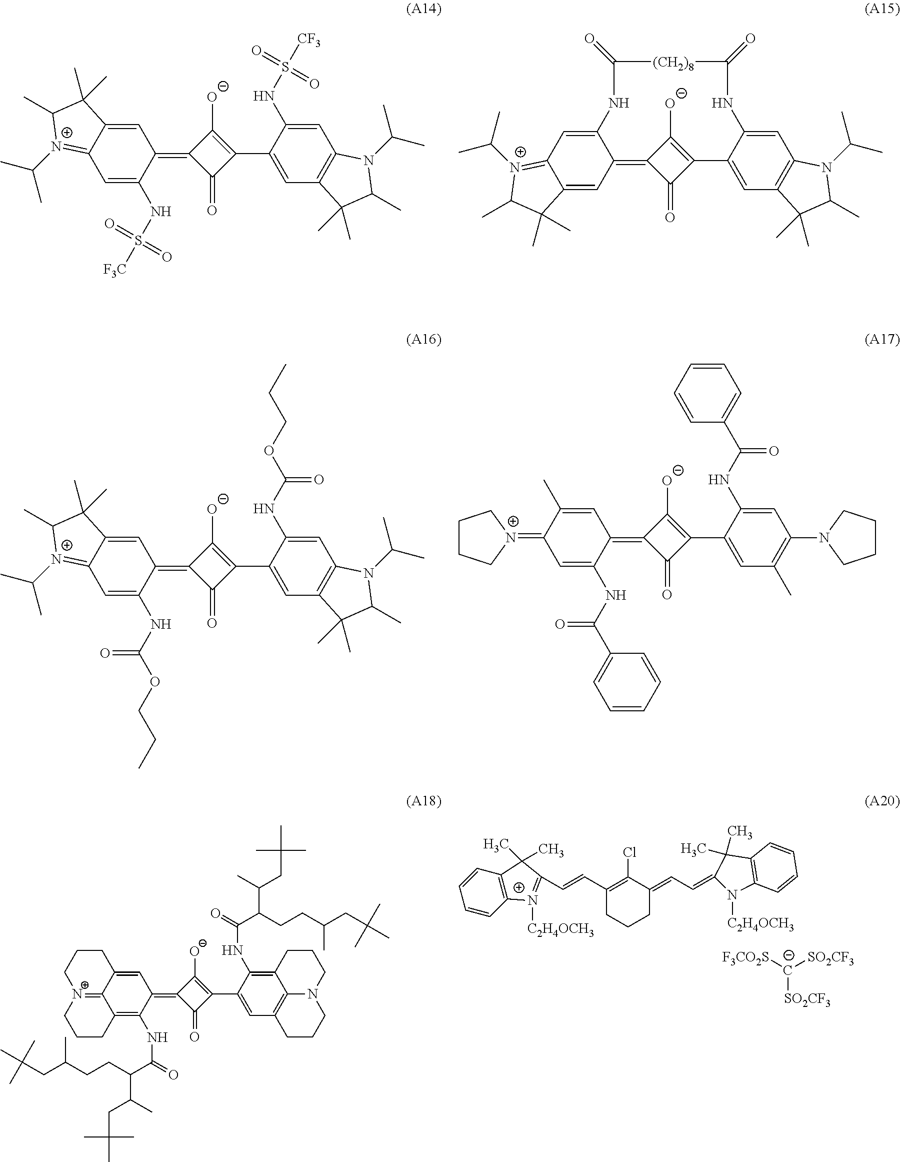

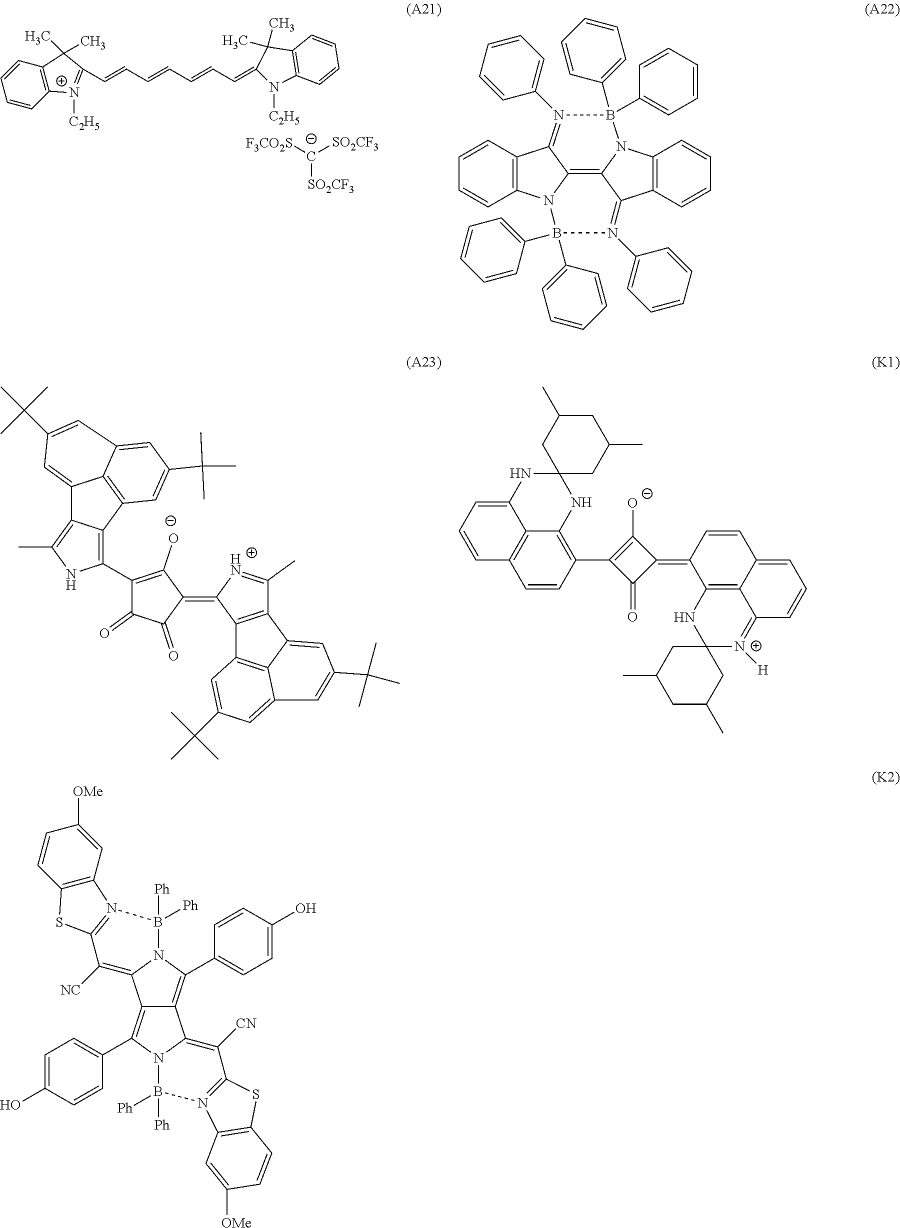

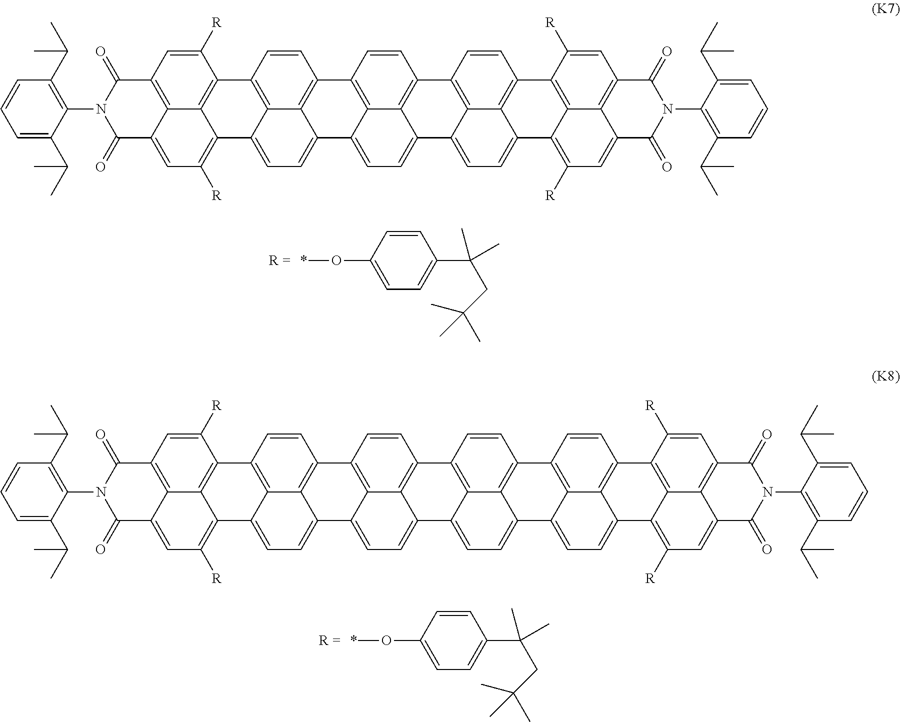

(Pigment Derivative)

B1, K3, K4, K5: compounds having the following structures

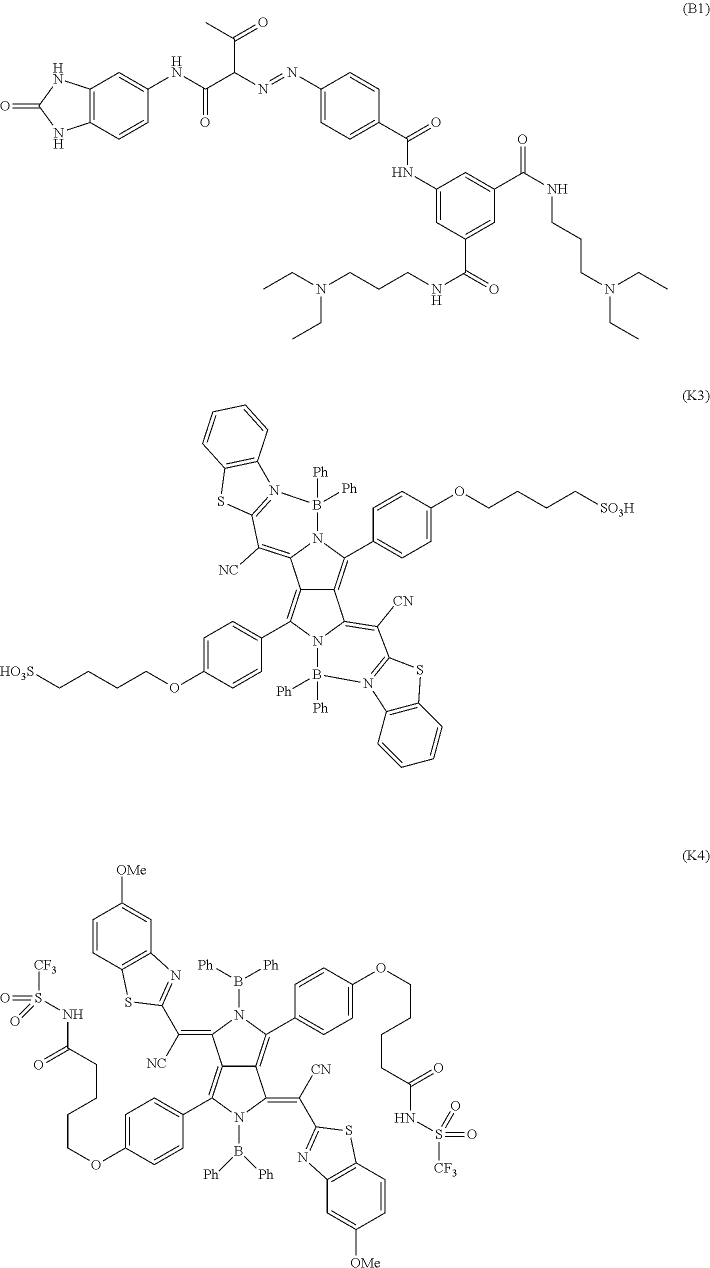

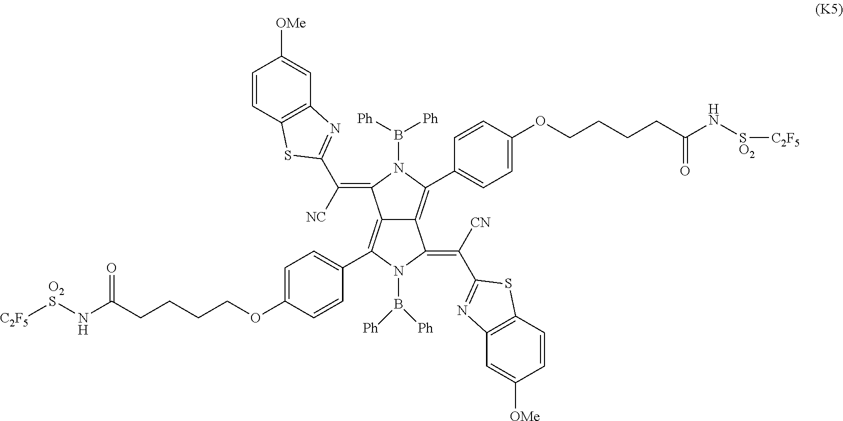

(Dispersant)

C1: a resin having the following structure (a numerical value added to a main chain represents a molar ratio, and a numerical value added to a side chain represents the number of repeating units; Mw=20,000)

C2: a resin having the following structure (a numerical value added to a main chain represents a molar ratio, and a numerical value added to a side chain represents the number of repeating units; Mw=24,000)

C3: a resin having the following structure (a numerical value added to a main chain represents a molar ratio, and a numerical value added to a side chain represents the number of repeating units; Mw=20,000)

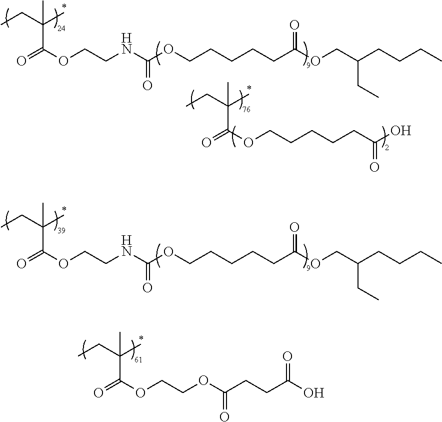

(Resin)

P1: a resin having the following structure (Mw=11000; a numerical value added to a main chain represents a molar ratio; Me represents a methyl group)

P2: a resin having the following structure (Mw=4400, acid value=95 mgKOH/g; in the following structural formula, M represents a phenyl group, and A represents a biphenyltetracarboxylic dianhydride residue)

P3: a resin having the following structure (Mw=41400; a numerical value added to a main chain represents a molar ratio)

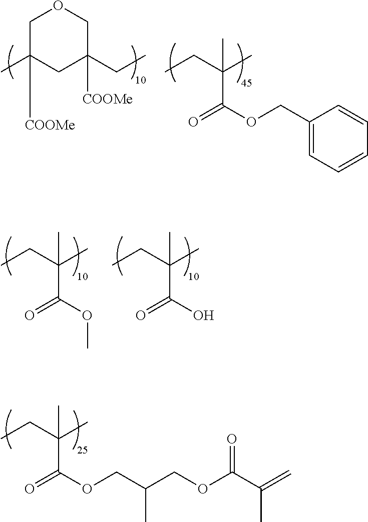

(Polymerizable Compound)

D1: a compound having the following structure (a+b+c=3, polymerizable group value: 7.00 mmol/g)

D2: a compound having the following structure (a+b+c=4, polymerizable group value: 6.34 mmol/g)

D3: a mixture of compounds having the following structures (a compound in which a+b+c=5 (polymerizable group value=5.81 mmol/g):a compound in which a+b+c=6 (polymerizable group value=5.35 mmol/g)=3:1 (molar ratio))

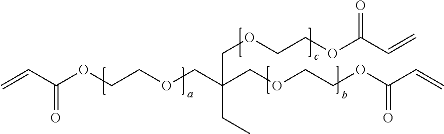

D4: a compound having the following structure (polymerizable group value: 11.35 mmol/g)

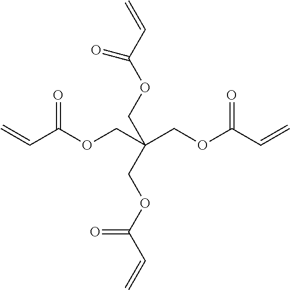 [SMILES: C=CC(=O)OCC(COC(=O)C=C)(COC(=O)C=C)COC(=O)C=C]

D5: a mixture of compounds having the following structures (a mixture including a left side compound (polymerizable group value=10.37 mmol/g) and a right side compound (polymerizable group value=9.53 mmol/g) at a molar ratio of 7:3)

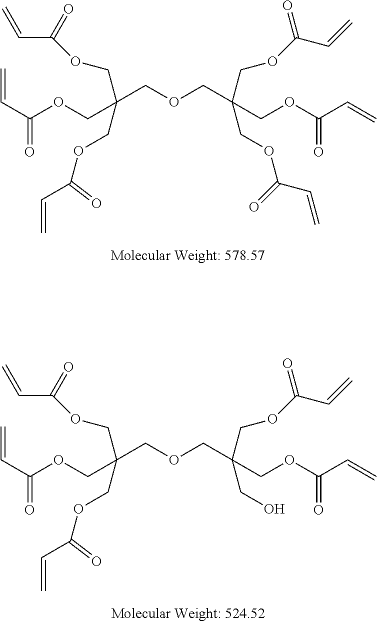 [SMILES: C=CC(=O)OCC(COCC(COC(=O)C=C)(COC(=O)C=C)COC(=O)C=C)(COC(=O)C=C)COC(=O)C=C ; C=CC(=O)OCC(CO)(COCC(COC(=O)C=C)(COC(=O)C=C)COC(=O)C=C)COC(=O)C=C]

D7: ARONIX M-510 (manufactured by Toagosei Co., Ltd.)

D8: a mixture of compounds having the following structures (the content of triacrylate: 55% to 63 mol %, polymerizable group value=10.64 mmol/g)

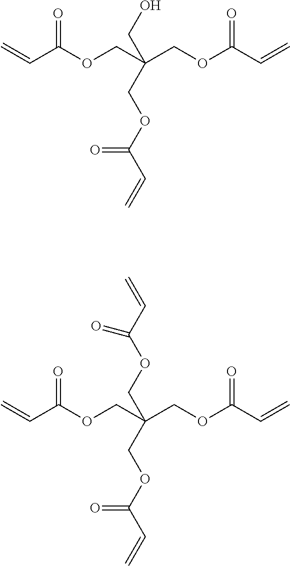

(Photopolymerization Initiator)

I1 to I5: compounds (oxime compounds) having the following structures

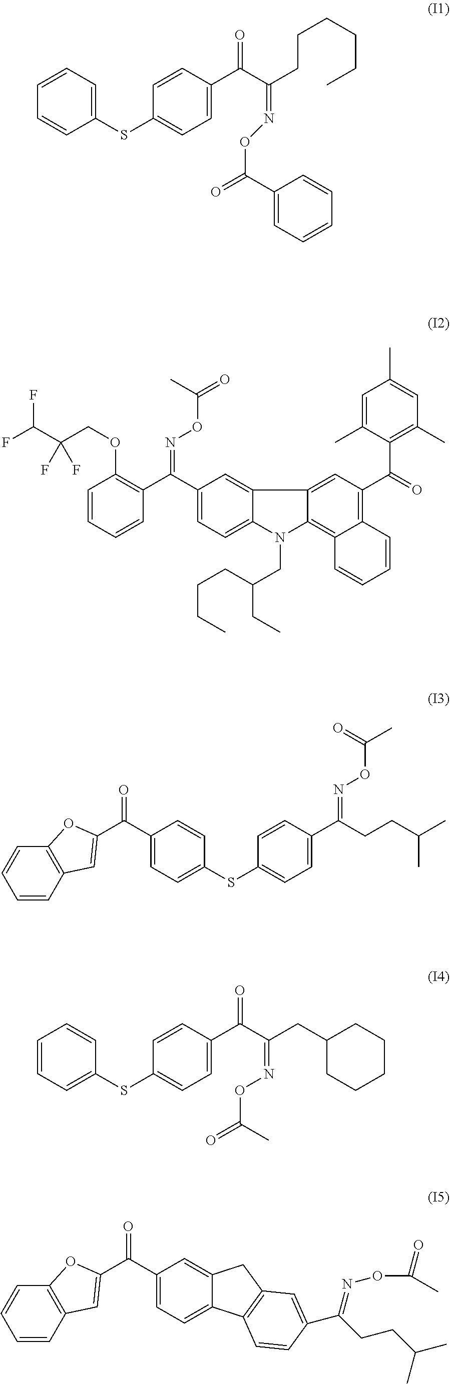 [SMILES: CCCCCC/C(=N/OC(=O)c1ccccc1)C(=O)c1ccc(Sc2ccccc2)cc1 ; CCCCC(CC)Cn1c2ccc(/C(=N\OC(C)=O)c3ccccc3OCC(F)(F)C(F)F)cc2c2cc(C(=O)c3c(C)cc(C)cc3C)c3ccccc3c21 ; CC(=O)O/N=C(\CCC(C)C)c1ccc(Sc2ccc(C(=O)c3cc4ccccc4o3)cc2)cc1 ; CC(=O)O/N=C(/CC1CCCCC1)C(=O)c1ccc(Sc2ccccc2)cc1 ; CC(=O)O/N=C(\CCC(C)C)c1ccc2c(c1)Cc1cc(C(=O)c3cc4ccccc4o3)ccc1-2]

I6: IRGACURE-184 (manufactured by BASF SE)

I7: IRGACURE-TPO (manufactured by BASF SE)

I8: benzopinacol

(Silane Coupling Agent)

H1: a compound having the following structure (in the following structural formulae, Et represents an ethyl group)

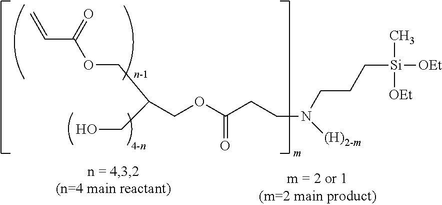

(Ultraviolet Absorber)

U1, U2: compounds having the following structures

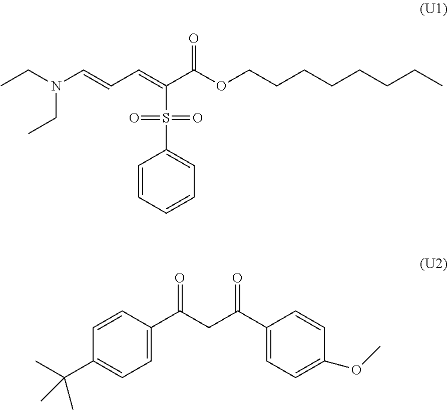

(Surfactant)

W1: the following mixture (Mw=14000, in the following formula, “%” representing the proportion of a repeating unit is mol %)

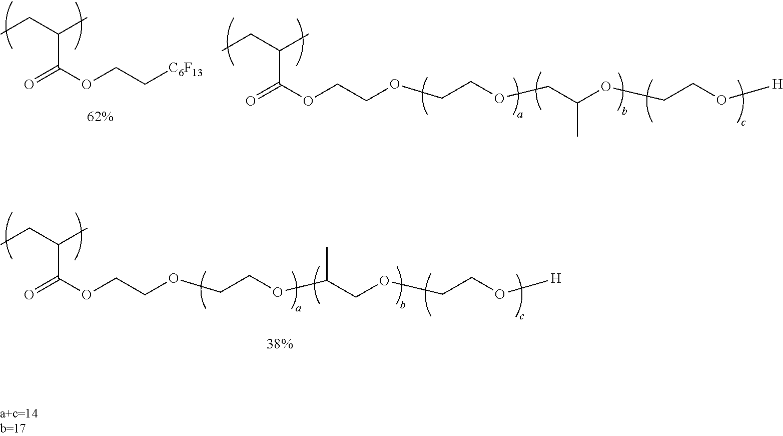

W2: MEGAFACE RS-72-K (manufactured by DIC Corporation, a PGMEA solution having a solid content of 30 mass %)

(Antioxidant)

Y1: ADEKA STAB AO-80 (manufactured by Adeka Corporation)

(Polymerization Inhibitor)

G1: p-methoxyphenol

(Solvent)

J1: propylene glycol monomethyl ether acetate (PGMEA)

J2: cyclohexanone

J3: 3-methoxy-N,N-dimethylpropanamide

### Manufacturing Examples 1 to 50

A photosensitive composition shown in the following table was applied to a glass substrate using a spin coating method such that the thickness of the formed film was 1 μm. Next, the coating film was heated using a hot plate at 100° C. for 2 minutes. Next, using a KrF scanner exposure device (manufactured by Canon Corporation, FPA-6000ES6a), the coating film was exposed to pulses of light through a mask having a Bayer pattern for forming a pixel size of 1 μm×1 μm. Next, puddle development was performed at 23° C. for 60 seconds using a tetramethylammonium hydroxide (TMAH) 0.3 mass % aqueous solution. Next, the coating film was rinsed by spin showering and was cleaned with pure water. Next, the coating film was heated using a hot plate at 200° C. for 5 minutes to form a pattern (pixel).

The pulse exposure condition was as follows.

Exposure light: KrF ray (wavelength: 248 nm)

Exposure dose: 25 to 2000 mJ/cm²

Maximum instantaneous illuminance: 250000000 W/m² (average illuminance: 30000 W/m²)

Pulse duration: 30 nanoseconds

Frequency: 4 kHz

(Manufacturing Example R1 and R2)

A photosensitive composition shown in the following table was applied to a glass substrate using a spin coating method such that the thickness of the formed film was 1 μm. Next, the coating film was heated using a hot plate at 100° C. for 2 minutes. Next, using an i-ray stepper exposure device FPA-i5+(manufactured by Canon Corporation), the coating film was exposed through a mask having a Bayer pattern having a pixel size of 1 μm×1 μm at an exposure dose of 25 to 2000 mJ/cm². The illuminance of the exposure light was substantially uniform through an exposure treatment. Next, puddle development was performed at 23° C. for 60 seconds using a tetramethylammonium hydroxide (TMAH) 0.3 mass % aqueous solution. Next, the coating film was rinsed by spin showering and was cleaned with pure water. Next, the coating film was heated using a hot plate at 200° C. for 5 minutes to form a pattern (pixel).

<Evaluation of Pattern Formability>

An optimal exposure dose (Eopt) for resolving the above-described pattern (1.0 μm×1.0 μm Bayer pattern) was determined, and the pattern formability was evaluated based on the following standards. The optimal exposure dose (Eopt) refers to a minimum exposure dose at which an exposure mask size was reached.

A: Eopt was 50 mJ/cm² or higher and lower than 300 mJ/cm²

B: Eopt was 300 mJ/cm² or higher and lower than 1000 mJ/cm²

C: Eopt was 1000 mJ/cm² or higher and 1700 mJ/cm² or lower

D: Eopt was lower than 50 mJ/cm² or higher or higher than 1700 mJ/cm²

<Evaluation of Residues>

In each of the manufacturing Examples, a portion (non-exposed portion) outside of a region where a pattern was formed by exposure at the optimal exposure dose (Eopt) was observed with a scanning electron microscope (SEM) (magnification of 10000 power) to evaluate development residues according to the following evaluation standards.

A: in the portion (non-exposed portion) outside the region where the pattern was formed, no residues were observed

B: in the portion (non-exposed portion) outside the region where the pattern was formed, a small amount of residues were observed, but there was no problem in practice

C: in the portion (non-exposed portion) outside the region where the pattern was formed, a significant amount of residues were observed

TABLE 8

| | Manufacturing | Manufacturing | Manufacturing | Manufacturing | Manufacturing |
|---|---|---|---|---|---|
| | Example 1 | Example 2 | Example 3 | Example 4 | Example 5 |
| Photosensitive | Preparation | Preparation | Preparation | Preparation | Preparation |
| Composition | Example 1 | Example 2 | Example 3 | Example 4 | Example 5 |
| Used | | | | | |
| Pattern | A | A | A | A | A |
| Formability | | | | | |
| Residue | A | A | A | A | A |
| | Manufacturing | Manufacturing | Manufacturing | Manufacturing | Manufacturing |
| | Example 6 | Example 7 | Example 8 | Example 9 | Example 10 |
| Photosensitive | Preparation | Preparation | Preparation | Preparation | Preparation |
| Composition | Example 6 | Example 7 | Example 8 | Example 9 | Example 10 |
| Used | | | | | |
| Pattern | A | A | A | A | A |
| Formability | | | | | |
| Residue | A | A | A | A | A |

TABLE 9

| | Manufacturing | Manufacturing | Manufacturing | Manufacturing | Manufacturing |
|---|---|---|---|---|---|
| | Example 11 | Example 12 | Example 13 | Example 14 | Example 15 |
| Photosensitive | Preparation | Preparation | Preparation | Preparation | Preparation |
| Composition | Example 11 | Example 12 | Example 13 | Example 14 | Example 15 |
| Used | | | | | |
| Pattern | A | A | A | A | A |
| Formability | | | | | |
| Residue | A | A | A | A | A |
| | Manufacturing | Manufacturing | Manufacturing | Manufacturing | Manufacturing |
| | Example 16 | Example 17 | Example 18 | Example 19 | Example 20 |
| Photosensitive | Preparation | Preparation | Preparation | Preparation | Preparation |
| Composition | Example 16 | Example 17 | Example 18 | Example 19 | Example 20 |
| Used | | | | | |
| Pattern | A | A | A | A | A |
| Formability | | | | | |
| Residue | A | A | A | A | A |

TABLE 10

| | Manufacturing | Manufacturing | Manufacturing | Manufacturing | Manufacturing |
|---|---|---|---|---|---|
| | Example 21 | Example 22 | Example 23 | Example 24 | Example 25 |
| Photosensitive | Preparation | Preparation | Preparation | Preparation | Preparation |
| Composition | Example 21 | Example 22 | Example 23 | Example 24 | Example 25 |
| Used | | | | | |
| Pattern | A | A | A | B | C |
| Formability | | | | | |
| Residue | A | A | A | A | A |
| | Manufacturing | Manufacturing | Manufacturing | Manufacturing | Manufacturing |
| | Example 26 | Example 27 | Example 28 | Example 29 | Example 30 |
| Photosensitive | Preparation | Preparation | Preparation | Preparation | Preparation |
| Composition | Example 26 | Example 27 | Example 28 | Example 29 | Example 30 |
| Used | | | | | |
| Pattern | A | A | A | A | A |
| Formability | | | | | |
| Residue | A | B | A | A | A |

TABLE 11

| | Manufacturing | Manufacturing | Manufacturing | Manufacturing | Manufacturing |
|---|---|---|---|---|---|
| | Example 31 | Example 32 | Example 33 | Example 34 | Example 35 |
| Photosensitive | Preparation | Preparation | Preparation | Preparation | Preparation |
| Composition | Example 31 | Example 32 | Example 33 | Example 34 | Example 35 |
| Used | | | | | |
| Pattern | B | B | B | B | A |
| Formability | | | | | |
| Residue | A | A | A | A | A |
| | Manufacturing | Manufacturing | Manufacturing | Manufacturing | Manufacturing |
| | Example 36 | Example 37 | Example 38 | Example 39 | Example 40 |
| Photosensitive | Preparation | Preparation | Preparation | Preparation | Preparation |
| Composition | Example 36 | Example 37 | Example 38 | Example 39 | Example 40 |
| Used | | | | | |
| Pattern | B | A | A | A | A |
| Formability | | | | | |
| Residue | B | A | A | A | A |

TABLE 12

| | Manufacturing | Manufacturing | Manufacturing | Manufacturing | Manufacturing |
|---|---|---|---|---|---|
| | Example 41 | Example 42 | Example 43 | Example 44 | Example 45 |
| Photosensitive | Preparation | Preparation | Preparation | Preparation | Preparation |
| Composition | Example 41 | Example 42 | Example 43 | Example 44 | Example 45 |
| Used | | | | | |
| Pattern | A | A | A | A | A |
| Formability | | | | | |
| Residue | A | A | A | A | A |
| | Manufacturing | Manufacturing | Manufacturing | Manufacturing | Manufacturing |
| | Example 46 | Example 47 | Example 48 | Example 49 | Example 50 |
| Photosensitive | Preparation | Preparation | Preparation | Preparation | Preparation |
| Composition | Example 46 | Example 47 | Example 48 | Example 49 | Example 50 |
| Used | | | | | |
| Pattern | A | A | A | A | A |
| Formability | | | | | |
| Residue | A | A | A | A | A |

TABLE 13

| | Manufacturing | Manufacturing |
|---|---|---|
| | Example R1 | Example R2 |
| Photosensitive | Preparation | Preparation |
| Composition Used | Example 51 | Example 52 |
| Pattern | D | D |
| Formability | | |
| Residue | A | A |

As shown in the above-described tables, in Manufacturing Examples 1 to 50 in which the films were formed by exposing the photosensitive compositions according to Preparation Examples 1 to 50 to pulses of light, the results of the evaluations of pattern formability and residues were excellent.

In the compositions according to Preparation Examples 1 to 50, the same effects were obtained although the antioxidant, the polymerization inhibitor, and the silane coupling agent were changed to the compounds described in this specification.

What is claimed is:

1. A photosensitive composition for pulse exposure comprising:
a near infrared absorber A;
a photoinitiator B; and
a compound C that is cured by reacting with an active species generated from the photoinitiator B.

2. The photosensitive composition according to claim 1,
wherein an A/B that is a ratio of an absorbance A of the photosensitive composition with respect to light having a wavelength of 248 nm to an absorbance B of the photosensitive composition with respect to light having a wavelength of 365 nm is 3.4 or higher.

3. The photosensitive composition according to claim 1,
wherein the photoinitiator B includes an photoinitiator b1 that satisfies the following condition 1,
condition 1: after a propylene glycol monomethyl ether acetate solution including 0.035 mmol/L of the photoinitiator b1 is exposed to pulses of light having a wavelength of 355 nm under conditions of a maximum instantaneous illuminance of 375000000 W/m², pulse duration: 8 nanoseconds, and frequency: 10 Hz, a quantum yield q₃₅₅ is 0.05 or higher.

4. The photosensitive composition according to claim 3,
wherein the quantum yield q₃₅₅ of the photoinitiator b1 is 0.10 or higher.

5. The photosensitive composition according to claim 3,
wherein the photoinitiator b1 satisfies the following condition 2,
condition 2: after a film having a thickness of 1.0 μm and including 5 mass % of the photoinitiator b1 and 95 mass % of a resin is exposed to pulses of light having a wavelength of 265 nm under conditions of a maximum instantaneous illuminance of 375000000 W/m², pulse duration: 8 nanoseconds, and frequency: 10 Hz, a quantum yield q₂₆₅ is 0.05 or higher.

6. The photosensitive composition according to claim 5,
wherein the quantum yield q₂₆₅ of the photoinitiator b1 is 0.10 or higher.

7. The photosensitive composition according to claim 3,
wherein the photoinitiator b1 satisfies the following condition 3,
condition 3: after a film including 5 mass % of the photoinitiator b1 and a resin is exposed to one pulse of light having a wavelength in a wavelength range of 248 to 365 nm under conditions of a maximum instantaneous illuminance of 62/500,0000 W/m², pulse duration: 8 nanoseconds, and frequency: 10 Hz, an active species concentration in the film reaches 0.000000001 mmol or higher per 1 cm² of the film.

8. The photosensitive composition according to claim 7,
wherein the active species concentration in the film of the photoinitiator b1 reaches 0.0000001 mmol or higher per 1 cm² of the film under the condition 3.

9. The photosensitive composition according to claim 1,
wherein a content of the near infrared absorber A is 15 mass % or higher with respect to a total solid content of the photosensitive composition.

10. The photosensitive composition according to claim 1,
wherein a content of the compound C is 5% to 30 mass % with respect to a total solid content of the photosensitive composition.

11. The photosensitive composition according to claim 1,
wherein the photoinitiator B is a photoradical polymerization initiator, and the compound C is a radically polymerizable compound.

12. The photosensitive composition according to claim 11,
wherein the radically polymerizable compound includes a radically polymerizable monomer.

13. The photosensitive composition according to claim 12,
wherein a polymerizable group value of the radically polymerizable monomer is 10.5 mmol/g or higher.

14. The photosensitive composition according to claim 11,
wherein the photoradical polymerization initiator is at least one compound selected from an alkylphenone compound, an acylphosphine compound, a benzophenone compound, a thioxanthone compound, a triazine compound, or an oxime compound.

15. The photosensitive composition according to claim 1, further comprising:
an ultraviolet absorber.

16. The photosensitive composition according to claim 15,
wherein a content of the ultraviolet absorber is 0.01% to 7 mass % with respect to a total solid content of the photosensitive composition.

17. The photosensitive composition according to claim 1, further comprising:
an antioxidant.

18. The photosensitive composition according to claim 17,
wherein a content of the antioxidant is 0.1% to 5 mass % with respect to a total solid content of the photosensitive composition.

19. The photosensitive composition according to claim 1, which is a composition for a near infrared cut filter.

20. The photosensitive composition according to claim 1, which is a photosensitive composition for a near infrared transmitting filter.
